(19) United States
(12) Patent Application Publication
(10) Pub. No.: US 2024/0341184 A1
(43) Pub. Date: Oct. 10, 2024

(54) LIGHT EMITTING ELEMENT AND DISPLAY DEVICE

(71) Applicant: Samsung Display Co., Ltd., Yongin-si (KR)

(72) Inventors: JIYOUNG LEE, Yongin-si (KR); TSUYOSHI NAIJO, Yongin-si (KR); YUNJEE PARK, Yongin-si (KR); SUNG-SOO BAE, Yongin-si (KR); HOJUNG SYN, Yongin-si (KR); HYOSUP SHIN, Yongin-si (KR); CHANGWOONG CHU, Yongin-si (KR)

(73) Assignee: Samsung Display Co., Ltd., Yongin-si (KR)

(21) Appl. No.: 18/436,263

(22) Filed: Feb. 8, 2024

(30) Foreign Application Priority Data
Mar. 29, 2023 (KR) 10-2023-0041444

(51) Int. Cl. H10K 85/60; C09K 11/06; H10K 50/12; H10K 50/13; H10K 85/30; H10K 85/40

(52) U.S. Cl. CPC H10K 85/658; C09K 11/06; H10K 85/346; H10K 85/40; H10K 85/6572; C09K 2211/1018; C09K 2211/1044; C09K 2211/185; H10K 50/121; H10K 50/13; H10K 85/654

(57) ABSTRACT

Embodiments provide a light emitting element and a display device including the same. The light emitting element includes a first electrode, a second electrode, and a plurality of emission layers disposed between the first electrode and the second electrode, wherein at least one of the plurality of emission layers include a hole transporting host, an electron transporting host, a phosphorescent sensitizer, and a first fluorescent dopant. The first fluorescent dopant comprises a pentacyclic fused ring core that includes one boron atom and two heteroatoms as ring-forming atoms, and at least one amine substituent of the fused ring core; the at least one amine substituent is substituted with at least one substituted or unsubstituted pyrenyl group; and a difference between a triplet state energy level of the first fluorescent dopant and a singlet state energy level of the first fluorescent dopant is equal to or greater than about 0.4 eV.

### CROSS-REFERENCE TO RELATED APPLICATION(S)

This application claims priority to and benefits of Korean Patent Application No. 10-2023-0041444 under 35 U.S.C. § 119, filed on Mar. 29, 2023 in the Korean Intellectual Property Office, the entire contents of which are incorporated herein by reference.

### BACKGROUND

### 1. Technical Field

The disclosure relates to a light emitting element and a display device, and more particularly, to a light emitting element having a tandem structure and a display device including the same.

### 2. Description of the Related Art

Active development continues for an organic electroluminescence display device as an image display device. An organic electroluminescence display device is different from a liquid crystal display in that it includes a so-called self-luminescent light emitting element in which holes and electrons respectively injected from a first electrode and a second electrode recombine in an emission layer, and thus a luminescent material in the emission layer emits light to achieve display.

In the application of a light emitting element to a display device, there is a demand for a light emitting element having high efficiency and long service life, and continuous development is required on a light emitting element that is capable of stably attaining such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which luminous efficiency and an element service life are improved.

The disclosure also provides a display device including the light emitting element in which luminous efficiency and service life are improved.

An embodiment provides a light emitting element which may include a first electrode, a second electrode disposed on the first electrode, and emission layers disposed between the first electrode and the second electrode. At least one of the emission layers may include a hole transporting host, an electron transporting host, a phosphorescent sensitizer, and a first fluorescent dopant, wherein the first fluorescent dopant may include a pentacyclic fused ring core that includes one boron atom and two heteroatoms as ring-forming atoms, and at least one amine substituent of the fused ring core. The at least one amine substituent may be substituted with at least one substituted or unsubstituted pyrenyl group, and a difference between a triplet state energy level of the first fluorescent dopant and a singlet state energy level of the first fluorescent dopant may be equal to or greater than about 0.4 eV.

In an embodiment, the first fluorescent dopant may be represented by Formula 1:

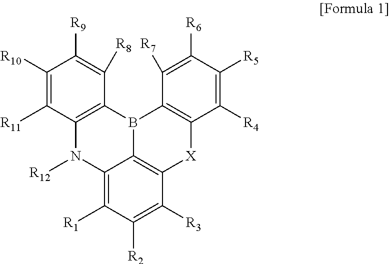

In Formula 1, X may be N(R₁₃), S, or O; R₁ to R₁₃ may each independently be a hydrogen atom, a deuterium atom, a substituted or unsubstituted amine group, or a substituted or unsubstituted aryl group having 3 to 30 ring-forming carbon atoms; and at least one of R₁ to R₁₁ may each independently be a moiety represented by Formula 2:

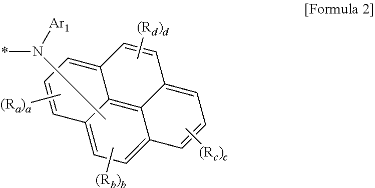

In Formula 2, Ar₁ may be a substituted or unsubstituted aryl group having 3 to 30 ring-forming carbon atoms; Rₐ to R_{d} may each independently be a hydrogen atom or a deuterium atom; a and c may each independently be an integer from 0 to 3; and b and d may each independently be an integer from 0 to 2.

In Formula 1, X may be N(R₁₃); and R₁₂ and R₁₃ may each independently be a substituted or unsubstituted biphenyl group or a substituted or unsubstituted terphenyl group.

In an embodiment, the first compound may include at least one compound selected from Compound Group 1, which is explained below.

In an embodiment, the hole transporting host and the electron transporting host may form an exciplex.

In an embodiment, a triplet state energy level of the exciplex may be higher than a triplet state energy level of the phosphorescent sensitizer, and the triplet state energy level of the phosphorescent sensitizer may be higher than a triplet state energy level of the first fluorescent dopant.

In an embodiment, light emitted from the first fluorescent dopant may have a full width at half maximum (FWHM) equal to or less than about 25 nm.

In an embodiment, the emission layers may include a first emission layer disposed on the first electrode and a second emission layer disposed on the first emission layer. One of the first emission layer and the second emission layer may include the hole transporting host, the electron transporting host, the phosphorescent sensitizer, and the first fluorescent dopant; and the other of first emission layer and the second emission layer may include the hole transporting host, the electron transporting host, the phosphorescent sensitizer, and a second fluorescent dopant that is different from the first fluorescent dopant.

In an embodiment, the second fluorescent dopant may have a difference between a singlet state energy level and a triplet state energy level equal to or less than about 0.3 eV.

In an embodiment, the emission layers may include a first emission layer disposed on the first electrode, and a second emission layer disposed on the first emission layer; and each of the first emission layer and the second emission layer may include the hole transporting host, the electron transporting host, the phosphorescent sensitizer, and the first fluorescent dopant.

In an embodiment, the hole transporting host may include at least one compound selected from Compound Group 2, which is explained below.

In an embodiment, the electron transporting host may include at least one compound selected from Compound Group 3, which is explained below.

In an embodiment, the first fluorescent dopant may have a molar extinction coefficient equal to or greater than about 2×10⁵ M⁻¹ cm⁻¹.

In an embodiment, the phosphorescent sensitizer may include a compound represented by Formula PS, which is explained below.

An embodiment provides a display device which may include a substrate in which a first pixel region, a second pixel region, and a third pixel region are defined; and a display element layer disposed on the substrate. The first pixel region may emit light in a first wavelength region; the second pixel region may emit light in a second wavelength region having a wavelength that is shorter than the light in the first wavelength region; the third pixel region may emit light in a third wavelength region having a wavelength that is shorter than the light in the first wavelength region and shorter than the light in the second wavelength region. The display element layer may include a first light emitting element, a second light emitting element, and a third light emitting element, which respectively correspond to the first pixel region, the second pixel region, and the third pixel region. Each of the first, second, and third light emitting elements may include a first electrode, a second electrode facing the first electrode, a first light emitting unit disposed between the first electrode and the second electrode and including a first emission layer, a second light emitting unit disposed on the first light emitting unit and including a second emission layer, and a charge generation layer disposed between the first light emitting unit and the second light emitting unit. The first fluorescent dopant may include a pentacyclic fused ring core that includes one boron atom and two heteroatoms as ring-forming atoms, and at least one amine substituent of the fused ring core; the at least one amine substituent may be substituted with at least one substituted or unsubstituted pyrenyl group; and a different between a triplet state energy level of the first fluorescent dopant and a singlet state energy level of the first fluorescent dopant may be equal to or greater than about 0.4 eV.

In an embodiment, the charge generation layer may include an n-type charge generation layer overlapping the first to third pixel regions and provided as a common layer on a first light emitting unit, and a p-type charge generation layer disposed on the n-type charge generation layer; and the p-type charge generation layer may be provided as a patterned layer overlapping each of the first to third pixel regions.

In an embodiment, the first light emitting unit may include a first hole transport region disposed on the first electrode, a first emission layer disposed on the first hole transport region, and a first electron transport region disposed on the first emission layer. The second light emitting unit may include a second hole transport region disposed on the charge generation layer, a second emission layer disposed on the second hole transport region, and a second electron transport region disposed on the second emission layer.

In an embodiment, the display device may further include a light control layer including a first light control part overlapping the first pixel region, a second light control part overlapping the second pixel region, and a third light control part overlapping the third pixel region, wherein the light control layer may be disposed on the first to third light emitting elements.

In an embodiment, the hole transporting host and the electron transporting host may form an exciplex; a triplet state energy level of the exciplex may be higher than a triplet state energy level of the phosphorescent sensitizer; and the triplet state energy level of the phosphorescent sensitizer may be higher than a triplet state energy level of the first fluorescent dopant.

In an embodiment, the light emitted from the first fluorescent dopant may have a full width at half maximum (FWHM) equal to or less than about 25 nm.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of a display device according to an embodiment;

FIG. 2 is a schematic cross-sectional view of a display device according to an embodiment;

FIG. 3 is a schematic plan view of a portion of a display device according to an embodiment;

FIG. 4 is a schematic cross-sectional view of a portion of a display device according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a light emitting element according to an embodiment;

FIG. 8 is a schematic cross-sectional view of light emitting elements according to an embodiment;

FIG. 9 is a schematic cross-sectional view of a display device according to an embodiment;

FIG. 10 is a schematic cross-sectional view of a display device according to an embodiment; and

FIG. 11 is a schematic perspective view of an interior of a vehicle in which display devices are disposed, according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/of”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is unsubstituted or substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle and an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “an adjacent group” may be interpreted as mean a substituent that is substituted at an atom which is directly linked to an atom substituted with a corresponding substituent, as another substituent that is substituted at an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are is not limited thereto.

In the specification, an alkenyl group may be a hydrocarbon group including at least one carbon-carbon double bond in the middle or at a terminus of an alkyl group having 2 or more carbon atoms. An alkenyl group may be linear or branched. The number of carbon atoms in an alkenyl group is not particularly limited but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or a terminus of an alkyl group having 2 or more carbon atoms. An alkynyl group may be linear or branched. The number of carbon atoms is not particularly limited but may be 2 to 30, 2 to 20, or 2 to 10. Examples of an alkynyl group may include an ethynyl group, a propynyl group, etc., but embodiments are not limited thereto.

In the specification, the hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below, but embodiments are not limited thereto:

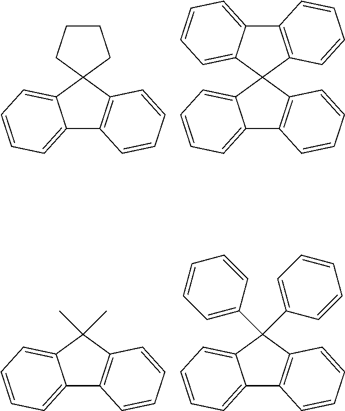

In the specification, a heterocyclic group may be any functional group or substituent derived from a ring including at least one of B, O, N, P, Si, Se, and S as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic. If a heterocyclic group includes two or more heteroatoms, the two or more heteroatoms may be the same as or different from each other.

In the specification, an aliphatic heterocyclic group may include at least one of B, O, N, P, Si, Se, and S as a heteroatom. The number of ring-forming carbon atoms in the aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, Se, and S as a heteroatom. If the heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. The above description of a heteroaryl group may be applied to a heteroarylene group except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an amino group is not particularly limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, a triphenylamino group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto:

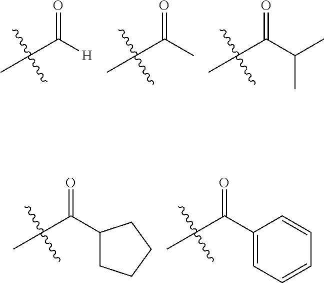

In the specification, the number of carbon atoms in a sulfinyl group or a sulfonyl group is not particularly limited but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, or a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group herein may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but the embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as the examples of an alkyl group as described above.

In the specification, an aryl group within an aryloxy group, an arylthio group, an arylsulfoxy group, an arylamino group, an arylboron group, an arylsilyl group, an arylamine group may be the same as the examples of the aryl group as described above.

In the specification, a direct linkage may be a single bond.

In the specification, the symbols [symbol] and —* each represent a bond to a neighboring atom in a corresponding formula or moiety.

Hereinafter, embodiments will be described with reference to the accompanying drawings.

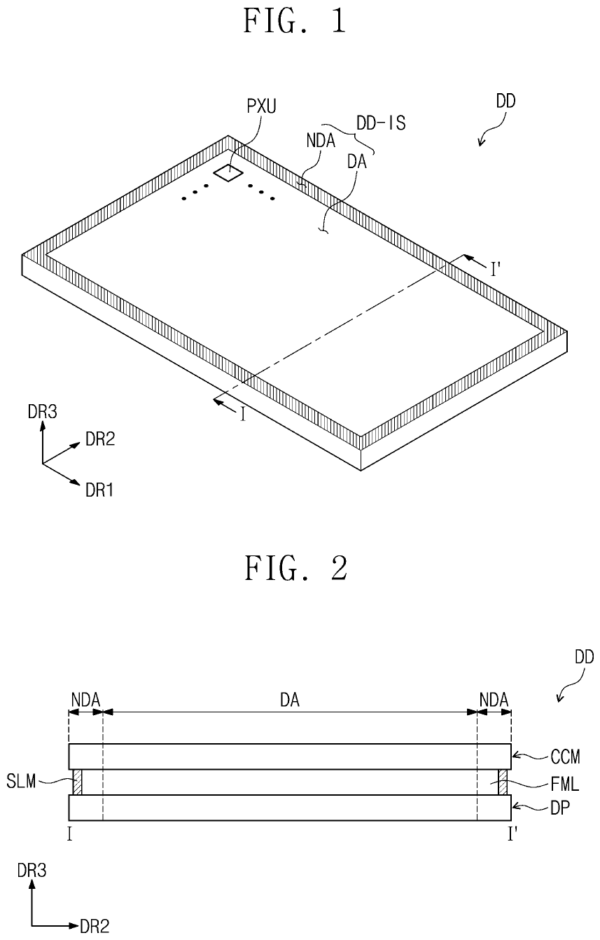

FIG. 1 is a schematic perspective view of a display device according to an embodiment.

FIG. 2 is a schematic cross-sectional view of a display device according to an embodiment.

FIG. 2 may be a schematic cross-sectional view illustrating a part taken along line I-I′ of FIG. 1.

In an embodiment, the display device DD may be a device that is activated according to an electrical signal. For example, the display device DD may be a large-sized display device such as a television, a monitor, or an outdoor billboard; or small or medium-sized products such as personal computers, laptop computers, personal digital terminals, car navigation systems, game consoles, smart phones, tablets, or cameras. However, these are merely presented as examples, and thus other display devices may be employed in other electronic apparatuses.

Referring to FIG. 1 and the following figures, the display device DD may have a thickness direction parallel to the third directional axis DR3 that is the normal direction with respect to the plane defined by the first directional axis DR1 and the second directional axis DR2. The directions indicated by the first to third directional axes DR1, DR2, and DR3 as described in the specification are relative concepts, and may thus be changed to other directions. The directions indicated by the first to third directional axes DR1, DR2, and DR3 may each be described as first to third directions, and the same reference symbols may be used. In this specification, a front surface (or a top surface) and a rear surface (or a bottom surface) of each member constituting the display device DD may be defined on the basis of the third directional axis DR3. In the specification, “in a plan view” may be defined as a state when viewed in the third direction DR3. In the specification, “on a cross-section” may be defined as a state when viewed in the first direction DR1 or the second direction DR2.

The display device DD may include a display surface DD-IS that is parallel to a plane defined by the first direction DR1 and the second direction DR2. The top surface of the member disposed on the uppermost side of the display device DD may be defined as the display surface DD-IS. The display device DD may display an image (or video) in the third direction DR3 through the display surface DD-IS. The display surface DD-IS may include a display region DA and a non-display region NDA. The display region DA may be a region in which the image (or video) is displayed. The non-display region NDA may be a region in which the image (or video) is not displayed. For example, unit pixels PXU may be disposed in the display region DA, and the unit pixels PXU may not be disposed in the non-display region NDA. Wirings and driving circuits for driving the unit pixels PXU may be disposed in the non-display region NDA.

The non-display region NDA may be defined by the edges of the display surface DD-IS. The non-display region NDA may surround the display region DA. However, this is only an example, and embodiments are not limited thereto. For example, the non-display region NDA may be omitted, or the non-display region NDA may be disposed only in one side of the display region DA.

FIG. 1 illustrates the display device DD having a flat display surface DD-IS, but embodiments are not limited thereto. The display device DD may include a curved display surface or a three-dimensional display surface. The three-dimensional display surface may include multiple display areas indicating different directions.

The unit pixels PXU illustrated in FIG. 1 may define pixel rows and pixel columns. The unit pixel PXU is a minimum repeat unit and may include at least one pixel. The unit pixel PXU may include pixels that provide light having colors that are different from each other.

Referring to FIG. 2, the display device DD may include a display panel DP and a light control member CCM that faces the display panel DP and may be spaced apart from the display panel DP. The display device DD may include a sealing member SLM and a filling layer FML disposed between the display panel DP and the light control member CCM.

The display panel DP may be a light emitting display panel, but embodiments are not particularly limited thereto. For example, the display panel DP may be an organic light emitting display panel, an inorganic light emitting display panel, or a quantum dot light emitting display panel. In an embodiment, an emission layer of the organic light emitting display panel may include an organic light emitting material. In another embodiment, an emission layer of the inorganic light emitting display panel may include an inorganic light emitting material. An emission layer of a quantum dot light emitting display panel may include a quantum dot and a quantum rod. Hereinafter, the display panel DP is described as an organic light emitting display panel.

The display panel DP may include a substrate BS, a circuit layer DP-CL, a display element layer DP-ED, and an encapsulation layer TFE. Each layer of the display panel DP will be described later in more detail.

The light control member CCM may be disposed on the display panel DP. The light control member CCM may be provided on the display panel DP and may be connected to the display panel DP through a bonding process using the sealing member SLM. However, embodiments are not limited thereto, and the light control member CCM may be directly disposed on the display panel DP. For example, the configuration of the light control member CCM may be formed through a continuous process on a base surface on which the display panel DP is provided after the display panel DP is formed.

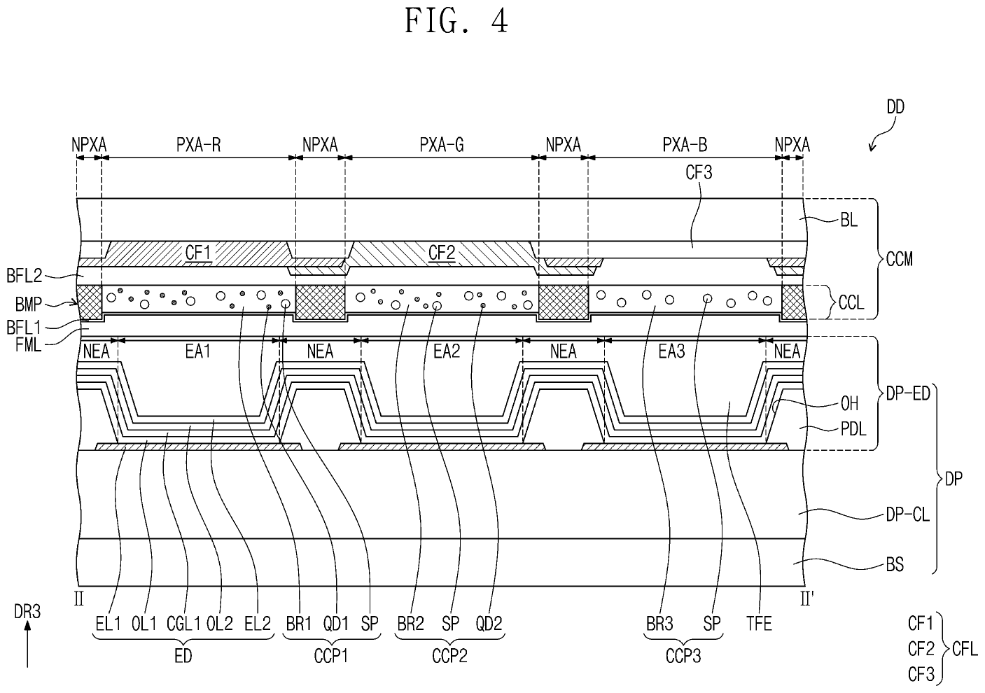

The light control member CCM may include light control patterns that may convert optical properties of source light provided from the display panel DP. The light control member CCM may optionally convert a wavelength or color of the source light or may transmit the source light. The light control member CCM may control the color purity or color reproduction rate of light emitted from the display device DD and may prevent external light, which may be incident from the outside of the display device DD, from being reflected. For example, the light control member CCM in an embodiment may include a quantum dot that may convert a wavelength of the source light provided from the display panel DP. In an embodiment, the light control member CCM may include a light control layer CCL (see FIG. 4) including a quantum dot and a color filter layer CFL (see FIG. 4) disposed on the light control layer CCL.

A display region DA and a non-display region NDA may be defined in each of the display panel DP and the light control member CCM the same as the display region DA and the non-display region NDA of the display device DD. Hereinafter, the display region DA of the display device DD may refer to the display region of each of the display panel DP and the light control member CCM, and the non-display region NDA of the display device DD may refer to the non-display region NDA of each of the display panel DP and the light control member CCM.

The sealing member SLM may be disposed in the non-display region NDA to connect the display panel DP and the light control member CCM. The sealing member SLM may be disposed in the non-display region NDA that is an outer portion of the display device DD to prevent foreign substances, oxygen, moisture, and the like from being introduced into the display device DD from the outside. The sealing member SLM may include a binder resin and inorganic fillers mixed in the binder resin. The sealing member SLM may further include other additives. For example, the additives may include an amine-based curing agent and a photoinitiator. The additives may further include a silane-based additive and an acrylic-based additive. The sealing member SLM may include an inorganic material such as frit.

In an embodiment, a cell gap may be formed, in a region in which the sealing member SLM is not disposed, between the display panel DP and the light control member CCM. A cell gap may be filled with a filling layer FML. The filling layer FML may fill a space between the display panel DP and the light control member CCM in the display region DA and the non-display region NDA. The filling layer FML may serve as a buffer. The filling layer FML may function to absorb an impact, and may increase the strength of the display device DD. The filling layer FML may be formed of a filling resin including a polymer resin. For example, the filling layer FML may be formed of a filling layer resin including an acrylic-based resin, an epoxy-based resin, or the like.

Although not shown in FIG. 2, the filling layer FML and the sealing member SLM may be omitted. For example, the filling layer FML and the sealing member SLM may be omitted, and the light control member CCM may be directly disposed on the display panel DP. In the specification, that one component is “directly disposed” on another component may mean that a third component is not disposed between one component and another component and, that one component may be in contact with another component.

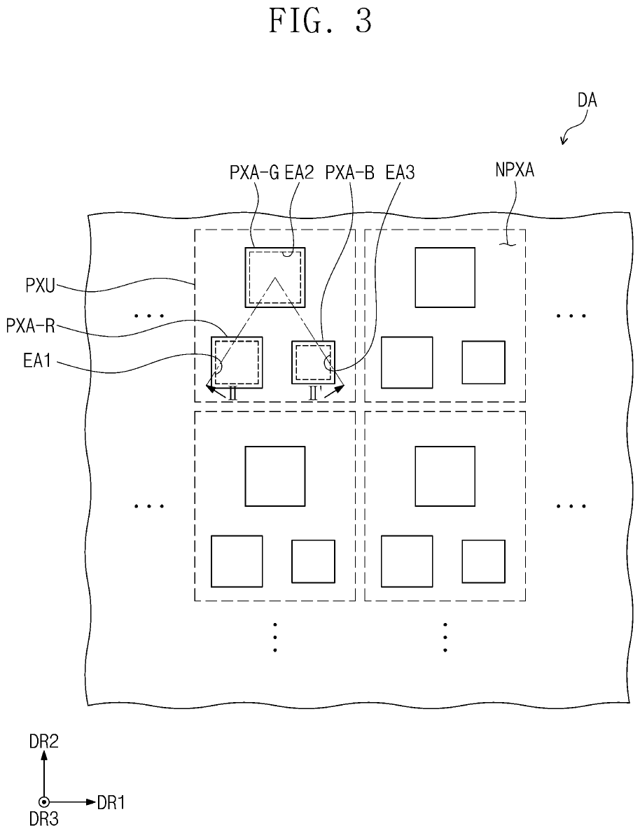

FIG. 3 is a schematic plan view of a portion of the display device according to the embodiment. FIG. 3 illustrates an enlarged portion of the display region DA in the display device DD of the embodiment. FIG. 4 is a schematic cross-sectional view of a portion of the display device according to the embodiment. FIG. 4 illustrates a part taken along line II-II′ of FIG. 3.

As illustrated in FIG. 3, the unit pixels PXU may each be arranged in the first direction DR1 and the second direction DR2. In an embodiment, the unit pixel PXU may include a first pixel, a second pixel, and a third pixel that emit light having colors that are different from each other. The first pixel, the second pixel, and the third pixel may output red light, green light, and blue light, respectively. FIG. 3 illustrates a first light emitting region EA1, a second light emitting region EA2, and a third light emitting region EA3 as respectively representing the first pixel, the second pixel, and the third pixel. FIG. 3 illustrates a first pixel region PXA-R, a second pixel region PXA-G, and a third pixel region PXA-B corresponding to the first light emitting region EA1, the second light emitting region EA2, and the third light emitting region EA3, respectively.

The first light emitting region EA1, the second light emitting region EA2, and the third light emitting region EA3 are arranged to respectively correspond to the first pixel region PXA-R, the second pixel region PXA-G, and the third pixel region PXA-B. That “the light emitting region is aligned with the pixel region” may mean that the light emitting region and the pixel region have the same center. That “the light emitting region is aligned with the pixel region” may mean that both distances between the edge of the light emitting region and the edge of the pixel region are the same in the first direction DR1, and both distances between the edge of the light emitting region and the edge of the pixel region are the same in the second direction DR2.

The first emission region EA1 may be a region in which source light of the first pixel is generated, the second emission region EA2 may be a region in which source light of the second pixel is generated, and the third emission region EA3 may be a region in which source light of the third pixel is generated. The first pixel region PXA-R is a region in which the output light of the first pixel is provided to the outside, the second pixel region PXA-G is a region in which the output light of the second pixel is provided to the outside, and the third pixel region PXA-B is a region in which the output light of the third pixel is provided to the outside. For example, the first pixel region PXA-R may be a region that emits light in a first wavelength region, the second pixel region PXA-G may be a region that emits light in a second wavelength region, and the third pixel region PXA-B may be a region that emits light in a third wavelength region. The light in the first wavelength region may be red light having an emission wavelength in a range of about 620 nm to about 700 nm. The light in the second wavelength region may be green light having an emission wavelength in a range of about 500 nm to about 600 nm. The light in the third wavelength region may be blue light having an emission wavelength in a range of about 410 nm to about 480 nm.

Non-pixel regions NPXA may be disposed between and around the first pixel region PXA-R, the second pixel region PXA-G, and the third pixel region PXA-B. The non-pixel regions NPXA may surround the first to third pixel regions PXA-R, PXA-G, and PXA-B. The non-pixel regions NPXA may set boundaries of the first to third pixel regions PXA-R, PXA-G, and PXA-B and prevent color mixing among the first to third pixel regions PXA-R, PXA-G, and PXA-B.

Referring to FIG. 3, the first pixel region PXA-R and the third pixel region PXA-B may be disposed in a same row, and the second pixel region PXA-G may be disposed in a different row from the first pixel region PXA-R and the third pixel region PXA-B. However, this is only an example, and the disposition of the first to third pixel regions PXA-R, PXA-G, and PXA-B may be changed. For example, the first to third pixel regions PXA-R, PXA-G, and PXA-B may be disposed in a same row.

In an embodiment, the first to third pixel regions PXA-R, PXA-G, and PXA-B may each have areas that are different from each other in a plan view. For example, the first pixel region PXA-R may have the largest area, and the third pixel PXA-B may have the smallest area. However, embodiments are not limited thereto, and at least two among the first to third pixel regions PXA-R, PXA-G, and PXA-B may have the same area.

FIG. 3 illustrates the first pixel region PXA-R, the second pixel region PXA-G, and the third pixel region PXA-B, which have a substantially rectangular shape in a plan view, but embodiments are not limited thereto. The first to third pixel regions PXA-R, PXA-G, and PXA-B may each have polygonal shapes that are different from each other, such as diamond or pentagon. In other embodiments, the first to third pixel regions PXA-R, PXA-G, and PXA-B may each have a rectangular shape with rounded corners. In embodiments, the first to third pixel regions PXA-R, PXA-G, and PXA-B may have shapes that are different from each other in a plan view.

Referring to FIG. 4, the display device DD according to an embodiment may include a display panel DP and a light control member CCM disposed on the display panel DP. The display panel DP according to an embodiment may include a substrate BS, a circuit layer DP-CL, and a display element layer DP-ED. The circuit layer DP-CL may be disposed on the substrate BS. The display element layer DP-ED may be disposed on the circuit layer DP-CL.

The substrate BS may provide a base surface on which the circuit layer DP-CL is disposed. The substrate BS may include a single layer or a stack of multiple layers. For example, the substrate BS may include a three-layered structure constituted by a polymer resin layer, an adhesive layer, and a polymer resin layer. For example, the polymer resin layer may include a polyimide-based resin. For example, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In the specification, the polyimide-based resin means a functional group of polyimide. The same description may be applied to the acrylate-based resin, the methacrylate-based resin, the polyisoprene-based resin, the vinyl-based resin, the epoxy-based resin, the urethane-based resin, the cellulose-based resin, the siloxane-based resin, the polyamide-based resin, the polyamide-based resin, and the perylene-based resin. The substrate BS may include a glass substrate, a metal substrate, an organic composite material substrate, or an inorganic composite material substrate.

The circuit layer DP-CL may include an insulation layer, a semiconductor pattern, a conductive pattern, a signal line, etc. The circuit layer DP-CL may include transistors (not shown). The transistors (not shown) may each include a control electrode, an input electrode, and an output electrode. For example, the circuit layer DP-CL includes a switching transistor and a driving transistor for driving the light emitting element ED of the display element layer DP-ED.

The display element layer DP-ED may include a pixel defining film PDL, the light emitting element ED, and an encapsulation layer TFE. An opening OH of the pixel defining film PDL may expose at least a portion of the first electrode EL1. Light emitting regions EA1, EA2, and EA3 may each be defined in the pixel defining film PDL to correspond to the first electrodes EL1 of the first pixel region PXA-R, the second pixel region PXA-G, and the third pixel region PXA-B. The first to third light emitting regions EA1, EA2, and EA3 may be defined by the openings OH of the pixel defining film PDL. A region among the light emitting regions EA1, EA2, and EA3, that is, the region in which the pixel defining film PDL is disposed, may be defined as a non-light emitting region NEA.

The pixel defining film PDL may be formed of a polymer resin. For example, the pixel defining film PDL may include a polyacrylate-based resin or a polyimide-based resin. For example, the pixel defining film PDL may include an inorganic material in addition to the polymer resin. In an embodiment, the pixel defining films PDL may include a light absorbing material, a black pigment, or a black dye. In another embodiment, the pixel defining film PDL may be formed of an inorganic material. For example, the pixel defining film PDL may be formed of silicon nitride (SiNₓ), silicon oxide (SiOₓ), silicon oxide (SiOₓN_{y}), etc.

The light emitting element ED may include a first electrode EL1, a second electrode EL2, light emitting units OL1 and OL2, and a charge generation layer CGL1. The first electrode EL1 and the second electrode EL2 are disposed on the circuit layer DP-CL to face each other, and emitting units OL1 and OL2 may be disposed between the first electrode EL1 and the second electrode EL2. The charge generation layer CGL1 may be disposed between light emitting units OL1 and OL2. The light emitting units OL1 and OL2 may each include functional layers including a hole transport material and an electron transport material, and an emission layer including a light emitting material. For example, the light emitting element ED according to an embodiment may have a tandem structure including multiple emission layers. In an embodiment, the light emitting units OL1 and OL2 may generate first color source light. In an embodiment, the first color source light may be blue light, but embodiments are not limited thereto. Hereinafter, the functional layers and emission layers included in the light emitting element ED will be described later.

FIG. 4 illustrates an embodiment in which the first light emitting unit OL1, the charge generation layer CGL1, and the second light emitting unit OL2 are disposed in the light emitting regions EA1, EA2, and EA3 and the non-light emitting region NEA to have a tandem structure. In an embodiment, a portion of light emitting units OL1 and OL2 may each be disposed on the pixel defining film PDL, and portions of light emitting units OL1 and OL2 disposed in the light emitting regions EA1, EA2, and EA3 may be connected to each other on the pixel defining film PDL to form common layers having an integrated shape. Accordingly, the functional layers and the emission layers disposed in the light emitting units OL1 and OL2 may also form common layers having an integrated shape in all of the light emitting regions EA1, EA2, and EA3 and the non-light emitting region NEA. However, embodiments are not limited thereto. For example, at least some of the light emitting units OL1 and OL2 may each be provided by being patterned in openings OH defined in the pixel defining film PDL. At least some of light emitting units OL1 and OL2 or at least some of the functional layers and the emission layers included in light emitting units OL1 and OL2 may each be provided by patterned through an inkjet printing method.

The encapsulation layer TFE may be disposed on the light emitting element ED, and the encapsulation layer TFE may be disposed on the second electrode EL2. The encapsulation layer TFE may be directly disposed on the second electrode EL2 and may be disposed filling the opening OH. The encapsulation layer TFE may be a single layer or a stack of multiple layers. The encapsulation layer TFE includes at least one insulation layer. The encapsulation layer TFE may include at least one inorganic film (hereinafter, an encapsulation-inorganic film). In an embodiment, the encapsulation layer TFE may also include at least one organic film (hereinafter, an encapsulation-organic film) and at least one encapsulation-inorganic film. For example, the encapsulation layer TFE includes may have a multi-layered structure in which a first inorganic film, an organic film, and a second inorganic film are sequentially stacked.

The encapsulation-inorganic film protects the light emitting element ED from moisture and/or oxygen, and the encapsulation-organic film protects the light emitting element ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not particularly limited thereto.

Referring to FIG. 4, the light control member CCM according to an embodiment may include a base layer BL, a color filter layer CFL, and a light control layer CCL. The light control layer CCL may be disposed below the base layer BL, and the color filter layer CFL may be disposed between the light control layer CCL and the base layer BL. The light control layer CCL may be disposed adjacent to the display panel DP to convert a wavelength of the source light generated from the light emitting element ED or to transmit the source light.

The base layer BL may be a member providing a base surface on which the light control member CCM is disposed. For example, the base layer BL may be a glass substrate, a metal substrate, a plastic substrate, etc. However, embodiments are not limited thereto, and the base layer BL may be an inorganic layer, an organic layer, or a composite material layer. Although not shown in FIG. 4, the base layer BL may be omitted in the display device DD according to an embodiment. For example, in case that the base layer BL is omitted, the light control layer CCL may be disposed on a reference surface provided by the encapsulation layer. The display device DD may further include a functional layer, such as an anti-reflection layer, an anti-fingerprint layer, or a hard coating layer, disposed on the base layer BL.

In an embodiment, the light control member CCM may include the color filter layer CFL. The color filter layer CFL may be disposed between the base layer BL and the light control layer CCL.

The color filter layer CFL may include first to third filters CF1, CF2, and CF3. The first filter CF1 may overlap at least a portion of the first light emitting region EA1, the second filter CF2 may overlap at least a portion of the second light emitting region EA2, and the third filter CF3 may overlap at least a portion of the third light emitting region EA3. The first filter CF1 may transmit second color light and block the first color source light. The second filter CF2 may transmit third color light and block the first color source light. The third filter CF3 may transmit the first color source light. For example, the first filter CF1 may be a red filter, the second filter CF2 may be a green filter, and the third filter CF3 may be a blue filter.

The first to third filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin. In an embodiment, the first filter CF1 and the second filter CF2 may each be a yellow filter. The first filter CF1 and the second filter CF2 may not be separated but be provided as one body.

The first filter CF1, the second filter CF2, and the third filter CF3 may each define a first pixel region PXA-R, a second pixel region PXA-G, a third pixel region PXA-B, and a non-pixel region NPXA. Only a corresponding filter among the first filter CF1, the second filter CF2, and the third filter CF3 may be disposed in each of the first pixel region PXA-R, the second pixel region PXA-G, and the third pixel region PXA-B. For example, the first pixel region PXA-R in which the second filter CF2 and the third filter CF3 do not overlap each other may be defined in the first filter CF1, the second pixel region PXA-G in which the first filter CF1 and the third filter CF3 do not overlap each other may be defined in the second filter CF2, and the third pixel region PXA-B in which the first filter CF1 and the second filter CF2 do not overlap each other may be defined in the third filter CF3. A region in which two or more filters among the first filter CF1, the second filter CF2, and the third filter CF3 overlap each other may be defined as the non-pixel region NPXA. In case that the filters CF1, CF2, and CF3 are disposed to overlap each other, a light shielding effect of external light may increase, and thus, the filters may have the same function as a black matrix. The overlapping structure of the filters CF1, CF2, and CF3 may have a function of preventing color mixing.

In embodiments, the color filter layer CFL may further include a light shielding part. The light shielding part may be the black matrix. The light shielding part may include an organic light shielding material or an inorganic light shielding material including a black pigment or dye. The light shielding part may prevent light leakage, and may separate boundaries between the adjacent filters CF1, CR2, and CF3. In case that the light shielding part is further disposed, the non-pixel region NPXA may be defined as a region in which the light shielding part is disposed.

In embodiments, the color filter layer CFL may further include a low refractive layer. The low refractive layer may be disposed between the filters CF1, CF2, and CF3 and the light control layer CCL. The low refractive layer may have a refractive index from about 1.1 to about 1.5. The refractive index value of the low refractive layer may be adjusted by the ratio of hollow inorganic particles and/or voids, etc. included in the low refractive layer.

The light control layer CCL may include a bank BMP and the light control parts CCP1, CCP2 and CCP3. In a plan view, the bank BMP may overlap the non-pixel region NPXA. Openings may be defined in the bank BMP. Openings respectively corresponding to the first pixel region PXA-R, the second pixel region PXA-G, and the third pixel region PXA-B may be defined in the bank BMP. An opening corresponding to the first pixel region PXA-R, an opening corresponding to the second pixel region PXA-G, and an opening corresponding to the third pixel region PXA-B may respectively correspond to the first light emitting region EA1, the second light emitting region EA2, and the third light emitting region EA3. That “the two configurations correspond to each other” may mean that the two configurations overlap in a plan view, which is not limited to the same area.

The bank BMP may include a base resin and an additive. The base resin may be formed of various resin compositions, which may be generally referred to as a binder. The additive may include a coupling agent and/or photoinitiator. The additive may further include a dispersant. The bank BMP may include a black coloring agent for shielding light. The bank BMP may include a black dye and/or pigment mixed in the base resin. The black component may include carbon black or include a metal such as chromium, or an oxide thereof.

The light control parts CCP1, CCP2, and CCP3 may include a first light control part CCP1, a second light control part CCP2, and a third light control part CCP3, which are disposed in openings defined in the bank BMP, respectively. The first light control part CCP1 may be disposed to correspond to the first pixel region PXA-R, the second light control part CCP2 may correspond to the second pixel region PXA-G, and the third light control part CCP3 may correspond to the third pixel region PXA-B. The first to third light control parts CCP1, CCP2, and CCP3 may be spaced apart from each other by the bank BMP. However, embodiments are not limited thereto, and at least a portion of the edges of the light control parts CCP1, CCP2, and CCP3 may overlap the bank BMP.

The first light control part CCP1 may convert the first color light into the second color light. The second color light may have a longer wavelength region than the first color light. For example, the first color light may be blue light, and the second color light may be red light. The first color light may have an emission wavelength in a range of about 410 nm to about 480 nm. The second color light may have an emission wavelength in a range of about 620 nm to about 700 nm. The first color light may be source light provided from the display panel DP to the light control layer CCL. The second color light may pass through the first filter CF1 as described above and be provided to the outside as first output light.

The second light control part CCP2 may convert the first color source light into third color light. The third color light may have a longer wavelength region than the first color light and may have a shorter wavelength region than the second color light. For example, the third color light may be green light. The third color light may have a wavelength region in a range of about 500 nm to about 600 nm. The third color light may pass through the second filter CF2 as described above and be provided to the outside as second output light.

The third light control part CCP3 may transmit the first color source light without converting it into other color light. The first color source light may pass through the third filter CF3 and be provided to the outside as third output light.

The first light control part CCP1, the second light control part CCP2, and the third light control part CCP3 may each be formed by an inkjet process. The first light control part CCP1, the second light control part CCP2, and the third light control part CCP3 may each be formed by providing compositions corresponding to a space defined by the bank BMP, for example, in multiple openings.

The first light control part CCP1 and the second light control part CCP2 may include quantum dots QD1 and QD2. The first light control part CCP1 may include a first quantum dot QD1 which converts the first color source light into the second color light, and the second light control part CCP2 may include a second quantum dot CCP2 which converts the first color source light into the third color light. For example, the first quantum dot QD1 may be a red quantum dot, and the second quantum dot QD2 may be a green quantum dot.

Quantum dots QD1 and QD2 may be materials having a crystal structure with a size of several nanometers, composed of hundreds to thousands of atoms, and may exhibit a quantum confinement effect by which an energy band gap increases due to a small size. In case that light of a wavelength having higher energy than the band gap is incident on the quantum dot, the quantum dot may absorb the light to be excited and may fall to a ground state while emitting light of a specific wavelength. The emitted light with the wavelength may have a value corresponding to the band gap. In case that the quantum dot is adjusted in size and composition, light emitting properties due to the quantum confinement effect may be controlled.

The quantum dots QD1 and QD2 may each independently be a Group II-VI compound, a Group I-II-VI compound, a Group II-IV-VI compound, a Group I-II-IV-VI compound, a Group III-VI compound, a Group I-III-VI compound, a Group III-V compound, a Group III-II-V compound, a Group II-IV-V compound, a Group IV-VI compound, a Group IV element, a Group IV compound, or any combination thereof.

Examples of a Group II-VI compound may include: a binary compound such as CdSe, CdTe, CdS, ZnS, ZnSe, ZnTe, ZnO, HgS, HgSe, HgTe, MgSe, MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS; a quaternary compound such as HgZnTeS, CdZnSeS, CdZnSeTe, CdZnSTe, CdHgSeS, CdHgSeTe, CdHgSTe, HgZnSeS, HgZnSeTe; or any mixture thereof. In an embodiment, a Group II-VI compound may further include a Group I metal and/or a Group IV element. Examples of a Group I-II-VI compound may include CuSnS or CuZnS, and ZnSnS, etc., and examples of a Group II-IV-VI compound may include ZnSnS, etc. Examples of a Group I-II-IV-VI compound may include a quaternary compound such as Cu₂ZnSnS₂, Cu₂ZnSnS₄, Cu₂ZnSnSe₄, Ag₂ZnSnS₂, or any mixture thereof.

Examples of a Group III-VI compound may include: a binary compound such as In₂S3 or In₂Se₃; a ternary compound such as InGaS₃ or InGaSe₃; or any combination thereof.

Examples of a Group I-III-VI compound may include: a ternary compound such as AgInS, AgInS₂, CuInS, CuInS₂, AgGaS₂, CuGaS₂ CuGaO₂, AgGaO₂, AgAlO₂; a quaternary compound such as AgInGaS₂ or CuInGaS₂; or any combination thereof.

Examples of a Group III-V compound may include: a binary compound such as GaN, GaP, GaAs, GaSb, AlN, AlP, AlAs, AlSb, InN, InP, InAs, InSb; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb; or any mixture thereof. A Group III-V compound may further include a Group II metal. For example, InZnP, etc. may be selected as a Group III-II-V compound.

Examples of a Group II-IV-V may include: a ternary compound such as ZnSnP, ZnSnP2, ZnSnAs2, ZnGeP2, ZnGeAs2, CdSnP2, CdGeP2; or any mixture thereof.

Examples of a Group IV-VI compound may include a binary compound such as SnS, SnSe, SnTe, PbS, PbSe, PbTe; a ternary compound such as SnSeS, SnSeTe, SnSTe, PbSeS, PbSeTe, PbSTe, SnPbS, SnPbSe, SnPbTe; a quaternary compound such as SnPbSSe, SnPbSeTe, SnPbSTe; or any mixture thereof. Examples of a Group IV element may include: Si, Ge, or any mixture thereof. A Group IV compound may be a binary compound such as SiC, SiGe, or any mixture thereof.

In an embodiment, a binary compound, the ternary compound, or the quaternary compound may be present in a particle with a uniform concentration distribution or may be present in the same particle with a partially different concentration distribution. The quantum dot may have a core/shell structure in which one quantum dot surrounds another quantum dot. The core/shell structure may have a concentration gradient in which the concentration of elements present in the shell decreases toward the core.

In an embodiment, the quantum dots QD1 and QD2 may have the above-described core/shell structure including a core including nanocrystals and a shell surrounding the core.

The shell of the quantum dot may serve as a protection layer to prevent the chemical deformation of the core to maintain semiconductor properties, and/or a charging layer to impart electrophoresis properties to the quantum dot. The shell may be a single layer or a multilayer.

An example of the shell of the quantum dots may include a metal or non-metal oxide, a semiconductor compound, or any combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but embodiments are not limited thereto.

Also, examples of the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dots QD1 and QD2 may each independently have a full width at half maximum (FWHM) of a light emission wavelength spectrum equal to or less than about 45 nm. For example, the quantum dots QD1 and QD2 may each independently have a FWHM of a light emission wavelength spectrum equal to or less than about 40 nm. For example, the quantum dots QD1 and QD2 may each independently have a FWHM of a light emission wavelength spectrum equal to or less than about 30 nm. Color purity or color reproducibility may be improved in any of the above ranges. Light emitted through such quantum dot may be emitted in all directions so that a wide viewing angle may be improved.

The form of the quantum dots QD1 and QD2 is not particularly limited as long as and may be any form used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoplate particles, etc. The quantum dots QD1 and QD2 may control the color of emitted light according to the particle size thereof. Accordingly, the quantum dots may have various light emission colors such as blue, red, and green.

The light control layer CCL may further include a scatterer SP. The first light control part CCP1 may include the first quantum dot QD1 and the scatterer SP, and the second light control part CCP2 may include the second quantum dot QD2 and the scatterer SP. The third light control part CCP3 may not include any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include any one among TiO₂, ZnO, Al₂O₃, SiO₂, and hollow sphere silica, or may be a mixture of at least two materials selected from among TiO₂, ZnO, Al₂O₃, SiO₂, and hollow sphere silica. Scattering particles may scatter incident light and increase an amount of light provided to the outside. In an embodiment, the scatterer SP may be omitted. For example, at least one of the first light control part CCP1, or the second light control part CCP2 may not include the scattering particles.

The first light control part CCP1, the second light control part CCP2, and the third light control part CCP3 may each include the quantum dots QD1 and QD2 and base resins BR1, BR2, and BR3 that disperse the scatterer SP. The first light control part CCP1 may include the first quantum dot QD1 and the scatterer SP dispersed in a first base resin BR1, and the second light control part CCP2 may include the second quantum dot QD2 and the scatterer SP dispersed in a second base resin BR2. The third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control member CCM may further include buffer layers BFL1 and BFL2 that block moisture and oxygen and protect components disposed in upper and lower portions. The buffer layers BFL1 and BFL2 may include a first buffer layer BFL1 and a second buffer layer BFL2. The first buffer layer BFL1 may be disposed between the encapsulation layer TFE and the light control layer CCL. The second buffer layer BFL2 may be disposed between the light control layer CCL and the color filter layer CFL.

The first buffer layer BFL1 may prevent moisture and/or oxygen (hereinafter, referred to as “moisture/oxygen”) from penetrating into the light control layer CCL. The first buffer layer BFL1 may be disposed under the light control layer CCL to prevent the light control layer CCL from being exposed to moisture/oxygen. The first buffer layer BFL1 may further include at least one inorganic layer. That is, the first buffer layer BFL1 may include an inorganic material. For example, the first buffer layer BFL1 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a light transmittance, etc. The first barrier layer BFL1 may further include an organic film. The first buffer layer BFL1 may be composed of a single layer or multiple layers.

The second buffer layer BFL2 may be a protective layer for protecting the light control layer CCL and the color filter layer CFL. The second buffer layer BFL2 may be an inorganic material layer including at least one inorganic material from among silicon nitride, silicon oxide, and silicon oxynitride. The second buffer layer BFL2 may be formed of a single layer or multiple layers.

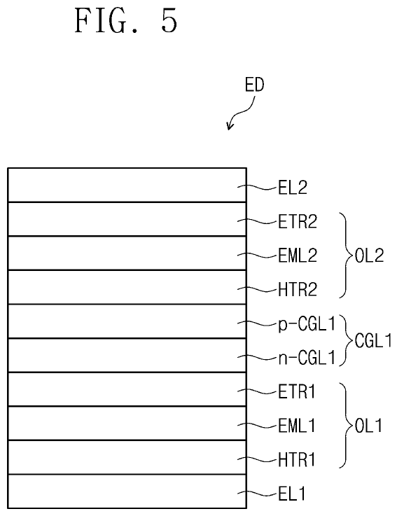

Hereinafter, FIGS. 5 to 8 are each a schematic cross-sectional view of a light emitting element according to an embodiment. The light emitting element ED may include a first electrode EL1, a second electrode EL2 facing the first electrode, and light emitting units OL1 and OL2 disposed between the first electrode EL1 and the second electrode EL2. The light emitting units OL1 and OL2 may include emission layers EML1 and EML2, respectively. Thus, the light emitting element ED according to an embodiment may include emission layers EML1 and EML2. The light emitting element ED may include a charge generation layer CGL1 disposed between the light emitting units OL1 and OL2. In an embodiment, the light emitting units OL1 and OL2 may respectively include hole transport regions HTR1 and HTR2, the emission layers EML1 and EML2, and electron transport regions ETR1 and ETR2, which are sequentially stacked.

Referring to FIG. 5, the light emitting element ED according to an embodiment may include the first electrode EL1, a first light emitting unit OL1, the charge generation layer CGL1, a second light emitting unit OL2, and the second electrode EL2, which are sequentially stacked. The first light emitting unit OL1 may include a first hole transport region HTR1, a first emission layer EML1, and a first electron transport region ETR1. The second light emitting unit OL2 may include a second hole transport region HTR2, a second emission layer EML2, and a second electron transport region ETR2.

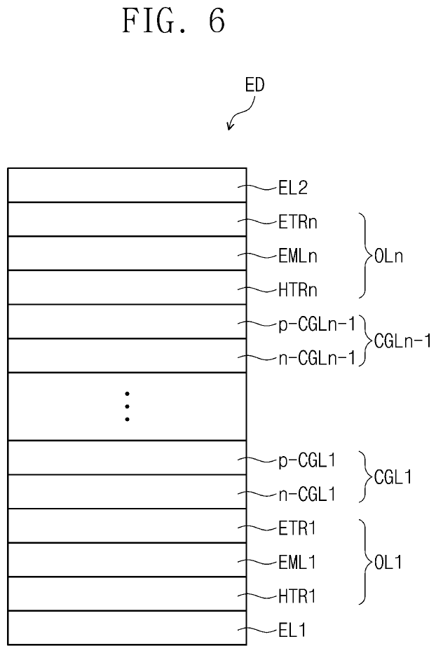

FIG. 5 illustrates that the light emitting element ED includes two light emitting units OL1 and OL2 and one charge generation layer CGL1 disposed therebetween, but embodiments are not limited thereto. For example, as illustrated in FIG. 6, the light emitting element ED according to an embodiment may include n light emitting units OL1 to OLn and n−1 charge generation layers CGL1 to CGLn−1 disposed between the n light emitting units OL1 to OLn. For example, n may be an integer of 3 or more. In the light emitting element ED according to an embodiment, the first light emitting unit OL1 may be directly disposed on the first electrode EL1, and the n-th light emitting unit OLn may be directly disposed below the second electrode EL2. The n-th light emitting unit OLn may include an n-th hole transport region HTRn, an n-th emission layer EMLn, and an n-th electron transport region ETRn, which are sequentially stacked.

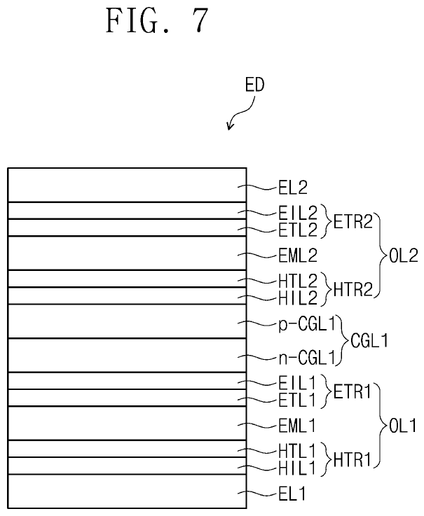

FIG. 7 illustrates a schematic cross-sectional view of the light emitting element ED according to an embodiment in which the first and second hole transport regions HTR1 and HTR2 respectively include the hole injection layers HIL1 and HIL2 and the hole transport layers HTL1 and HTL2, and the first and second electron transport regions ETR1 and ETR2 respectively include electron injection layers EIL1 and EIL2 and electron transport layers ETL1 and ETL2, as compared with FIG. 5.

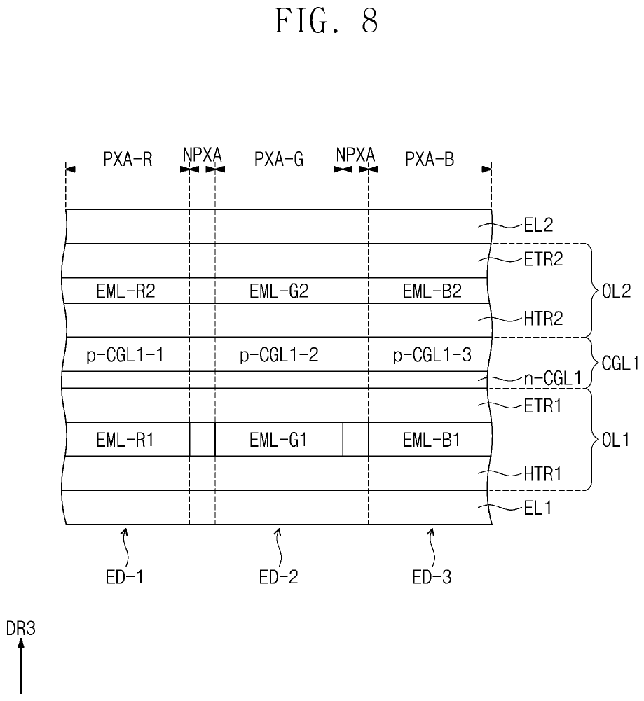

FIG. 8 is a view schematically illustrating light emitting elements according to an embodiment. FIG. 8 is a cross-sectional view of light emitting elements respectively corresponding to first to third pixel regions PXA-R, PXA-G, and PXA-B as compared with FIG. 5.

Referring to FIG. 8, first to third light emitting elements ED-1, ED-2, and ED-3 may each include a first electrode EL1, a second electrode EL2 facing the first electrode EL1, a first light emitting unit OL1 disposed between the first electrode EL1 and the second electrode EL2, a second light emitting unit OL2 disposed on the first light emitting unit OL1, and a charge generation layer CGL1 disposed between the first light emitting unit OL1 and the second light emitting unit OL2. The first light emitting element ED-1 may overlap a first pixel region PXA-R, the second light emitting element ED-2 may overlap a second pixel region PXA-G, and the third light emitting element ED-3 may overlap a third pixel region PXA-B.

In an embodiment, the first to third light emitting elements ED-1, ED-2, and ED-3 may each include the first electrode EL1, the first light emitting unit OL1, the charge generation layer CGL1, the second light emitting unit OL2, and the second electrode EL2, which are sequentially stacked on the substrate BS (see FIG. 4).

In an embodiment, the first light emitting unit OL1 may include a first red light emitting unit overlapping the first pixel region PXA-R, a first green light emitting unit overlapping the second pixel region PXA-G, and a first blue light emitting unit overlapping the third pixel region PXA-B. The second light emitting unit OL2 may include a second red light emitting unit overlapping the first pixel region PXA-R, a second green light emitting unit overlapping the second pixel region PXA-G, and a second blue light emitting unit overlapping the third pixel region PXA-B. Accordingly, the first red light emitting unit and the second red light emitting unit may correspond to the first pixel region PXA-R. The first green light emitting unit and the second green light emitting unit may correspond to the second pixel region PXA-G, and the first blue light emitting unit and the second blue light emitting unit may correspond to the third pixel region PXA-B.

In an embodiment, the first light emitting unit OL1 may include a first hole transport region HTR1, first emission layers EML-R1, EML-G1, and EML-B1, and a first electron transport region ETR1. For example, the first red light emitting unit may include the first hole transport region HTR1, a first red emission layer EML-R1, and the first electron transport region ETR1, which are sequentially stacked on the first electrode EL1. The first green light emitting unit may include the first hole transport region HTR1, a first green emission layer EML-G1, and the first electron transport region ETR1, which are sequentially stacked on the first electrode EL1. The first blue light emitting unit may include the first hole transport region HTR1, a first blue emission layer EML-B1, and the first electron transport region ETR1, which are sequentially stacked on the first electrode EL1.

In an embodiment, the first hole transport region HTR1 and the second electron transport region ETR1 may be provided as a common layer overlapping all of the first to third pixel regions PXA-R, PXA-G, and PXA-B and a non-pixel region NPXA. The first red emission layer EML-R1, the first green emission layer EML-G1, and the first blue emission layer EML-B1 may be provided as patterned layers overlapping the first to third pixel regions PXA-R, PXA-G, and PXA-B, respectively, and not overlapping the non-pixel region NPXA.

The charge generation layer CGL1 may be disposed between the first light emitting unit OL1 and the second light emitting unit OL2 to adjust a balance of holes and/or charges between the first light emitting unit OL1 and the second light emitting unit OL2. For example, the charge generation layer CGL1 may facilitate the movement of holes and/or charges between the first light emitting unit OL1 and the second light emitting unit OL2. The charge generation layer CGL1 may include an n-type charge generation layer n-CGL1 and a p-type charge generation layer p-CGL1.

In an embodiment, the n-type charge generation layer n-CGL1 may be disposed on the first light emitting unit OLL. The n-type charge generation layer n-CGL1 may be provided as a common layer overlapping all of the first to third pixel regions PXA-R, PXA-G, and PXA-B and the non-pixel region NPXA. The p-type charge generation layer p-CGL1 may be disposed on the n-type charge generation layer n-CGL1 and may be provided as a patterned layer. For example, the p-type charge generation layer p-CGL1 may include first to third p-type charge generation layers respectively overlapping the first to third pixel regions PXA-R, PXA-G, and PXA-B. The first to third p-type charge generation layers may overlap the first to third pixel regions PXA-R, PXA-G, and PXA-B, respectively, and may not overlap the non-pixel region NPXA.

The second light emitting unit OL2 may be disposed on the charge generation layer CGL1 and may include a second hole transport region HTR2, second emission layers EML-R2, EML-G2, and EML-B2, and a second electron transport region ETR2. For example, the second red light emitting unit may include a second hole transport region HTR2, a second red emission layer EML-R2, and a second electron transport region ETR2, which are sequentially stacked on the charge generation layer CGL1. The second green light emitting unit may include the second hole transport region HTR2, a second green emission layer EML-G2, and the second electron transport region ETR2, which are sequentially stacked on the charge generation layer CGL1. The second blue light emitting unit may include the second hole transport region HTR2, a second blue emission layer EML-B2, and the second electron transport region ETR2, which are sequentially stacked on the charge generation layer CGL1.

In the third light emitting element ED-3 according to an embodiment, at least one of the first blue emission layer EML-B1 or the second blue emission layer EML-B2 may include a hole transporting host, an electron transporting host, a phosphorescent sensitizer, and a first fluorescent dopant, which will be described later.

The following description is based on the light emitting element ED illustrated in FIG. 5, and the description of the light emitting element ED based on FIG. 5 may be equally applied to FIGS. 6 to 8. For example, the descriptions of the first and second hole transport regions HTR1 and HTR2 may be equally applied to the n-th hole transport region HTRn. The descriptions of the first and second electron transport regions ETR1 and ETR2 may be equally applied to the n-th electron transport region ETRn. The descriptions of the first and second emission layers EML1 and EML2 may be equally applied to the n-th emission layer EMLn.

In the light emitting element ED according to an embodiment, the first electrode EL1 has conductivity. The first electrode EL1 may be formed of a metal material, a metal alloy, or a conductive compound. The first electrode EL1 may be an anode or a cathode. However, embodiments are not limited thereto. The first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. Embodiments are not limited thereto, and the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The first and second hole transport regions HTR1 and HTR2 may be provided on the first electrode EL1. The first hole transport region HTR1 may be disposed closer to the first electrode EL1 than the second hole transport region HTR2. The first and second hole transport regions HTR1 and HTR2 may each independently be a layer consisting of a single material, a layer including different materials, or a structure including multiple layers including different materials.

The first and second hole transport regions HTR1 and HTR2 may include at least one of hole injection layers HIL1 and HIL2, hole transport layers HTL1 and HTL2, or electron blocking layers (not shown). The first hole transport region HTR1 may include at least one of a first hole injection layer HIL1, a first hole transport layer HTL1, or a second electron blocking layer (not shown). The second hole transport region HTR2 may be disposed on the first hole transport region HTR1 and may include at least one of a second hole injection layer HIL2, a second hole transport layer HTL2, and a second electron blocking layer (not shown), which are stacked. In embodiments, the first and second hole transport regions HTR1 and HTR2 may each include multiple stacked hole transport layers.

In another embodiment, the first and second hole transport regions HTR1 and HTR2 may each independently have a single-layered structure of the hole injection layers HIL1 and HIL2 or the hole transport layers HTL1 and HTL2 or may have a single-layered structure formed of a hole injection material and a hole transport material. The hole transport regions HTR1 and HTR2 may each have a single-layered structure formed of multiple different materials, or a structure in which hole injection layers HIL1 and HIL2/hole transport layers HTL1 and HTL2, hole injection layers HIL1 and HIL2/hole transport layers HTL1 and HTL2/buffer layers (not shown), hole injection layers HIL1 and HIL2/buffer layers (not shown), hole transport layers HTL1 and HTL2/buffer layers (not shown), or hole injection layers HIL1 and HIL2/hole transport layers HTL1 and HTL2/electron blocking layers (not shown) are respectively stacked in order from the first electrode EL1, but embodiments are not limited thereto.

The first and second hole transport regions HTR1 and HTR2 may each be formed using various methods such as a vacuum deposition method, a spin coating method, a cast method, a Langmuir-Blodgett (LB) method, an inkjet printing method, a laser printing method, and a laser induced thermal imaging (LITI) method.

The first and second hole transport regions HTR1 and HTR2 may each include a compound represented by Formula H-1:

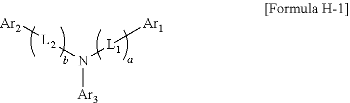

In Formula H-1, L₁ and L₂ may each independently be a direct linkage, a substituted or unsubstituted arylene group having 6 to 30 ring-forming carbon atoms or a substituted or unsubstituted heteroarylene group having 2 to 30 ring-forming carbon atoms. In Formula H-1, a and b may each independently be an integer from 0 to 10. In case that a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 above may be a diamine compound in which at least one of Ar₁ to Ar₃ includes an amine group as a substituent. In yet another embodiment, the compound represented by Formula H-1 above may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compounds selected from Compound Group H. However, the compounds listed in Compound Group H are only examples, and the compounds represented by Formula H-1 are not limited to Compound Group H:

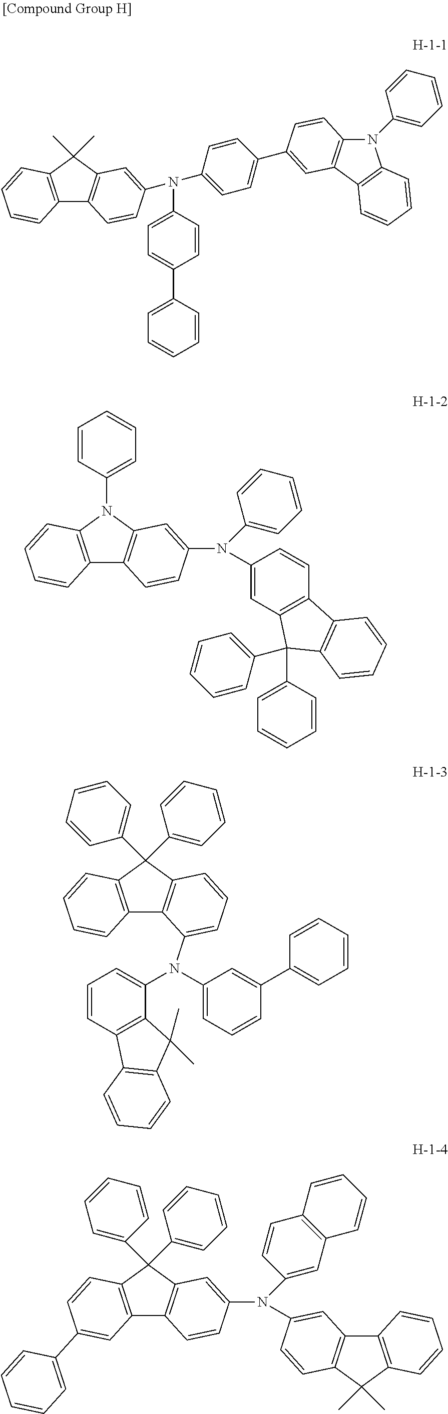 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

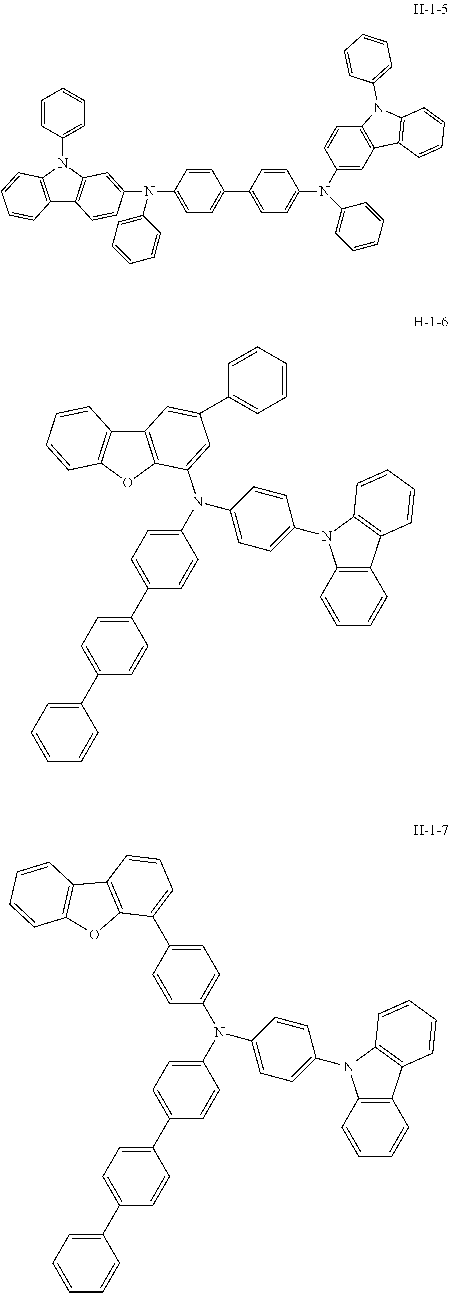 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

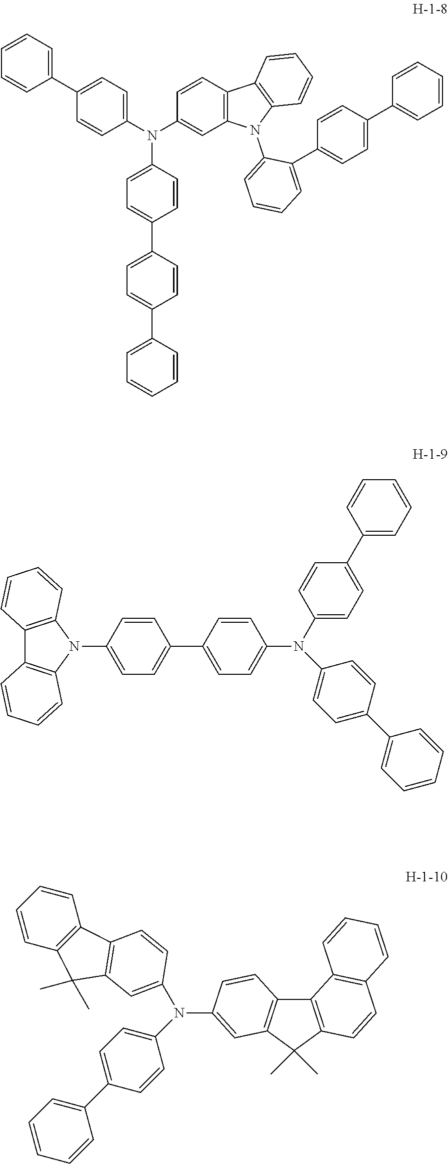 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

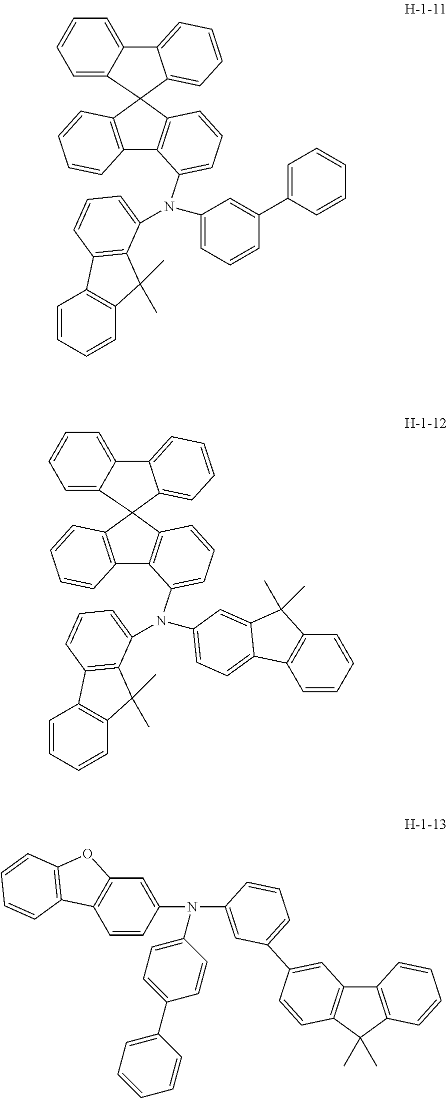 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

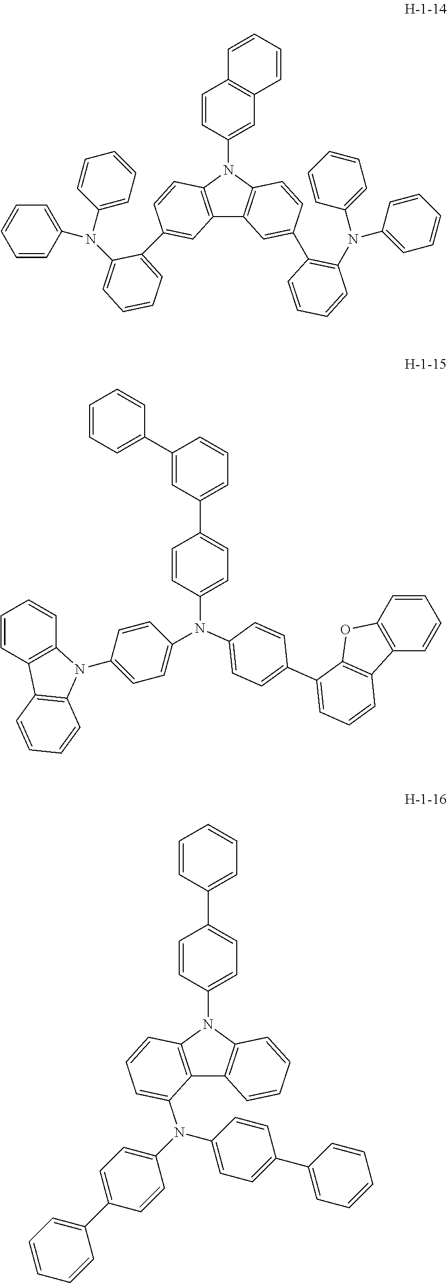 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

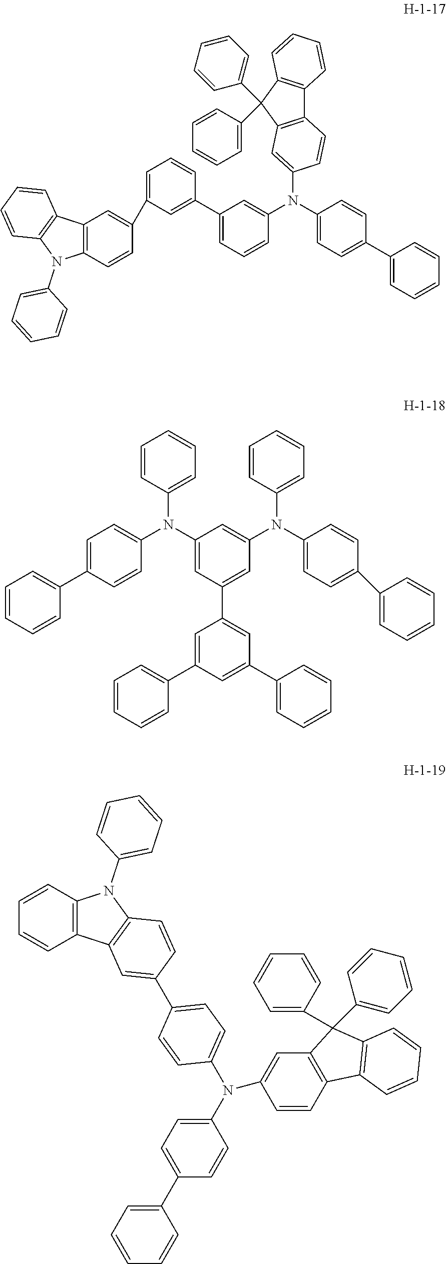 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The first and second hole transport regions HTR1 and HTR2 may each independently include a phthalocyanine compound such as copper phthalocyanine; N¹,N¹-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The first and second hole transport regions HTR1 and HTR2 may each independently include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The first and second hole transport regions HTR1 and HTR2 may each independently include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The first and second hole transport regions HTR1 and HTR2 may each independently include the above-described compounds of the hole transport region in at least one of the hole injection layers HIL1 and HIL2, the hole transport layers HTL1 and HTL2, or the electron blocking layer (not shown).

The first and second hole transport regions HTR1 and HTR2 may each independently have a thickness in a range of about 100 Å to about 10,000 Å. For example, the first and second hole transport regions HTR1 and HTR2 may each independently have a thickness in a range of about 100 Å to about 5,000 Å. In case that the first and second hole transport regions HTR1 and HTR2 respectively include the hole injection layers HIL1 and HIL2, the hole injection layers HIL1 and HIL2 may each independently have a thickness in a range of about 30 Å to about 1,000 Å. In case that the first and second hole transport regions HTR1 and HTR2 respectively include the hole transport layers HTL1 and HTL2, the electron transport layers HTL1 and HTL2 may each independently have a thickness in a range of about 30 Å to about 1,000 Å. For example, in case that the first and second hole transport regions HTR1 and HTR2 respectively include the electron blocking layers (not shown), the electron blocking layers (not shown) may each have a thickness in a range of about 10 Å to about 1,000 Å. If the thicknesses of the hole transport regions HTR1 and HTR2, the hole injection layers HIL1 and HIL2, and the electron blocking layers (not shown) satisfy the above-described ranges, satisfactory hole transport properties may be obtained without a substantial increase in driving voltage.

The first hole transport region HTR1 and the second hole transport region HTR2 may each independently further include, in addition to the above-described materials, a charge generating material to increase conductivity. The charge generating material may be dispersed uniformly or non-uniformly in the first hole transport region HTR1 and the second hole transport region HTR2. The charge generating material may be, for example, a p-dopant. The p-dopant may include at least one of a halogenated metal compound, a quinone derivative, a metal oxide, or a cyano group-containing compound, but embodiments are not limited thereto.

For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the first hole transport region HTR1 and the second hole transport region HTR2 may each independently further include at least one of a buffer layer (not shown) or an electron blocking layer (not shown) in addition to the hole injection layer HIL and the hole transport layer HTL. The buffer layer (not shown) may compensate for a resonance distance according to the wavelength of light emitted from the emission layers EML1 and EML2 and may thus increase light emission efficiency. Materials that may be included in the first hole transport region HTR1 and the second hole transport region HTR2 may be used as materials included in the buffer layer (not shown). The electron blocking layer (not shown) may prevent electron injection from the first electron transport region ETR1 and the second electron transport region ETR2 into the first hole transport region HTR1 and the second hole transport region HTR2, respectively.

The emission layers EML1 and EML2 are provided on the hole transport regions HTR1 and HTR2, respectively. For example, the first emission layer EML1 may be provided on the first hole transport region HTR1, and the second emission layer EML2 may be provided on the second hole transport region HTR2. The first and second emission layers EML1 and EML2 may each independently have a thickness in a range of about 100 Å to about 1,000 Å. For example, the first and second emission layers EML1 and EML2 may each independently have a thickness in a range of about 100 Å to about 300 Å. The first and second emission layers EML1 and EML2 may each independently be a layer consisting of a single material, a layer including different materials, or a structure including multiple layers including different materials.

In an embodiment, at least one of the emission layers EML1 and EML2 may include a hole transporting host, an electron transporting host, a phosphorescent sensitizer, and a first fluorescent dopant. In case that the light emitting element ED includes the first emission layer EML1 and the second emission layer EML2, at least one of the first emission layer EML1 or the second emission layer EML2 may include a hole transporting host, an electron transporting host, a phosphorescent sensitizer, and a first fluorescent dopant.

For example, one of the first emission layer EML1 and the second emission layer EML2 may include a hole transporting host, an electron transporting host, a phosphorescent sensitizer, and a first fluorescent dopant, and the other may include a hole transporting host, an electron transporting host, and a second fluorescent dopant. In the light emitting element ED according to an embodiment, the first emission layer EML1 and the second emission layer EML2 may each independently include a hole transporting host, an electron transporting host, a phosphorescent sensitizer, and a first fluorescent dopant. The hole transporting host, the electron transporting host, the phosphorescent sensitizer, and the first fluorescent dopant included in each of the first emission layer EML1 and the second emission layer EML2 may be the same as or different from each other.

In the emission layers EML1 and EML2 including the hole transporting host, the electron transporting host, the phosphorescent sensitizer, and the first fluorescent dopant, the energy may be transferred from the hole transporting host and the electron transporting host to the phosphorescent sensitizer, and the energy may be transferred from the phosphorescent sensitizer to the first fluorescent dopant. The emission layers EML1 and EML2 according to an embodiment may emit light by transferring energy from the phosphorescent sensitizer to the first fluorescent dopant. In case that the energy is transferred from the phosphorescent sensitizer to the first fluorescent dopant, Forster energy transfer and Dexter energy transfer may occur at the same time.

In the emission layers EML1 and EML2 including the hole transporting host, the electron transporting host, and the second fluorescent dopant, the energy may be transferred directly from the hole transporting host and the electron transporting host to the second fluorescent dopant. The emission layers EML1 and EML2 including the second fluorescent dopant may further include the phosphorescent sensitizer together with the hole transporting host and the electron transporting host. Energy may be transferred from the hole transporting host and the electron transporting host to the phosphorescent sensitizer, and energy may be transferred from the phosphorescent sensitizer to the second fluorescent dopant.

In an embodiment, the first fluorescent dopant may include a pentacyclic fused ring core containing one boron atom (B) and two heteroatoms as ring-forming atoms. In the first fluorescent dopant according to an embodiment, the core may have a structure in which first to third aromatic rings are fused via one boron atom and two heteroatoms. The fused ring core of the first fluorescent dopant may contain a nitrogen atom (N), an oxygen atom (O), and/or a sulfur atom (S) as heteroatoms. For example, the first fluorescent dopant may contain one boron atom and two nitrogen atoms in the fused ring core as ring-forming atoms. The first to third aromatic rings may be substituted or unsubstituted benzene rings.

The first aromatic ring and the second aromatic ring may be symmetric with respect to the boron atom in the fused ring core. However, embodiments are not limited thereto, and the first aromatic ring and the second aromatic ring may be asymmetric with respect to the boron atom in the fused ring core. The third aromatic ring may be linked to all of one boron atom and two heteroatoms in the fused ring core.

In an embodiment, the first fluorescent dopant may be a polycyclic compound including a substituent having a low triplet state energy level (T1). The first fluorescent dopant may include at least one substituent having a low triplet state energy level (T1). The substituent having a low triplet state energy level (T1) may be linked to the fused ring core of the first fluorescent dopant. The substituent having a low triplet state energy level (T1) may contribute to lowering the triplet state energy level of the first fluorescent dopant. For example, the substituent having a low triplet state energy level (T1) may be a pyrenyl group. The pyrenyl group may be substituted at an amine group and linked to the fused ring core of the first fluorescent dopant. Accordingly, the emission layers EML1 and EML2 including the first fluorescent dopant may each emit blue light.

In an embodiment, the first fluorescent dopant may be a polycyclic compound represented by Formula 1. In the polycyclic compound represented by Formula 1 according to an embodiment, a benzene ring to which R₁ to R₃ are linked may correspond to the above-described third aromatic ring. A benzene ring to which R₄ to R₇ are linked may correspond to the above-described first aromatic ring, and a benzene ring to which R₈ to R₁₁ are linked may correspond to the above-described second aromatic ring. In the polycyclic compound represented by Formula 1, the pentacyclic fused ring core containing one boron atom and two heteroatoms as ring-forming atoms may exhibit multiple resonance characteristics.

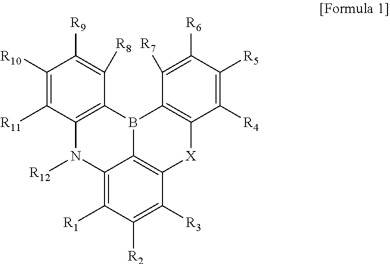

In Formula 1, X may be N(R₁₃), O, or S. In an embodiment, X may be N(R₁₃). Therefore, the first fluorescent dopant according to an embodiment may include a fused ring core containing one boron atom and two heteroatoms as ring-forming atoms.

In Formula 1, R₁ to R₁₃ may each independently be a hydrogen atom, a deuterium atom, a substituted or unsubstituted amine group, or a substituted or unsubstituted aryl group having 3 to 30 ring-forming carbon atoms. In an embodiment, R₁ to R₁₃ may each independently be a hydrogen atom, a deuterium atom, a substituted or unsubstituted amine group, a substituted or unsubstituted phenyl group, a substituted or unsubstituted biphenyl group, or a substituted or unsubstituted terphenyl group. For example, R₁ to R₁₁ may each independently be a hydrogen atom, a deuterium atom, a substituted or unsubstituted amine group, or a substituted or unsubstituted phenyl group. For example, R₁₂ and R₁₃ may each independently be a substituted or unsubstituted biphenyl group or a substituted or unsubstituted terphenyl group. For example, R₁ to R₁₃ may each independently be a deuterium atom or an aryl group having 6 to 30 ring-forming carbon atoms.

In an embodiment, at least one of R₁ to R₁₁ may each independently be an amine group substituted with an aryl group having 6 to 30 ring-forming carbon atoms. For example, at least one of R₁ to R₁₁ may each independently be an amine group substituted with at least one pyrenyl group. In an embodiment, at least one of R₁ to Ru may each independently be a moiety represented by Formula 2. For example, at least one of R₂, R₅, or R₁₀ may each independently be a moiety represented by Formula 2. The moiety represented by Formula 2 may correspond to a substituent having a low triplet state energy level (T₁) as described above.

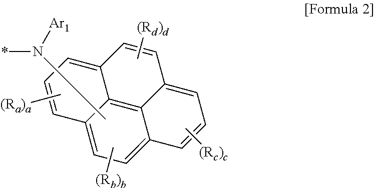

In Formula 2, Ar₁ may be a substituted or unsubstituted aryl group having 3 to 30 ring-forming carbon atoms. For example, Ar₁ may be a substituted or unsubstituted phenyl group.

In Formula 2, Rₐ to R_{d} may each independently be a hydrogen atom or a deuterium atom. For example, Rₐ to R_{d} may each be a hydrogen atom. In another example, at least one of Rₐ to R_{d} may each be a deuterium atom, and the remainder of Rₐ to R_{d} may each be a hydrogen atom. In Formula 2, a and c may each independently be an integer from 0 to 3; and b and d may each independently be an integer from 0 to 2. In case that a or c is 2 or greater, multiple Rₐ groups or multiple R_{c} groups may each be the same or at least one may be different from the remainder of the multiple Rₐ groups or multiple R_{c} groups. A case where a and c are each 0 may be the same as a case where each of a and c is 3 and three Rₐ groups and three R_{c} groups are all hydrogen atoms. In case that b or d is 2, two Re groups or two R_{d} groups may each be the same or different. A case where each of b and d is 0 may be the same as a case where each of b and d is 2 and two Re groups and two R_{d} groups are all hydrogen atoms.

The first fluorescent dopant according to an embodiment may include at least one moiety represented by Formula 2, and thus may exhibit a characteristic in which the triplet state energy level (T1_{F1}) is very low compared to the singlet state energy level (S1_{F1}). The first fluorescent dopant according to an embodiment may have a difference (E_{ST,F1}) between the singlet state energy level and the triplet state energy level equal to or greater than about 0.4 eV. For example, a difference (E_{ST,F1}) between a triplet state energy level of the first fluorescent dopant and a triplet state energy level of the first fluorescent dopant may be in a range of about 0.4 eV to about 1.0 eV.

In the first fluorescent dopant having a difference (E_{ST,F1}) between the singlet state energy level and the triplet state energy level equal to or greater than about 0.4 eV, excitons may not readily move from the triplet state to the singlet state. Accordingly, in the first fluorescent dopant, reverse intersystem crossing (RISC) does not occur, and thus the emission of the thermally activated delayed fluorescence (TADF) may not occur.

The light emitting element ED according to an embodiment may exhibit a long service life characteristic by including the first fluorescent dopant having a difference between the singlet state energy level and the triplet state energy level equal to or greater than about 0.4 eV in at least one of the emission layers EML1 and EML2.

The first fluorescent dopant includes an amine group substituted with a pyrenyl group, and thus a difference between the singlet state energy level and the triplet state energy level may be in a range of about 0.4 eV to about 1.0 eV. The pyrenyl group has a characteristic in which the triplet state energy level is lower than the singlet state energy level, and the first fluorescent dopant including the pyrenyl group may exhibit a characteristic in which the triplet state energy level is lower than the singlet state energy level. Accordingly, the first fluorescent dopant according to an embodiment may exhibit a characteristic in which the triplet state energy level is lower than the singlet state energy level by about 0.4 eV to about 1.0 eV.

In an embodiment, a first fluorescent dopant includes a substituent having a low triplet state energy level (T1), and thus has a narrow full width of half maximum and is advantageous in terms of color purity, thereby contributing to an increase in efficiency of the light emitting element ED. For example, a first fluorescent dopant may have a full width at half maximum (FWHM) of an emission wavelength spectrum equal to or less than about 25 nm. Since the FWHM of the light emitted from the first fluorescent dopant is equal to or less than about 25 nm, the first fluorescent dopant may contribute to improving color purity and color reproducibility of the light emitting element ED.

In an embodiment, a first fluorescent dopant may have a molar extinction coefficient equal to or greater than about 2×10⁵M⁻¹cm⁻¹. In case that the molar extinction coefficient of a first fluorescent dopant is equal to or greater than about 2×10⁵M⁻¹ cm⁻¹, the energy transfer from the phosphorescent sensitizer to the first fluorescent dopant may be facilitated, and thus the service life of the light emitting element ED may be improved.

In an embodiment, a first fluorescent dopant may include at least one compound selected from Compound Group 1. The light emitting element ED may include at least one compound selected from Compound Group 1 in at least one of emission layers EML1 and EML2.

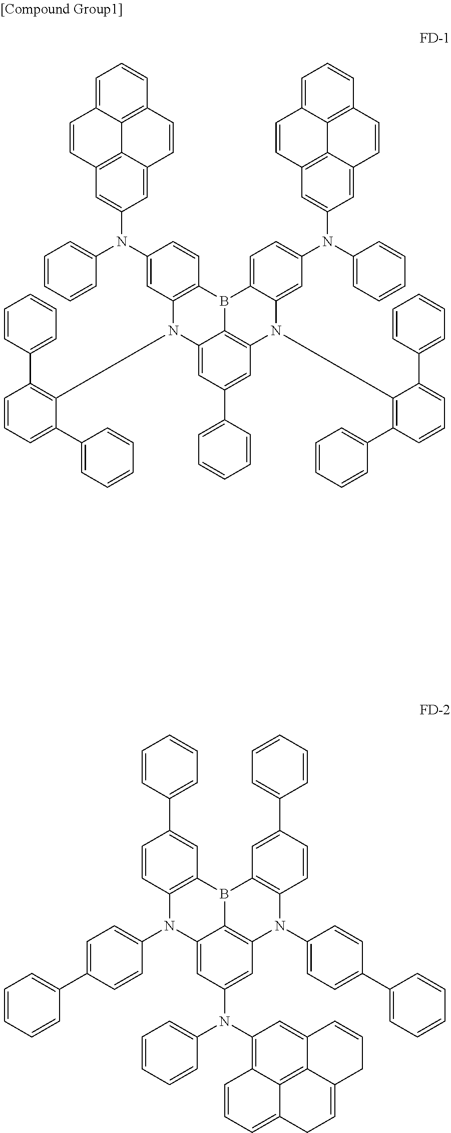 [SMILES: c1ccc(-c2cc3c4c(c2)N(c2c(-c5ccccc5)cccc2-c2ccccc2)c2cc(N(c5ccccc5)c5cc6ccc7cccc8ccc(c5)c6c78)ccc2B4c2ccc(N(c4ccccc4)c4cc5ccc6cccc7ccc(c4)c5c67)cc2N3c2c(-c3ccccc3)cccc2-c2ccccc2)cc1 ; C1=Cc2cc(N(c3ccccc3)c3cc4c5c(c3)N(c3ccc(-c6ccccc6)cc3)c3ccc(-c6ccccc6)cc3B5c3cc(-c5ccccc5)ccc3N4c3ccc(-c4ccccc4)cc3)c3cccc4c3c2C(=CC4)C1]

In an embodiment, a second fluorescent dopant may be different from the first fluorescent dopant. a second fluorescent dopant may be a donor-acceptor (DA) type fluorescent dopant. a second fluorescent dopant may have a difference between the singlet state energy level and the triplet state energy level less than the first fluorescent dopant. For example, a second fluorescent dopant may have a difference (E_{ST,F2}) between the singlet state energy level and the triplet state energy level equal to or less than about 0.3 eV. In the second fluorescent dopant, the reverse intersystem crossing (RISC) from the triplet state to the singlet state having higher energy occurs, and thus the emission of the thermally activated delayed fluorescence (TADF) may occur.

In an embodiment, a second fluorescent dopant may include the fused ring core containing one boron atom (B) and two nitrogen atoms (N) as ring-forming atoms. In the polycyclic compound according to an embodiment, the fused ring core may be a structure in which a first to third aromatic rings are fused via one boron atom and two nitrogen atoms. The first to third aromatic rings may be substituted or unsubstituted benzene rings.

The first aromatic ring and the second aromatic ring may be symmetric with respect to the boron atom in the fused ring core. However, embodiments are not limited thereto, and the first aromatic ring and the second aromatic ring may be asymmetric with respect to the boron atom in the fused ring core. The third aromatic ring may be linked to all of one boron atom and two nitrogen atoms in the fused ring core.

For example, the second fluorescent dopant may include Compound DA1, but embodiments are not limited thereto.

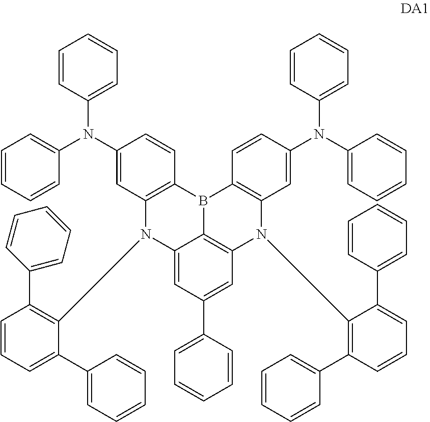 [SMILES: c1ccc(-c2cc3c4c(c2)N(c2c(-c5ccccc5)cccc2-c2ccccc2)c2cc(N(c5ccccc5)c5ccccc5)ccc2B4c2ccc(N(c4ccccc4)c4ccccc4)cc2N3c2c(-c3ccccc3)cccc2-c2ccccc2)cc1]

In the emission layers EML1 and EML2, the hole transporting host and the electron transporting host may form an exciplex. The triplet state energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy level of the exciplex formed by the hole transporting host and the electron transporting host may be about 2.4 eV to about 3.0 eV. The triplet energy of the exciplex may be a value smaller than an energy gap of each host material. The exciplex may have a triplet energy equal to or less than about 3.0 eV, which is an energy gap between the hole transporting host and the electron transporting host. However, this is only an example, and embodiments are not limited thereto.

In an embodiment, the hole transporting host may include any one of compound selected from Compound Group 2. The emission layers EML1 and EML2 may each independently include at least one compound selected from Compound Group 2 as the hole transporting host. The hole transporting host included in each of the emission layers EML1 and EML2 may be the same or different.

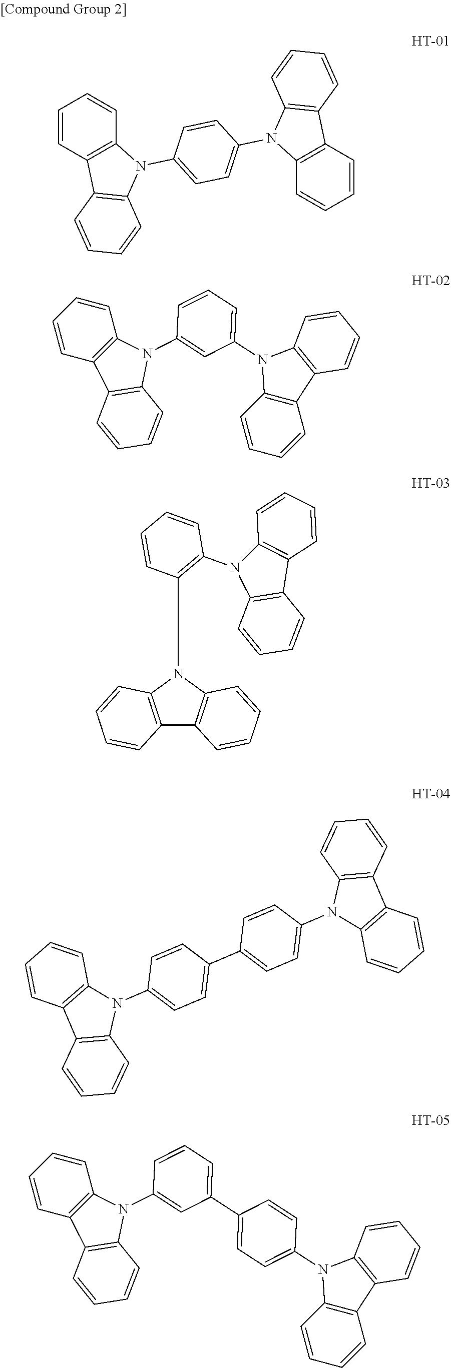

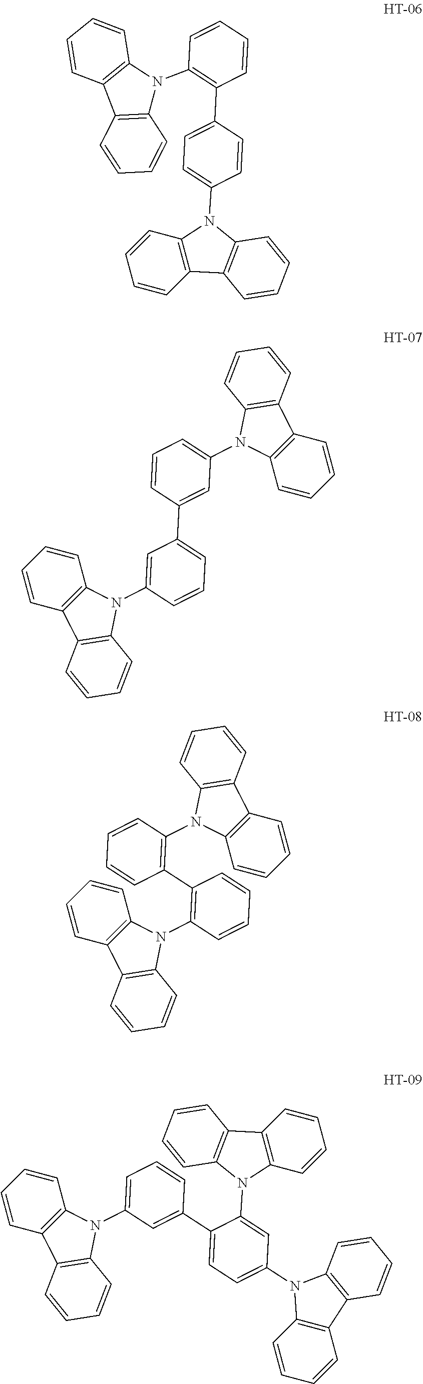 [SMILES: c1ccc(-n2c3ccccc3c3ccccc32)c(-c2ccc(-n3c4ccccc4c4ccccc43)cc2)c1 ; c1cc(-c2cccc(-n3c4ccccc4c4ccccc43)c2)cc(-n2c3ccccc3c3ccccc32)c1 ; c1ccc(-n2c3ccccc3c3ccccc32)c(-c2ccccc2-n2c3ccccc3c3ccccc32)c1 ; c1cc(-c2ccc(-n3c4ccccc4c4ccccc43)cc2-n2c3ccccc3c3ccccc32)cc(-n2c3ccccc3c3ccccc32)c1]

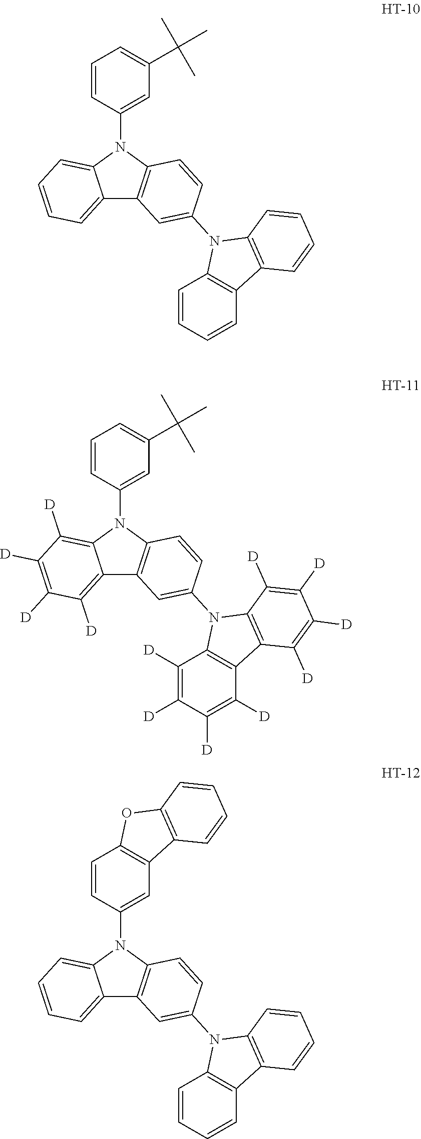

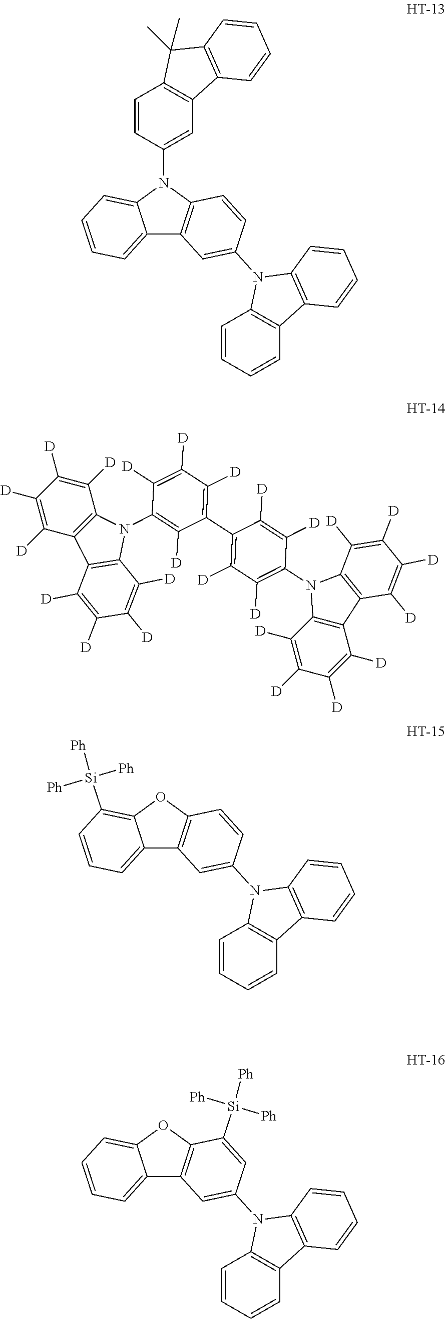 [SMILES: CC1(C)c2ccccc2-c2cc(-n3c4ccccc4c4cc(-n5c6ccccc6c6ccccc65)ccc43)ccc21 ; [2H]c1c([2H])c(-c2c([2H])c([2H])c(-n3c4c([2H])c([2H])c([2H])c([2H])c4c4c([2H])c([2H])c([2H])c([2H])c43)c([2H])c2[2H])c([2H])c(-n2c3c([2H])c([2H])c([2H])c([2H])c3c3c([2H])c([2H])c([2H])c([2H])c32)c1[2H] ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

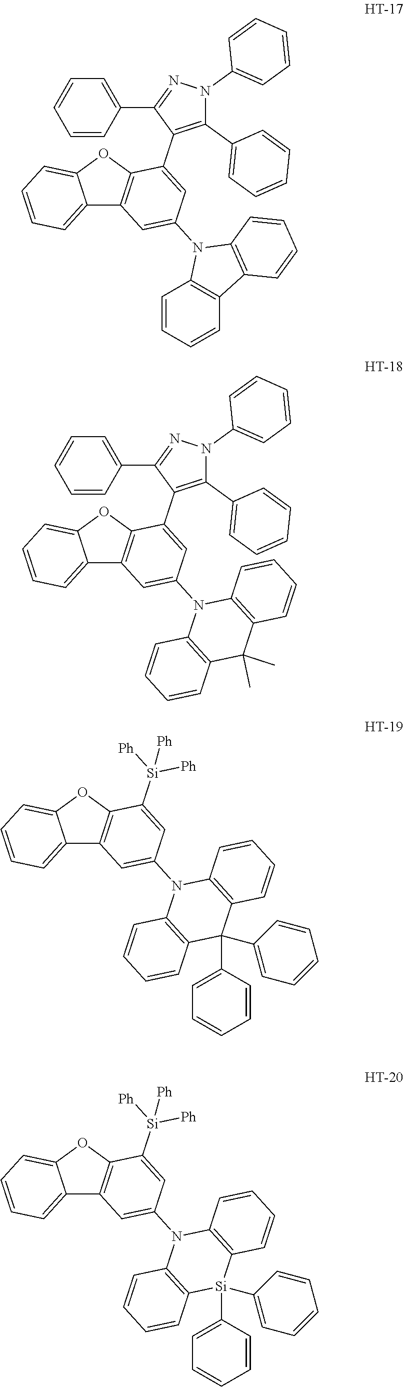

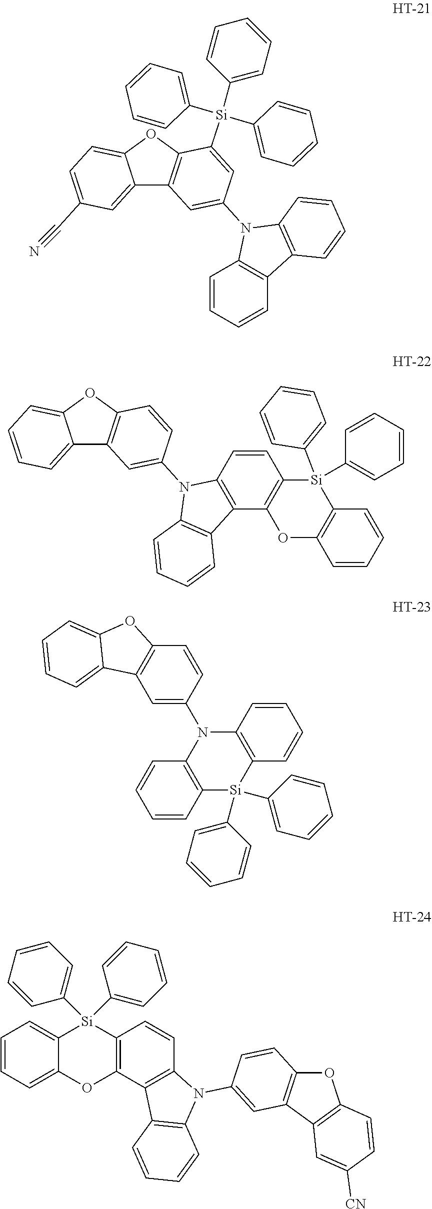 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

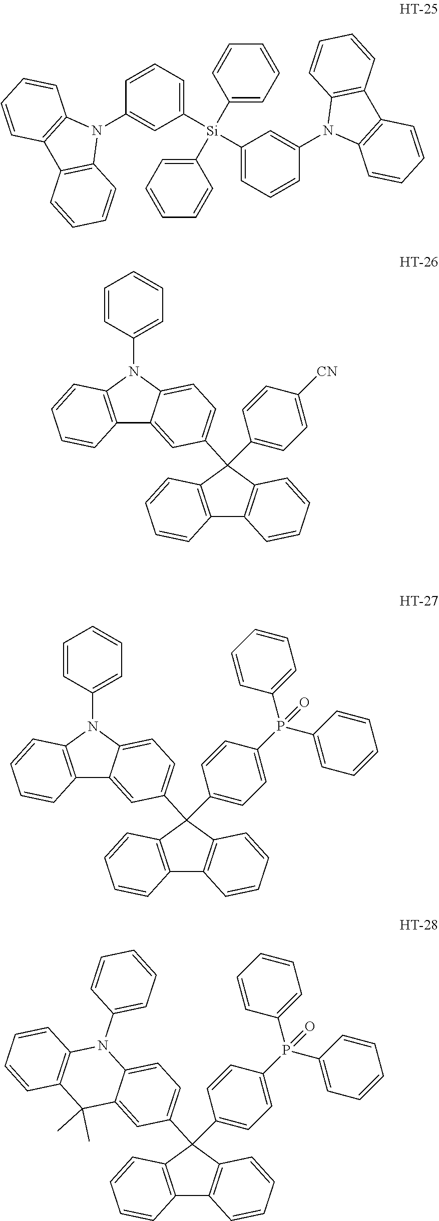 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

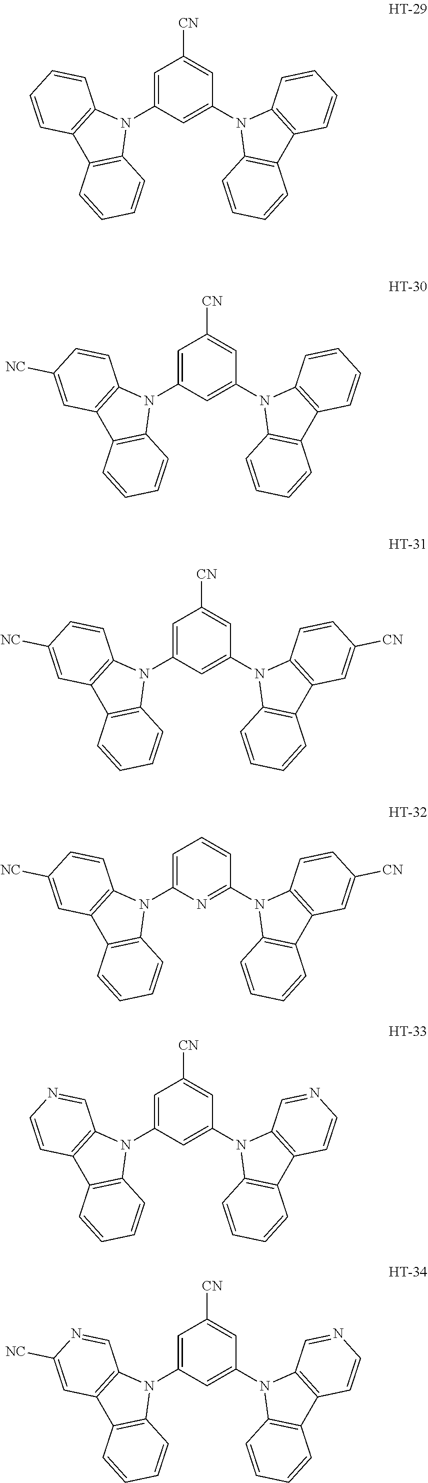 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3ccncc32)cc(-n2c3ccccc3c3cc(C#N)ncc32)c1]

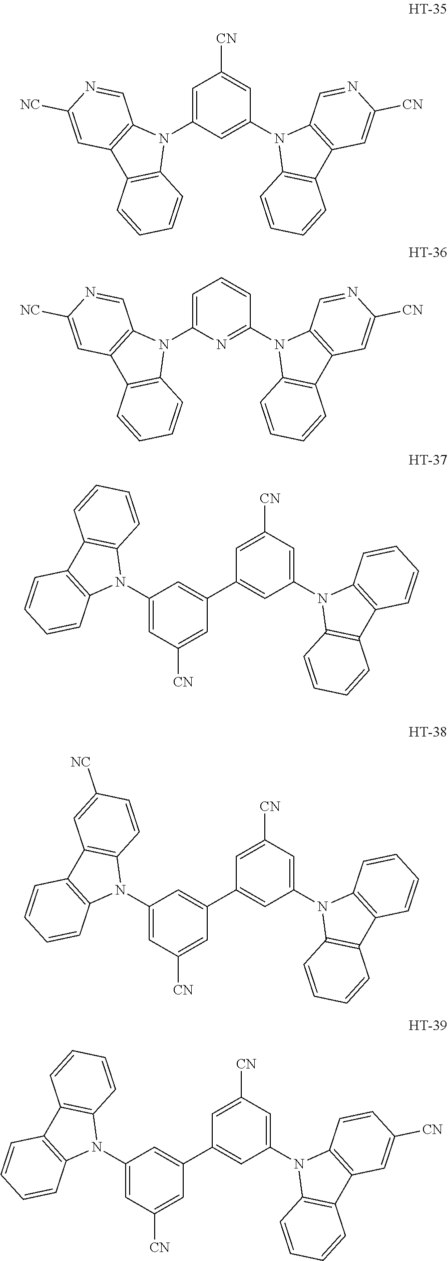 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cc(C#N)cc(-n3c4ccccc4c4cc(C#N)ccc43)c2)cc(-n2c3ccccc3c3ccccc32)c1 ; N#Cc1cc(-c2cc(C#N)cc(-n3c4ccccc4c4cc(C#N)ccc43)c2)cc(-n2c3ccccc3c3ccccc32)c1]

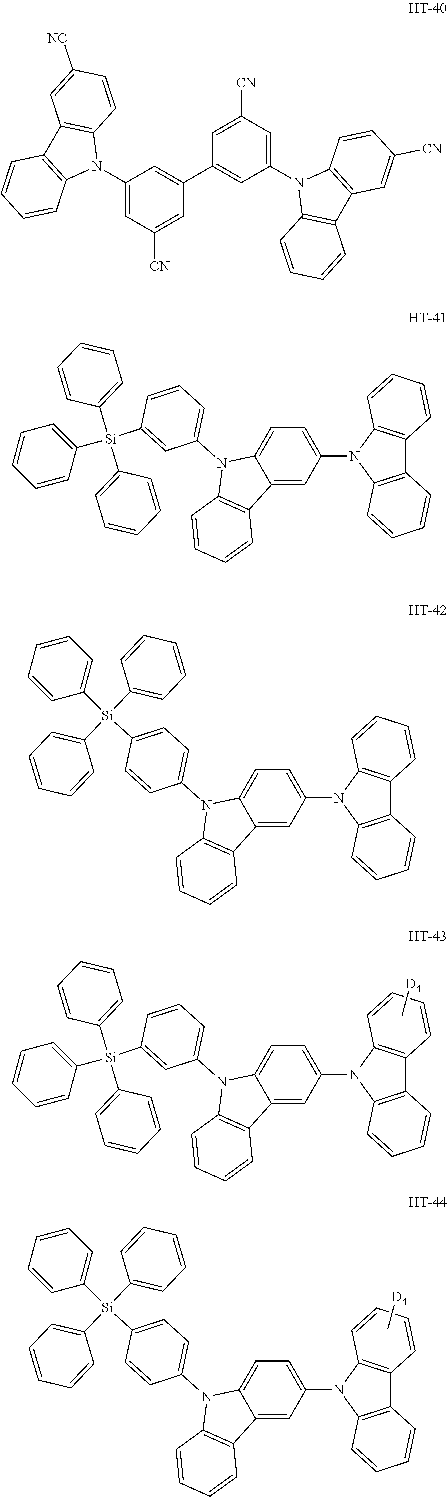

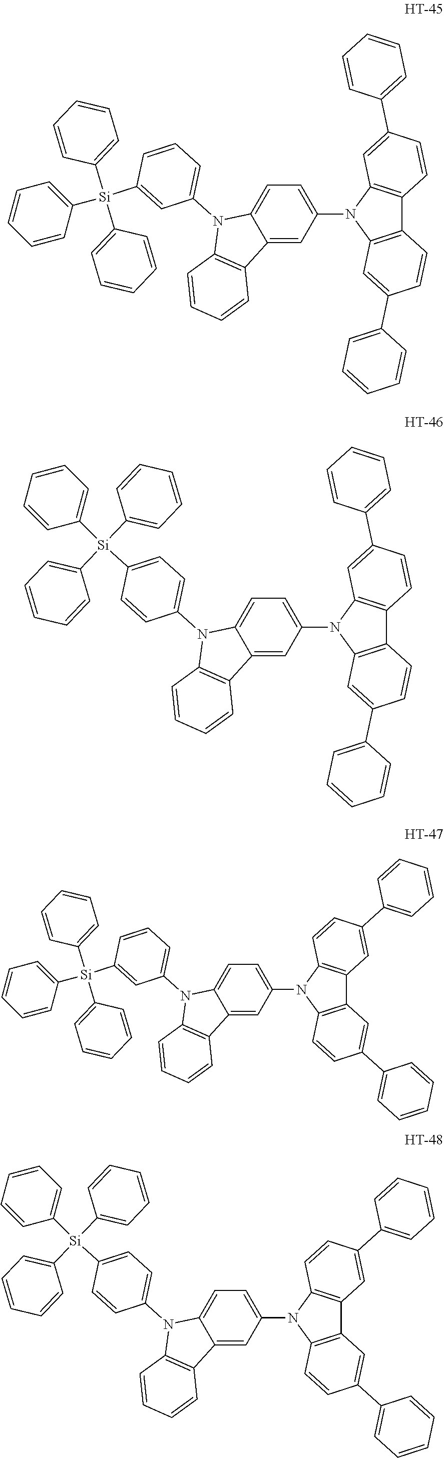 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

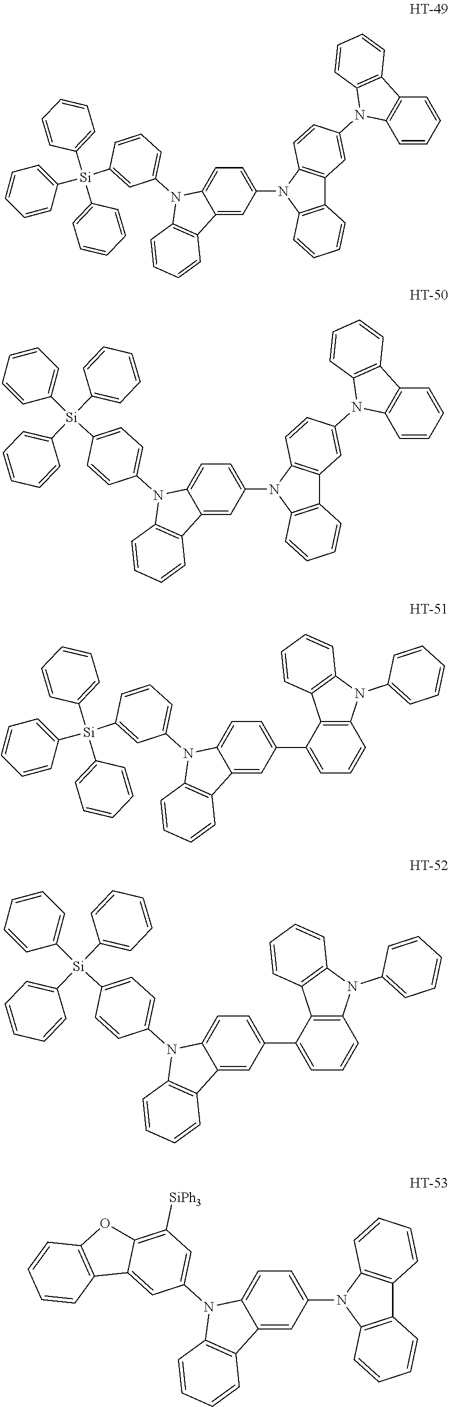

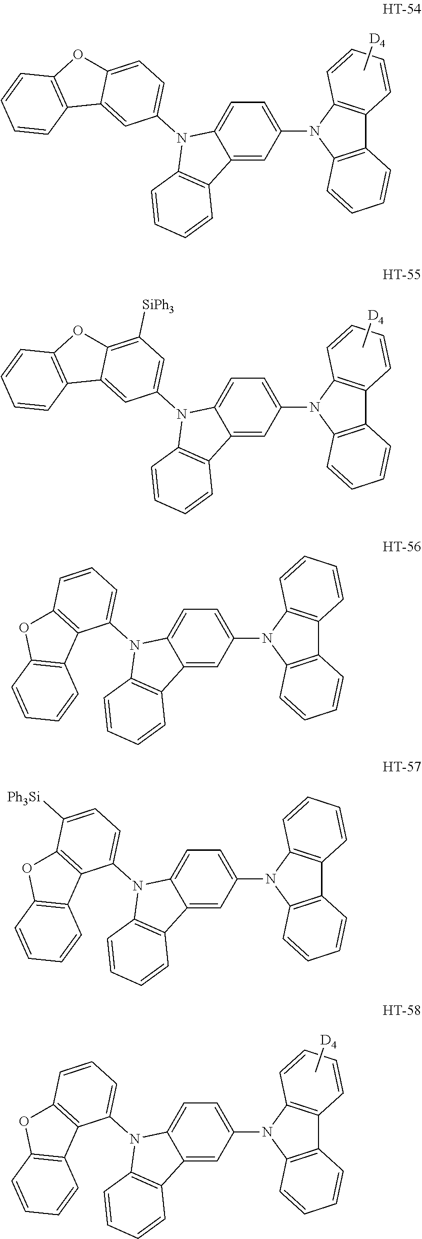

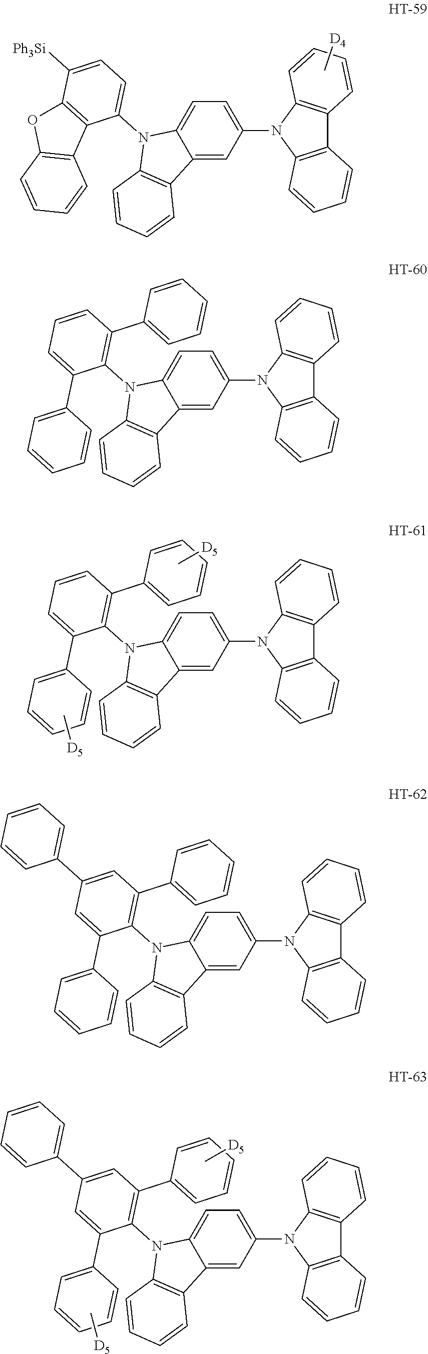

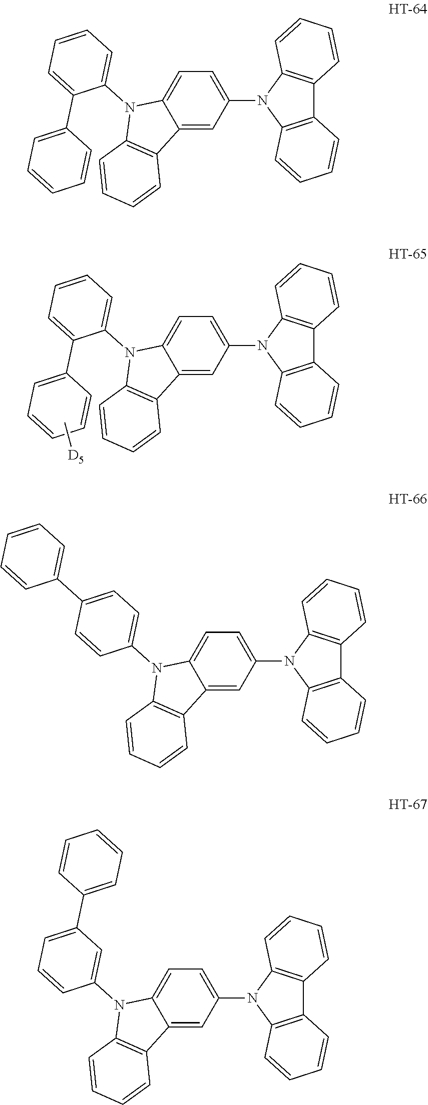

In embodiment compounds presented in Compound Group 2, D represents a deuterium atom, and Ph represents a substituted or unsubstituted phenyl group. For example, in Compound Group 2, Ph may represent an unsubstituted phenyl group.

In an embodiment, the electron transporting host may include at least one compound selected from Compound Group 3. Emission layers EML1 and EML2 may each independently include at least one compound selected from Compound Group 3 as the electron transporting host. The electron transporting host included in each of the emission layers EML1 and EML2 may be the same or different.

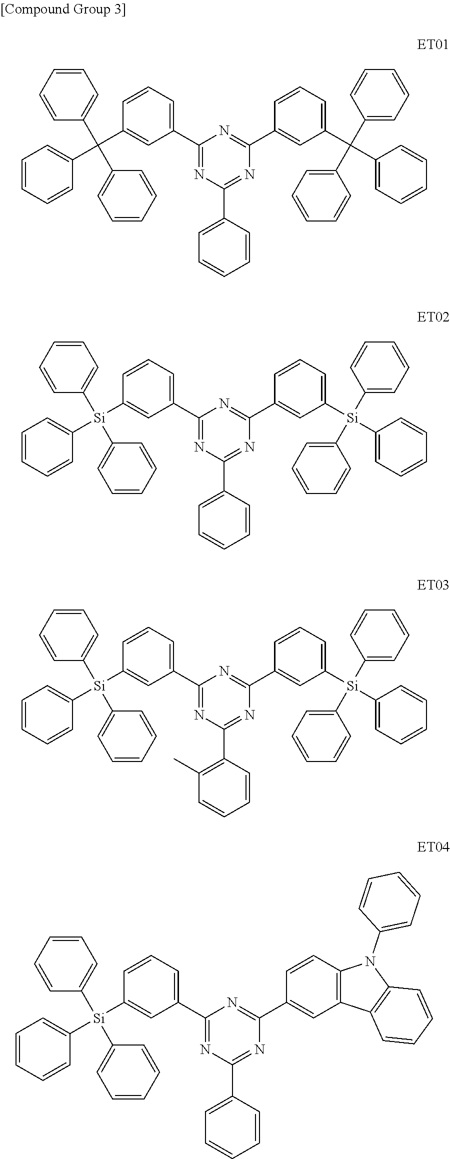 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1]

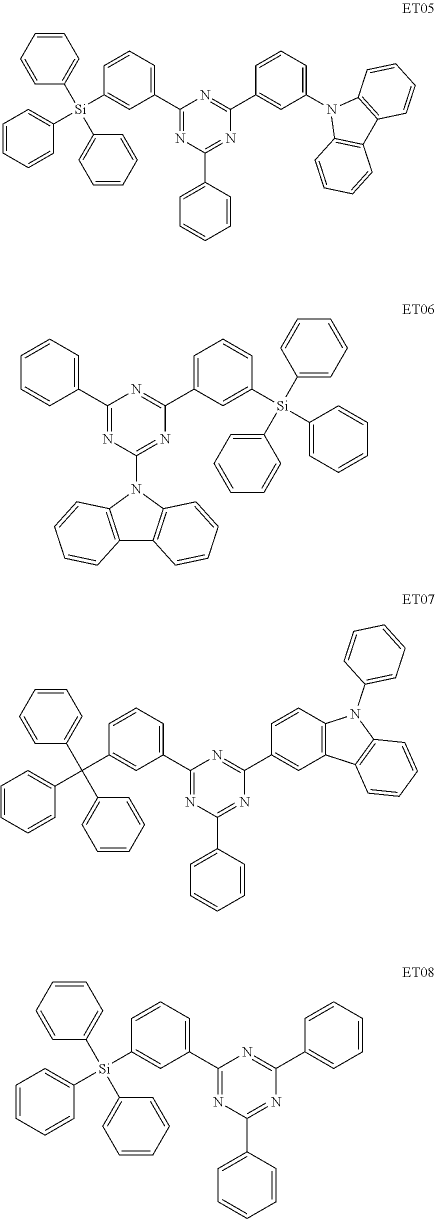

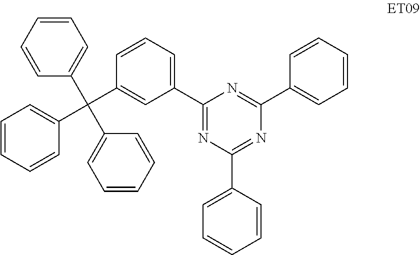

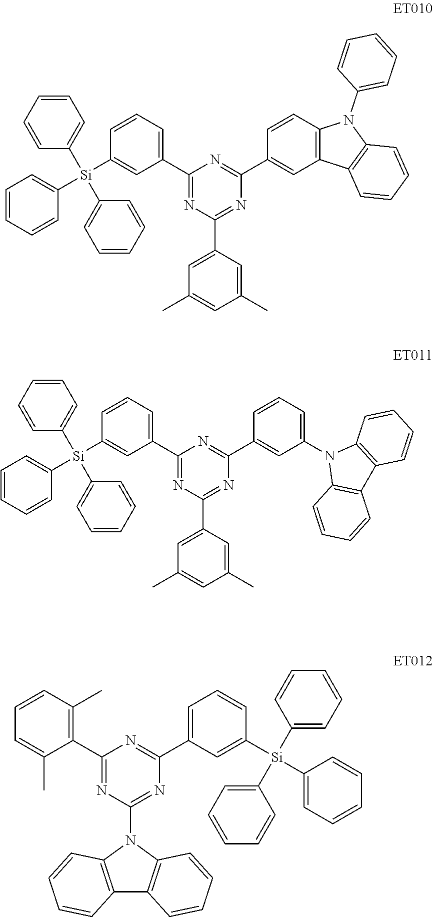

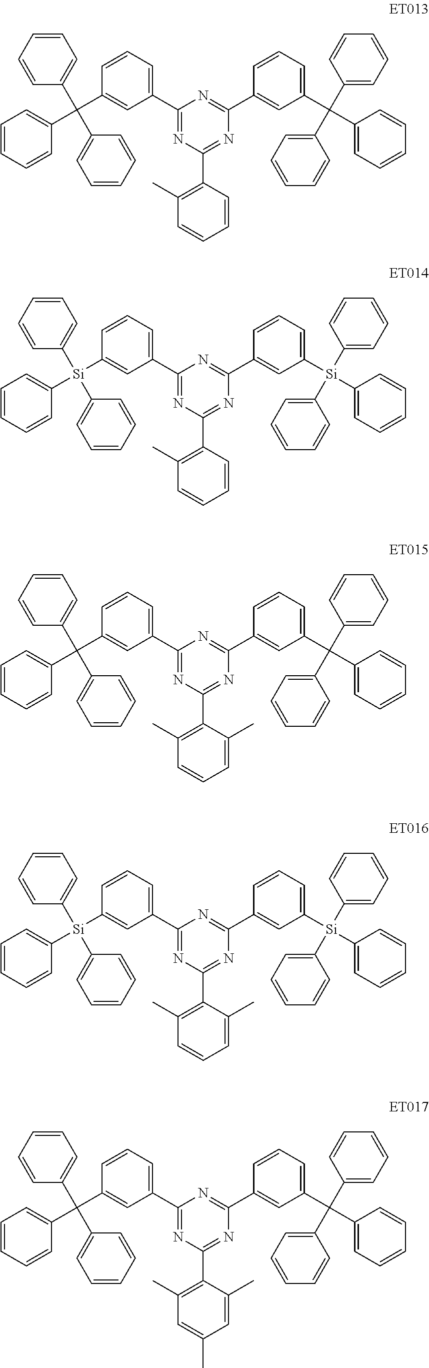

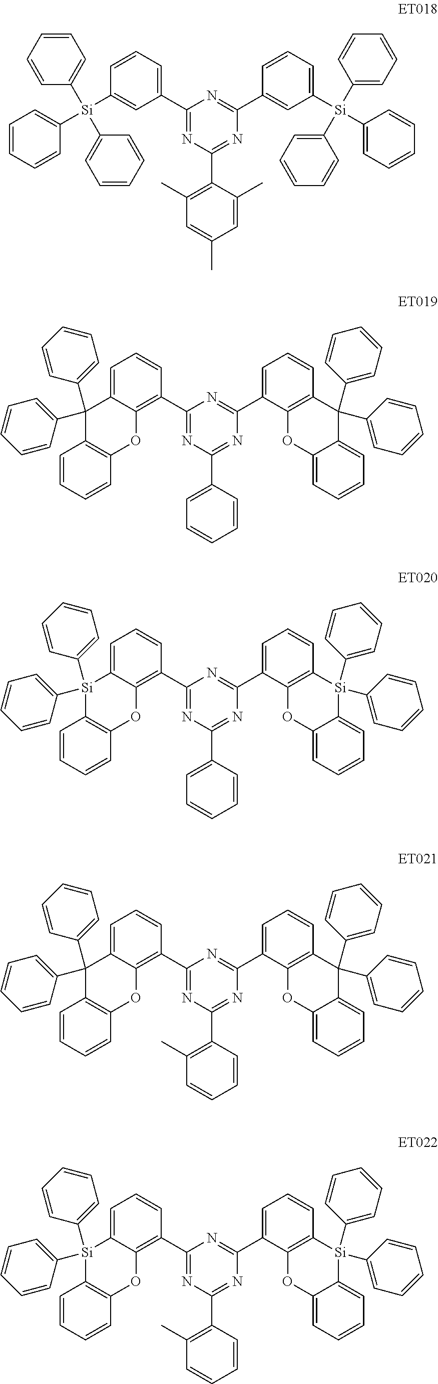

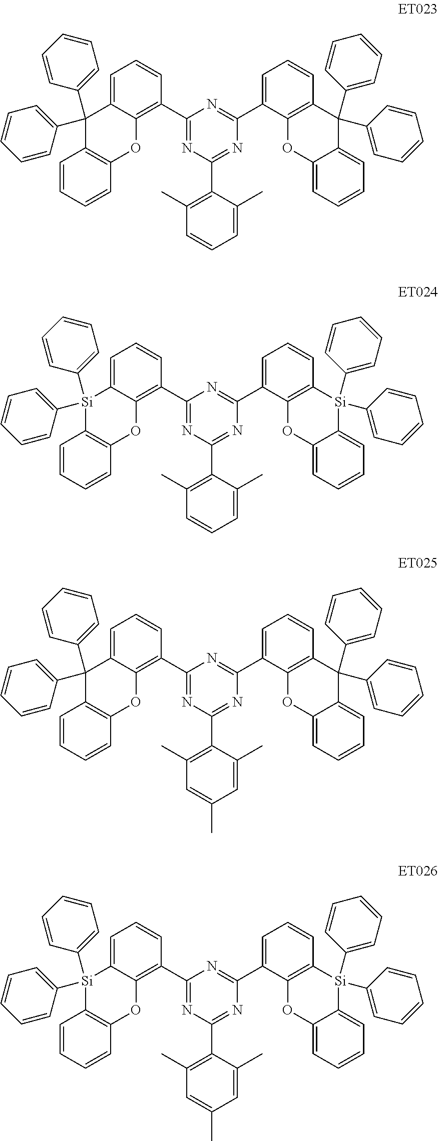 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

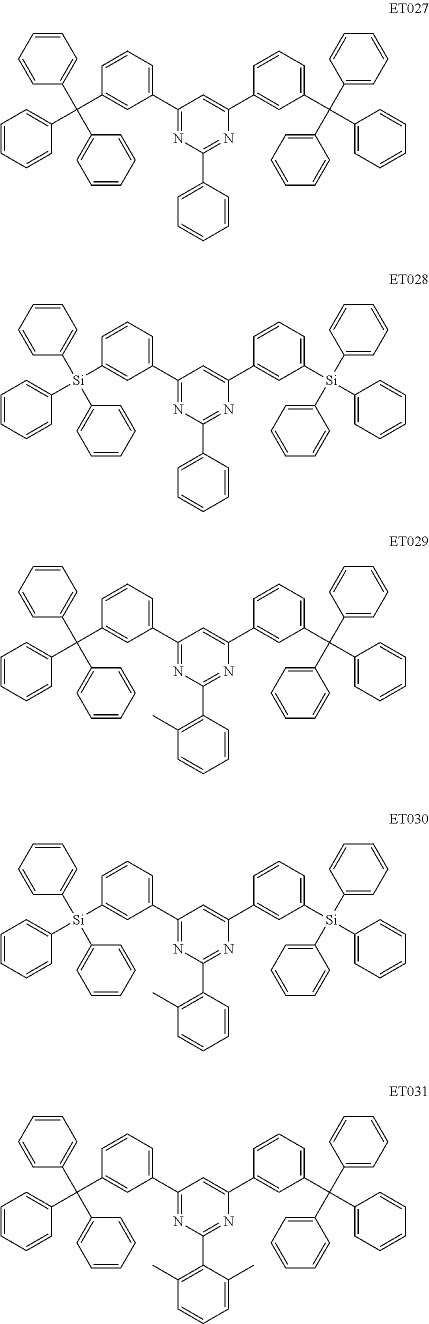

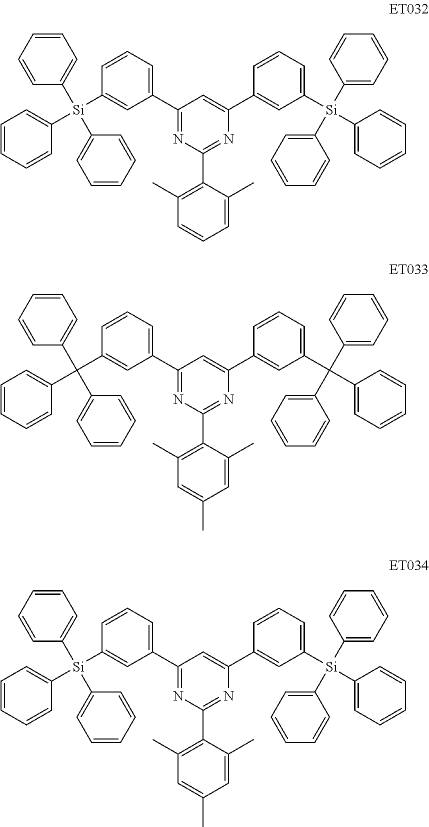 [SMILES: Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

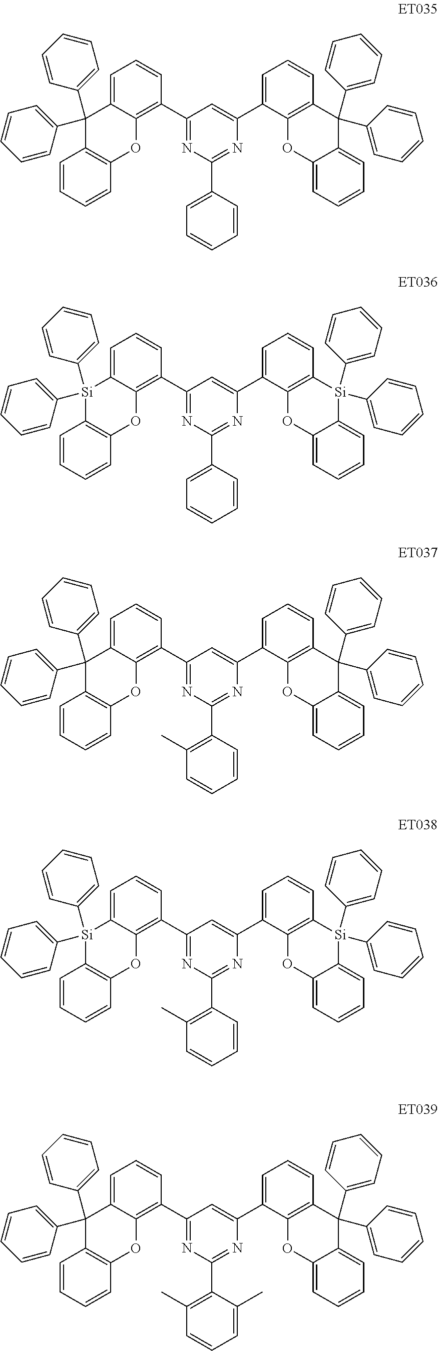

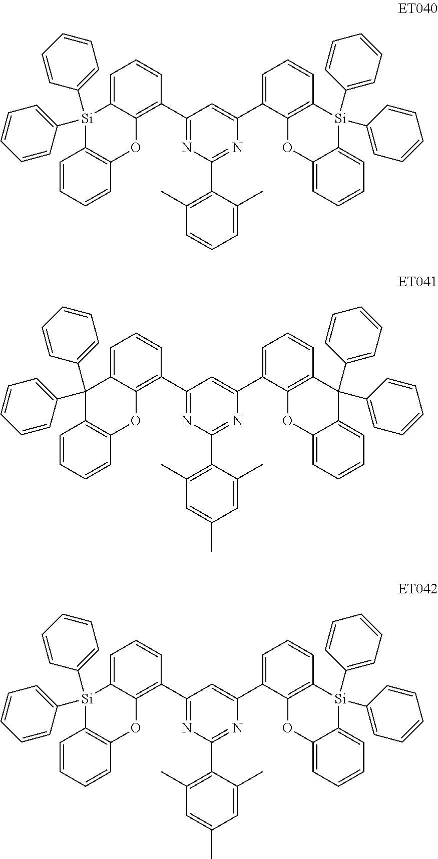 [SMILES: Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

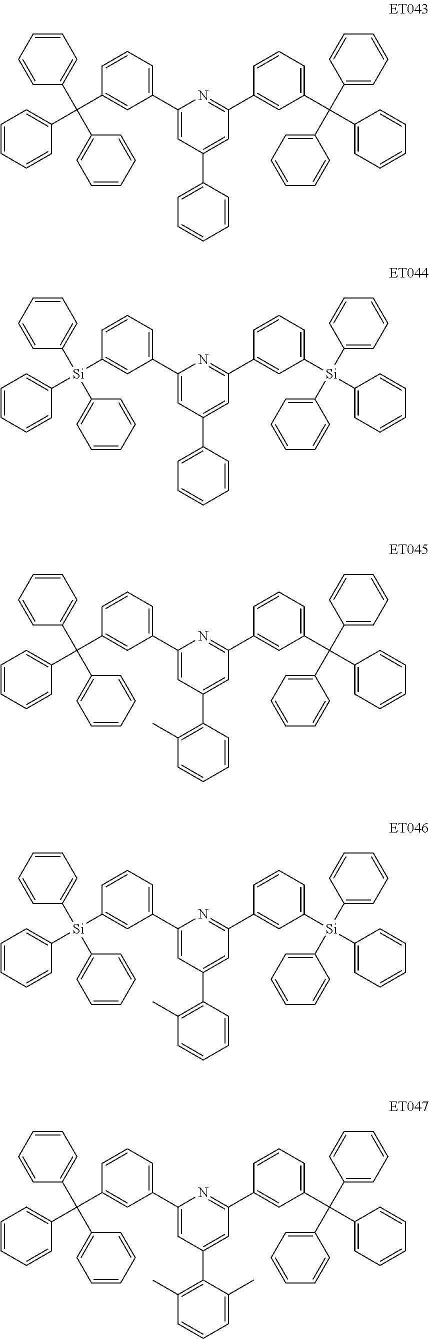

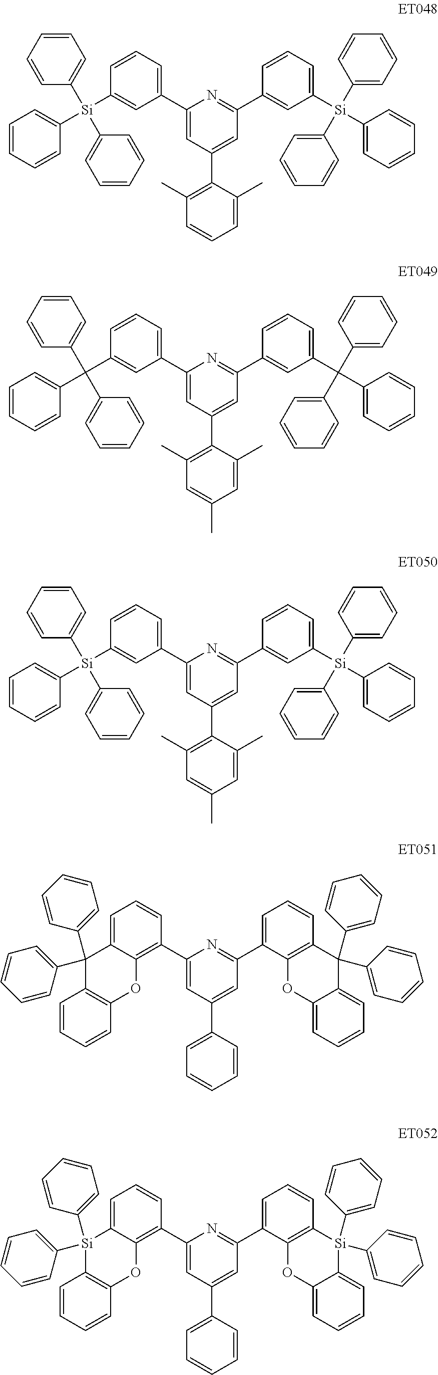

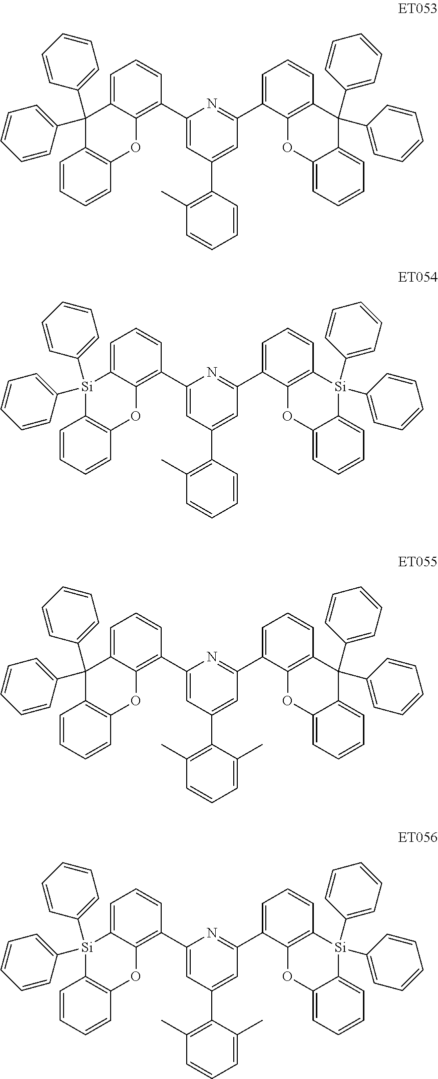 [SMILES: Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

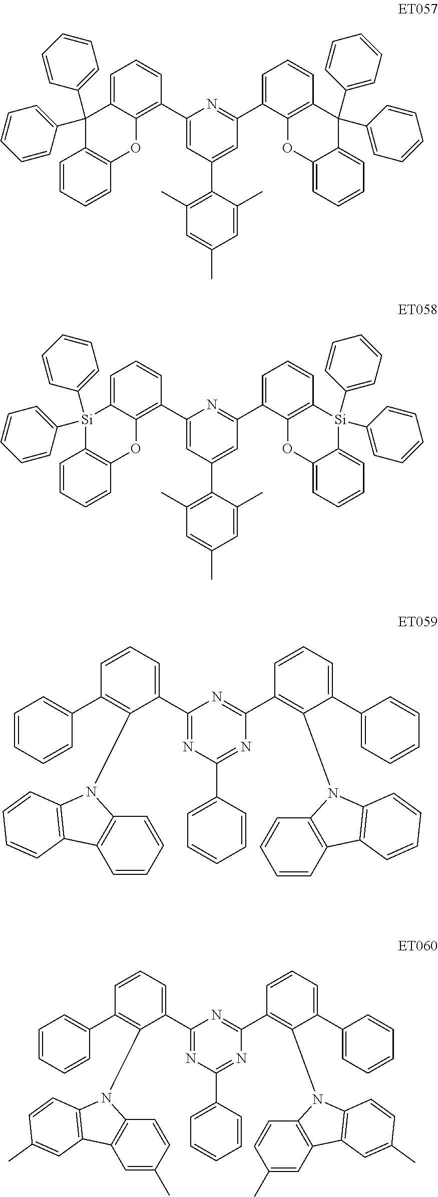

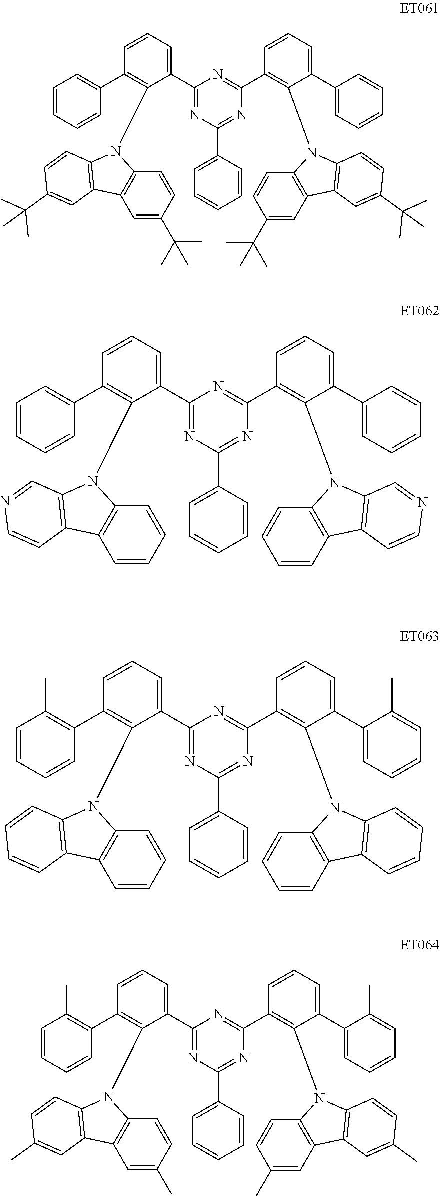

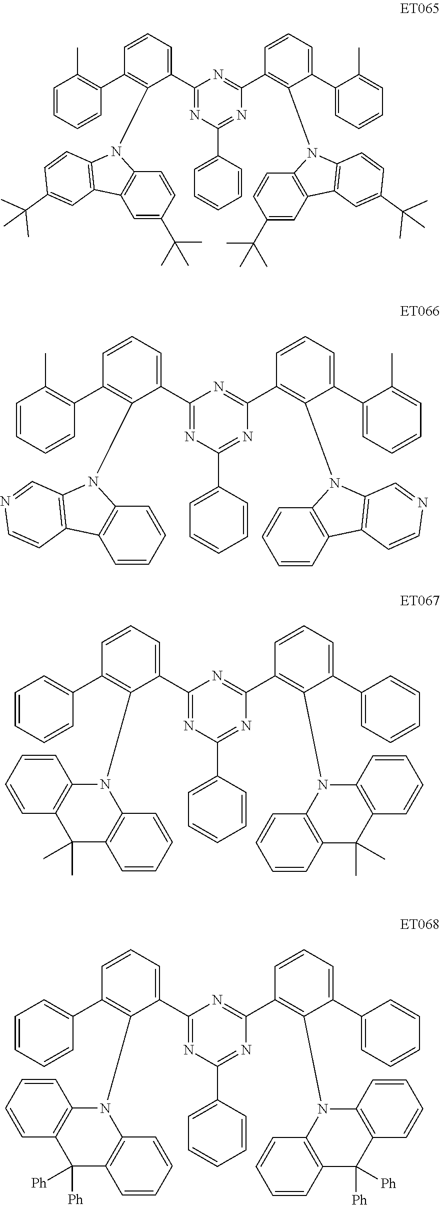

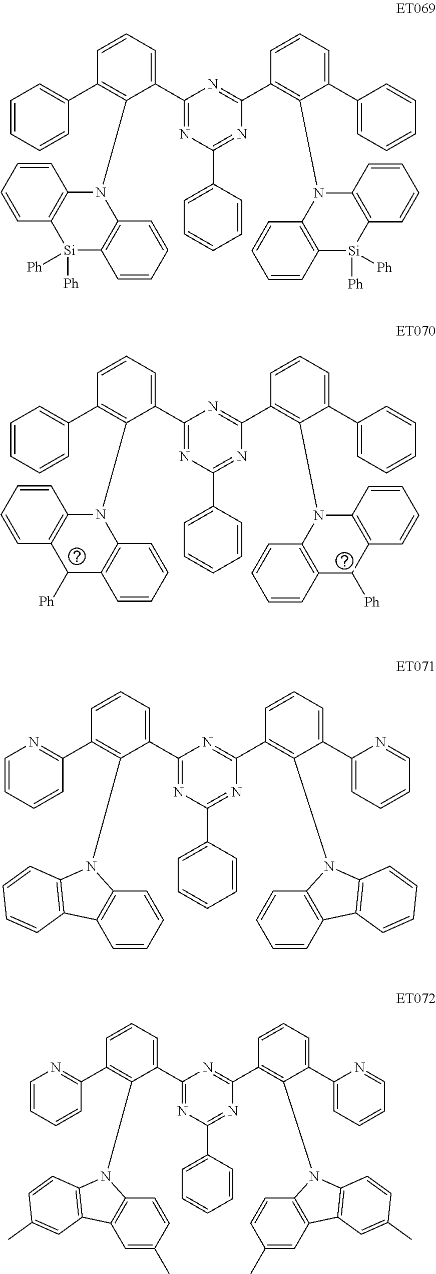

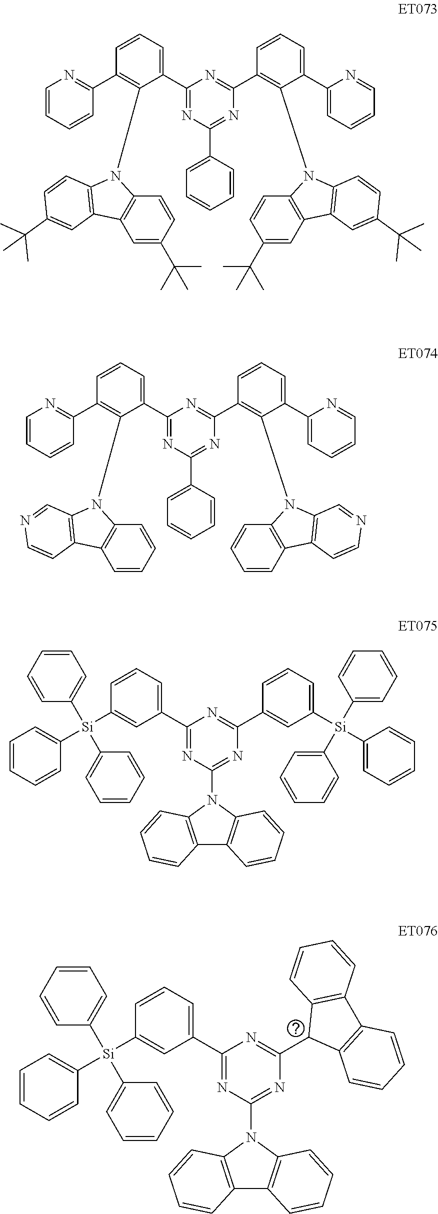 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(C4c5ccccc5-c5ccccc54)nc(-n4c5ccccc5c5ccccc54)n3)c2)cc1]

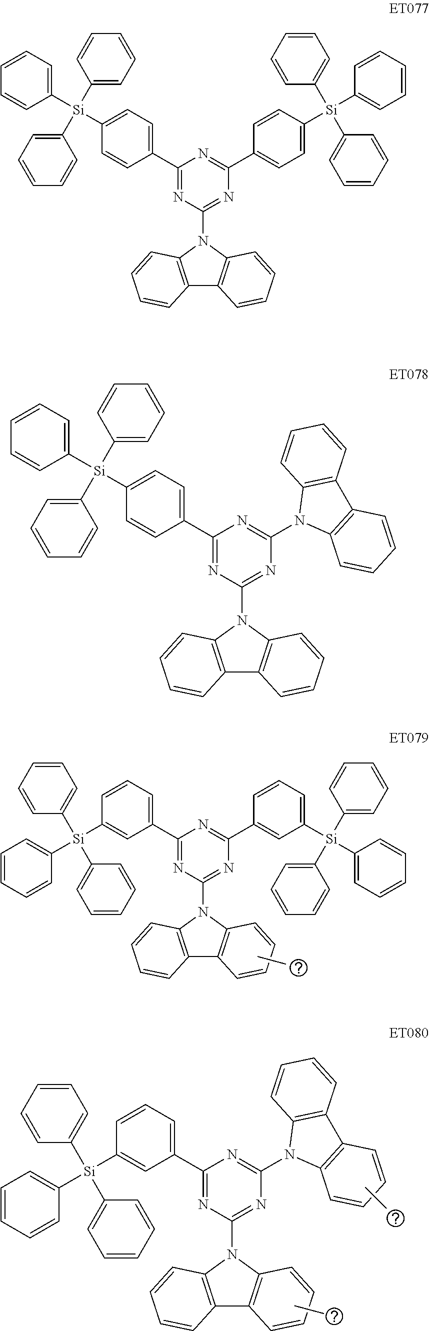

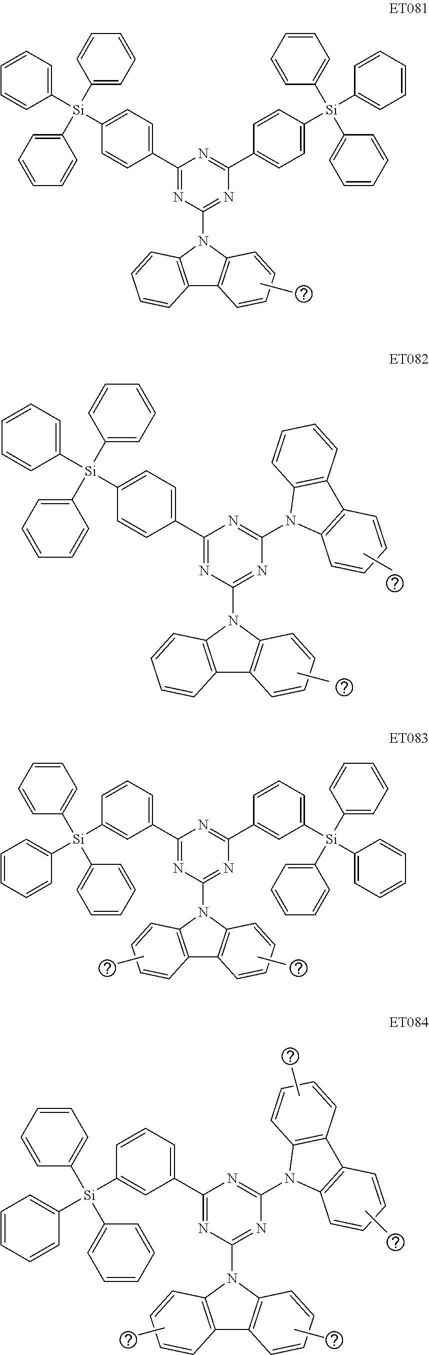

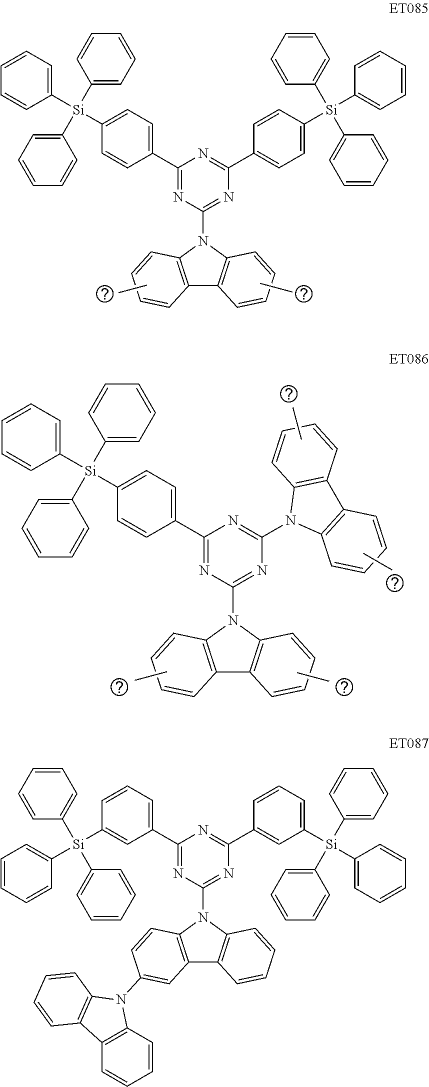

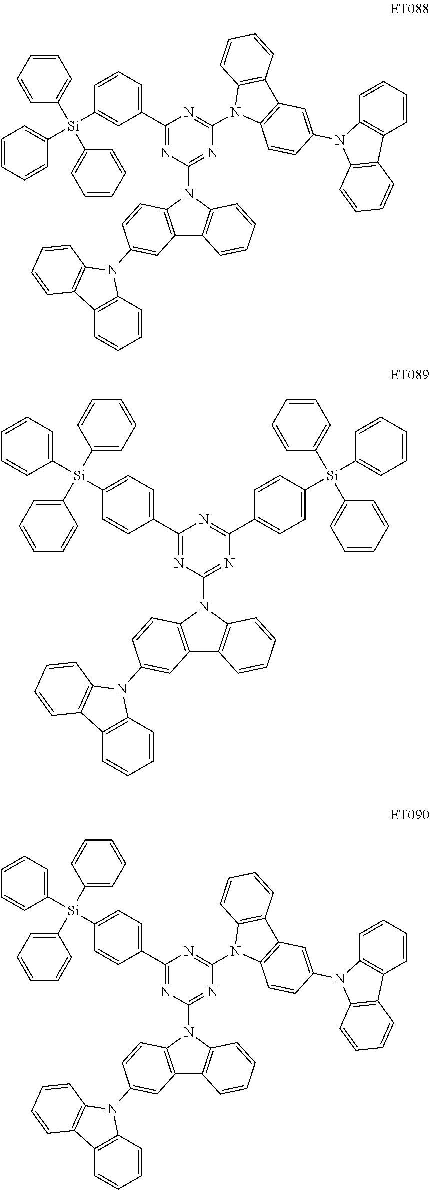 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

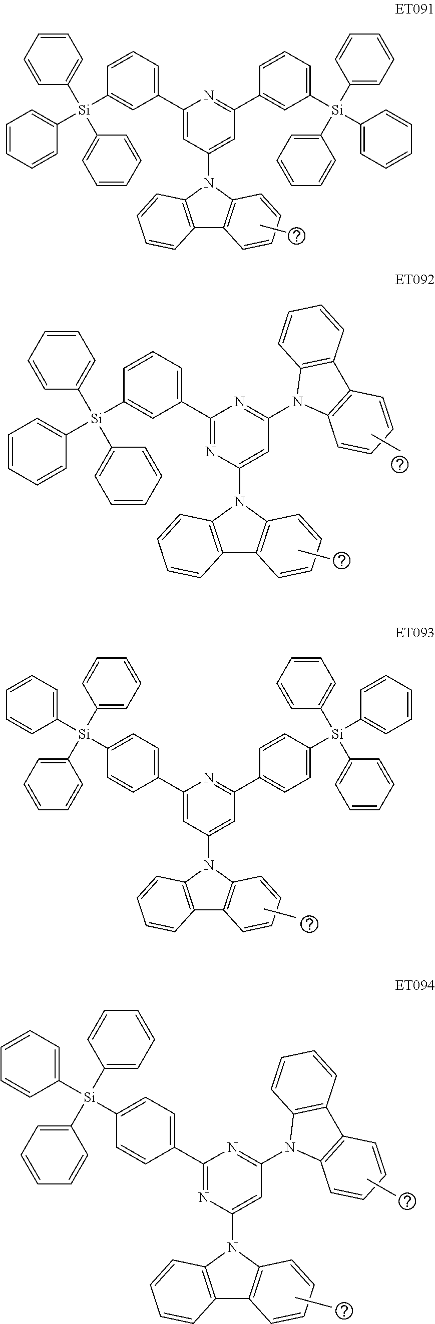

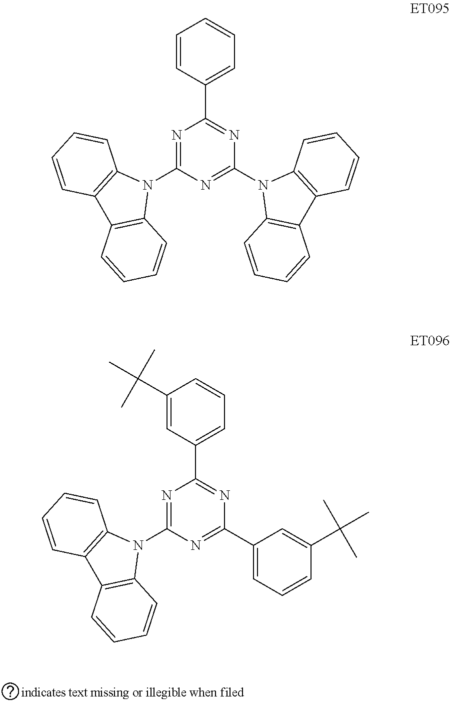 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In an embodiment, the phosphorescent sensitizer may be an auxiliary dopant that transfers energy from the hole transporting host and the electron transporting host to the first fluorescent dopant. The phosphorescent sensitizer may promote energy transfer from the hole transporting host and the electron transporting host to the first fluorescent dopant. Accordingly, the light emitting element ED according to an embodiment including the first fluorescent dopant and the phosphorescent sensitizer may have improved luminous efficiency. Since the energy transfer from the phosphorescent sensitizer to the first fluorescent dopant is promoted, excitons formed in the emission layers EML1 and EML2 may not accumulate in the emission layers EML1 and EML2, thereby reducing the deterioration of the element. Accordingly, the service life of the light emitting element ED according to an embodiment may be increased.

In an embodiment, the phosphorescent sensitizer may be a material including a metal complex. The phosphorescent sensitizer may be represented by Formula PS:

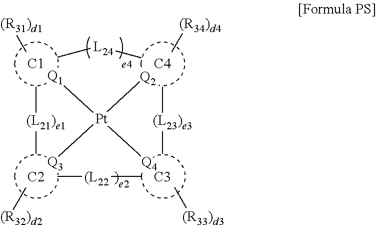

In Formula PS, Q₁ to Q₄ may each independently be C or N; and rings C1 to C4 may each independently be a substituted or unsubstituted hydrocarbon ring group having 5 to 30 ring-forming carbon atoms or a substituted or unsubstituted heterocyclic group having 2 to 30 ring-forming carbon atoms.

In Formula PS, e1 to e4 may each independently be 0 or 1; and L₂₁ to L₂₄ may each independently be a direct linkage,

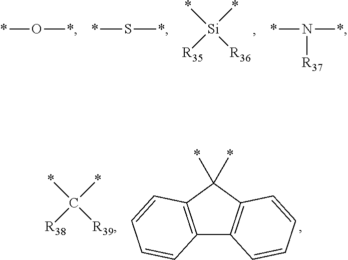

a substituted or unsubstituted divalent alkyl group having 1 to 20 carbon atoms, a substituted or unsubstituted arylene group having 6 to 30 ring-forming carbon atoms or a substituted or unsubstituted heteroarylene group having 2 to 30 ring-forming carbon atoms. In case that each of e1 to e4 is 0, rings C1 and C2 may not be directly linked to each other, rings C2 and C3 may not be directly linked to each other, rings C3 and C4 may not be directly linked to each other, and rings C1 and C4 may not be directly linked to each other.

In Formula PS, d1 to d4 may each independently be an integer from 0 to 4. In case that d1 is 2 or greater, multiple R₃₁ groups may be the same as each other or at least one may be different from the others. In case that d2 is 2 or greater, multiple R₃₂ groups may be the same as each other or at least one may be different from the others. In case that d3 is 2 or greater, multiple R₃₃ groups may be the same as each other or at least one may be different from the others. In case that d4 is 2 or greater, multiple R₃₄ groups may be the same as each other or at least one may be different from the others.

In Formula PS, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

The phosphorescent sensitizer represented by Formula PS may be any compound selected from Compound Group 4. The phosphorescent sensitizer according to an embodiment may include at least one compound selected from Compound Group 4. In the light emitting element ED according to an embodiment, the emission layers EML1 and EML2 including the first fluorescent dopant may include at least one compound selected from Compound Group 4. The emission layer including the second fluorescent dopant among the emission layers EML1 and EML2 may include at least one compound selected from Compound Group 4 as the phosphorescent sensitizer.

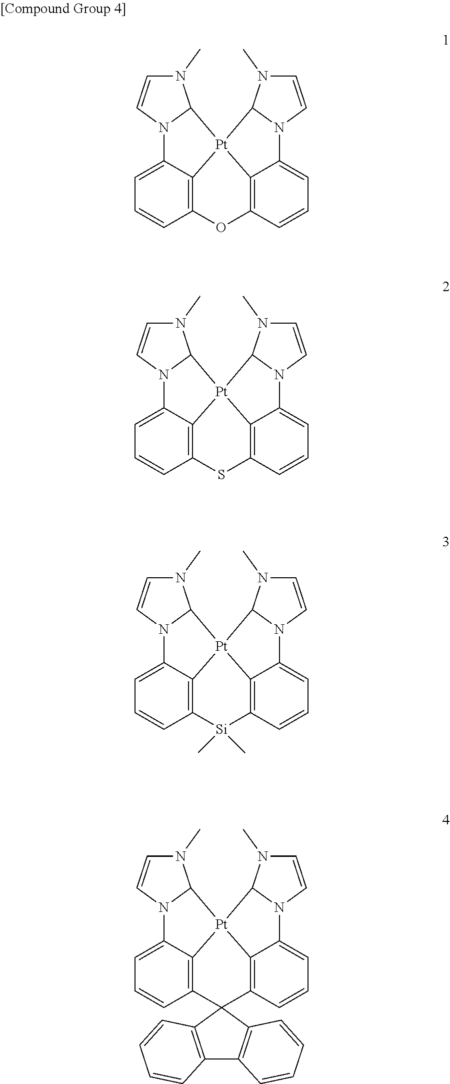

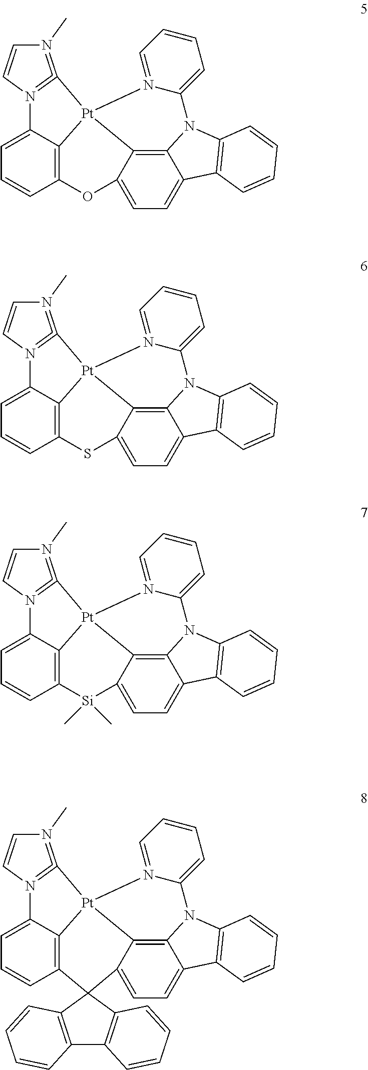

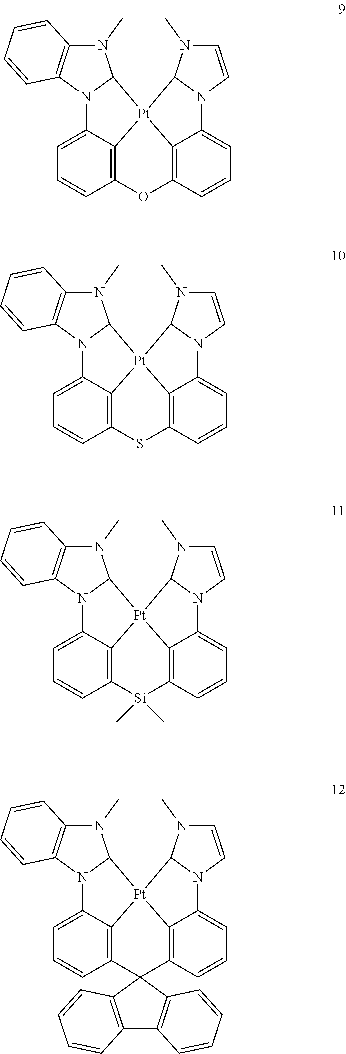

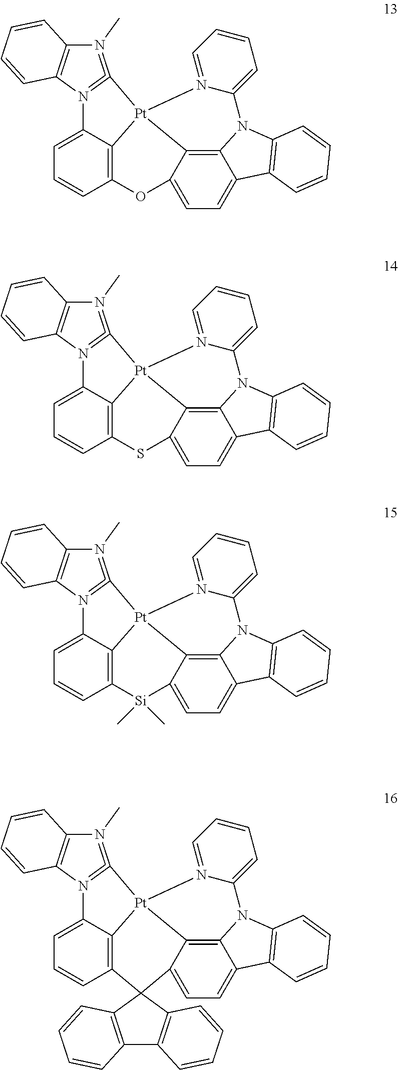

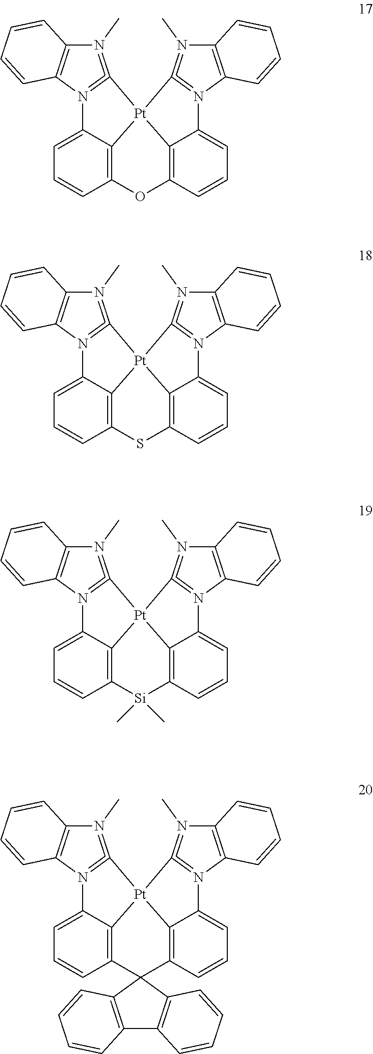

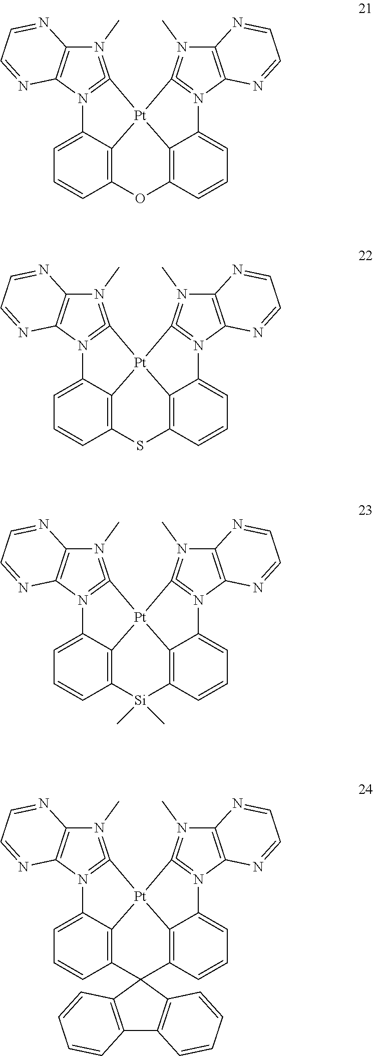

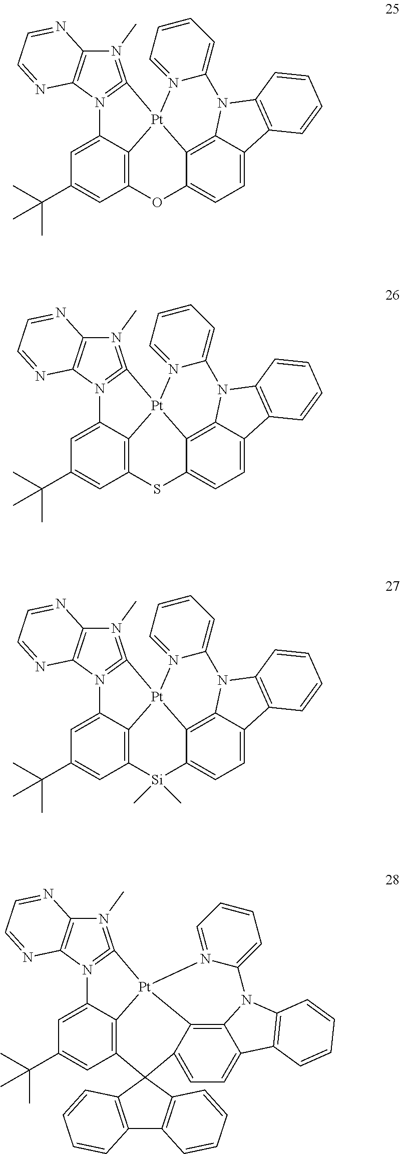

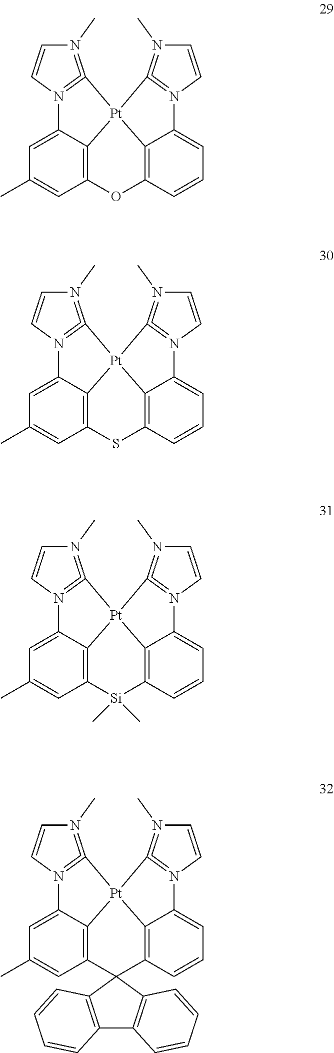

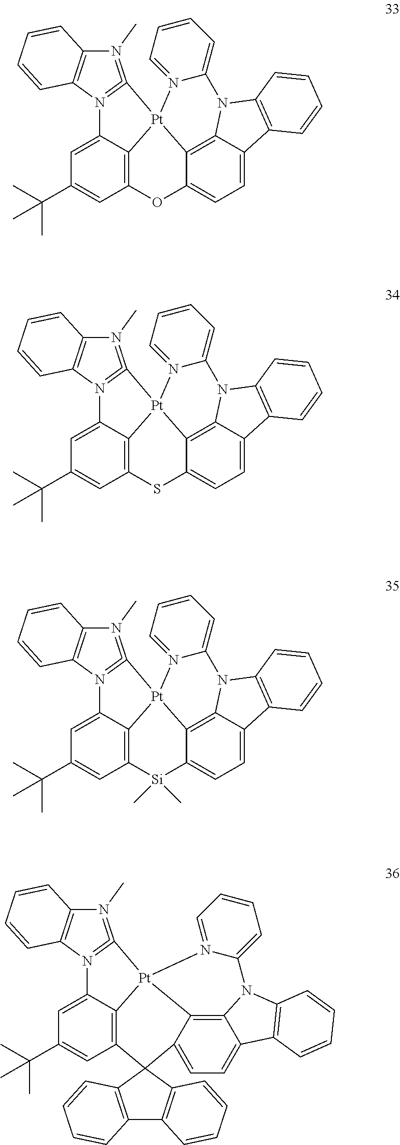

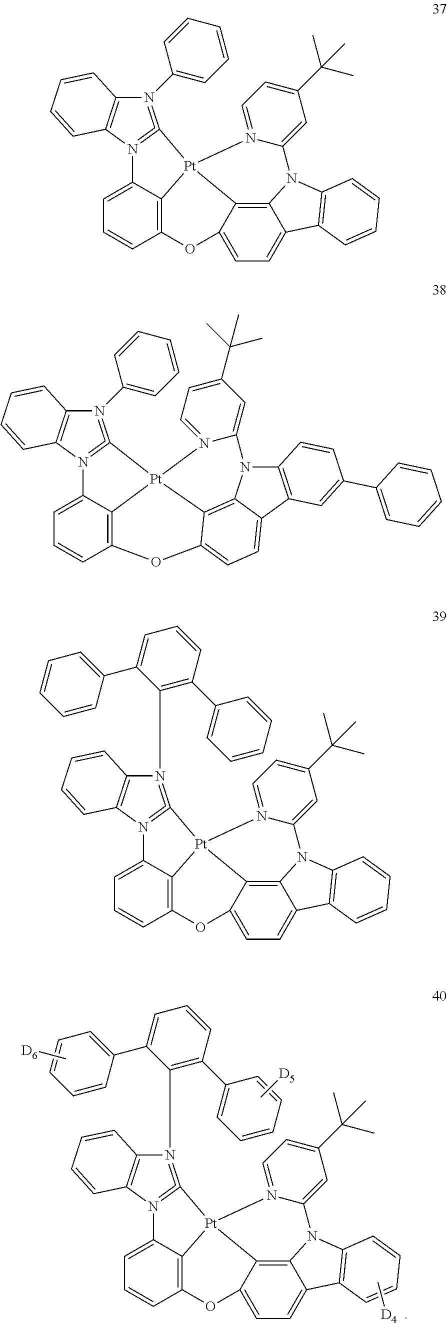

The emission layers EML1 and EML2 according to an embodiment may emit fluorescence. In the emission layers EML1 and EML2, the first fluorescent dopant and the second fluorescent dopant may absorb energy and emit light. The first fluorescent dopant may receive the energy from the phosphorescent sensitizer, and the second fluorescent dopant may receive the energy from the hole transporting host and the electron transporting host. The second fluorescent dopant may receive the energy from the phosphorescent sensitizer.

As described above, the hole transporting host and the electron transporting host may form an exciplex. The triplet state energy level (Tb1_{H}) of the exciplex formed by the hole transporting host and the electron transporting host may be higher than the triplet state energy level (T1_{P}) of the phosphorescent sensitizer. The triplet state energy level (T1_{P}) of the phosphorescent sensitizer may be higher than the triplet state energy level (T1_{F1}) of the first fluorescent dopant. Accordingly, the triplet state energy level (T1_{H}) of the exciplex, the triplet state energy level (T1_{P}) of the phosphorescent sensitizer, and the triplet state energy level (T1_{F1}) of the first fluorescent dopant may satisfy Expression 1:

$$T {1}_{H} > T {1}_{P} > T {1}_{F 1} \qquad [ Expression 1 ]$$

In case that the triplet state energy level (T1_{H}) of the exciplex, the triplet state energy level (T1_{P}) of the phosphorescent sensitizer, and the triplet state energy level (T1_{F1}) of the first fluorescent dopant satisfy Expression 1, the energy may readily be transferred from the exciplex to the phosphorescent sensitizer and the energy may readily be transferred from the phosphorescent sensitizer to the first fluorescent dopant. Back energy transfer from the triplet state of the first fluorescent dopant to the triplet state of the phosphorescent sensitizer or the triplet state of the exciplex may be prevented.

The light emitting element ED according to an embodiment may further include, in the emission layers EML1 and EML2, an emission layer material in addition to the hole transporting host, the electron transporting host, the phosphorescent sensitizer, the first fluorescent dopant, and the second fluorescent dopant, as described above. In the light emitting element ED according to an embodiment, the emission layers EML1 and EML2 may further include an anthracene derivative, a pyrene derivative, a fluoranthene derivative, a chrysene derivative, a dihydrobenzanthracene derivative, or a triphenylene derivative.

For example, the emission layers EML1 and EML2 may include a compound represented by Formula E-1. The compound represented by Formula E-1 may be used as a fluorescent host material.

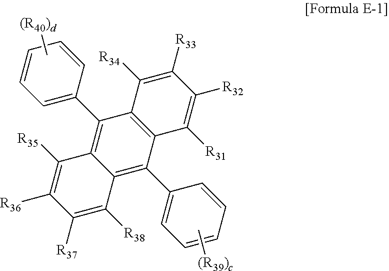

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer from 0 to 5. In case that c is 2 or greater, multiple R₃₉ groups may be the same as each other or at least one may be different from the others. In case that d is 2 or greater, multiple R₄₀ groups may be the same as each other or at least one may be different from the others.

In an embodiment, the compound represented by Formula E-1 may be one of Compound E1 to Compound E19:

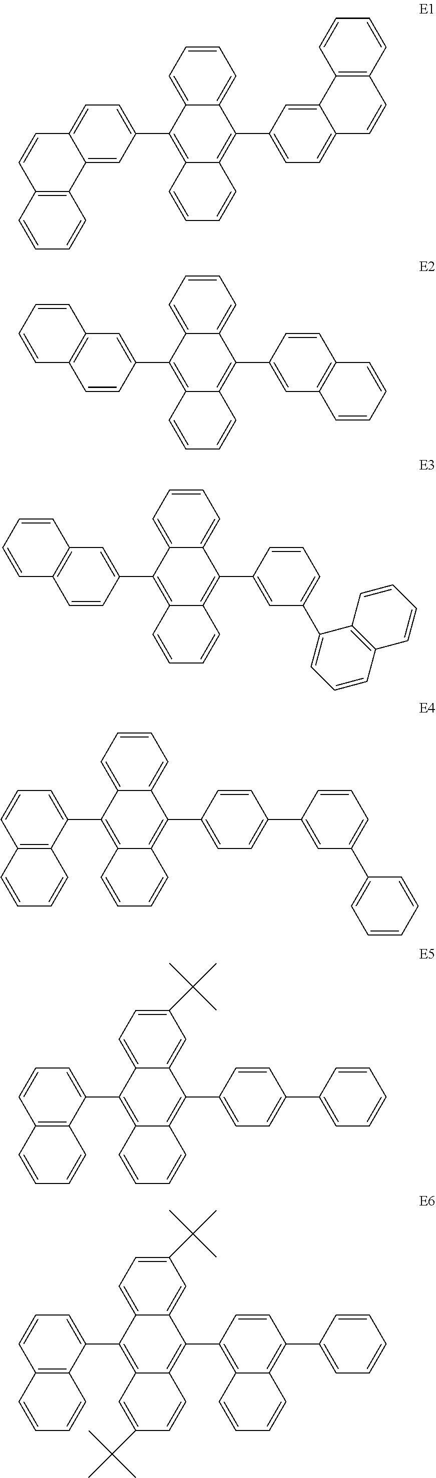

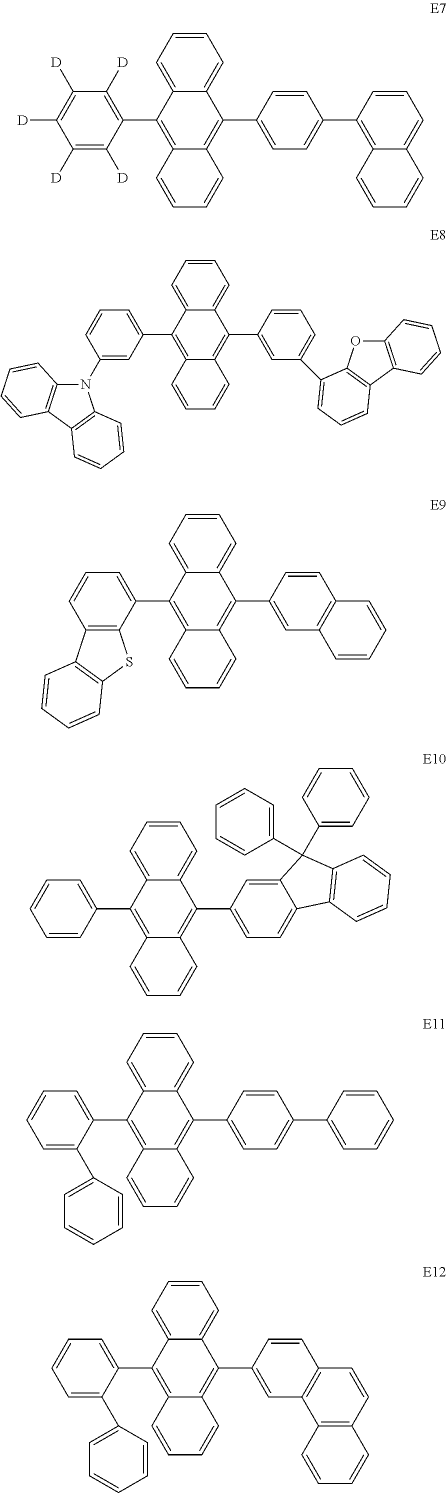

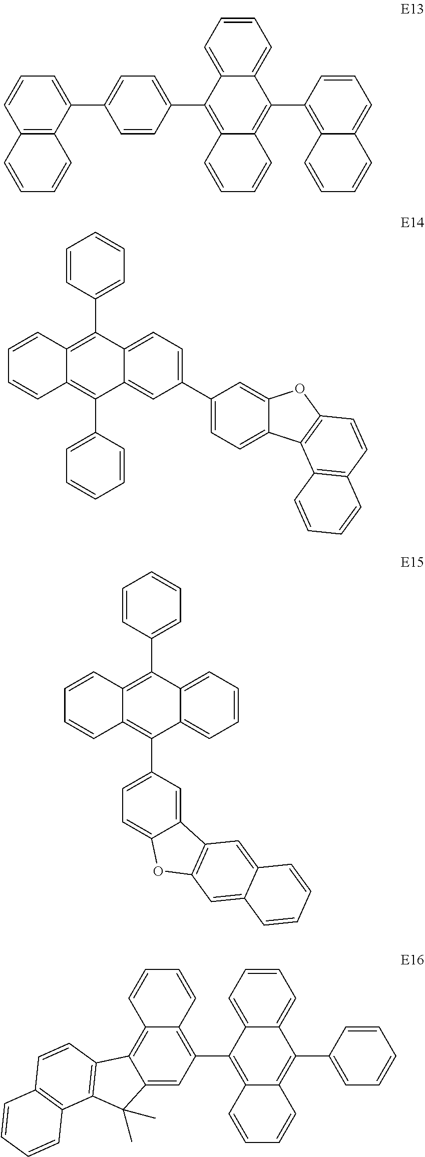

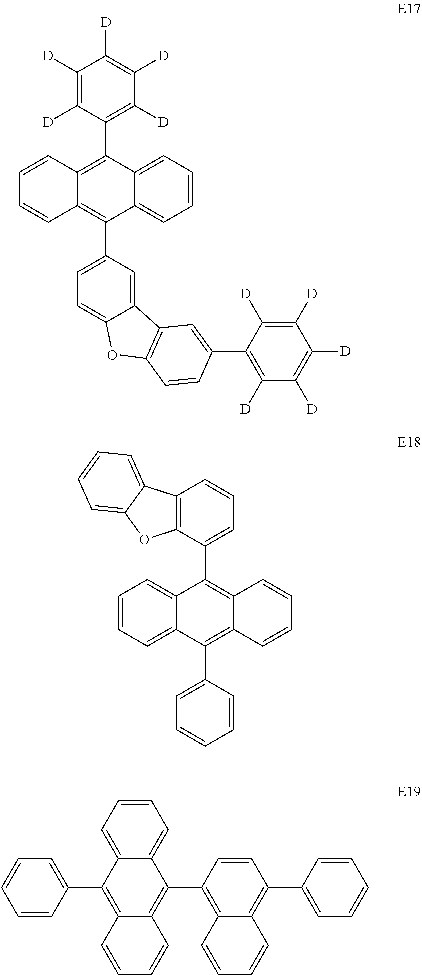

In an embodiment, the emission layers EML1 and EML2 may each independently include a compound represented by Formula E-2a or Formula E-2b. The compound represented by Formula E-2a or Formula E-2b may be used as a phosphorescent host material.

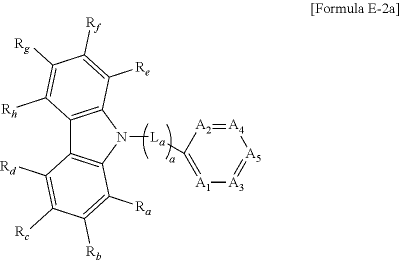

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In case that a is 2 or greater, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

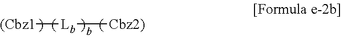

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and in case that b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

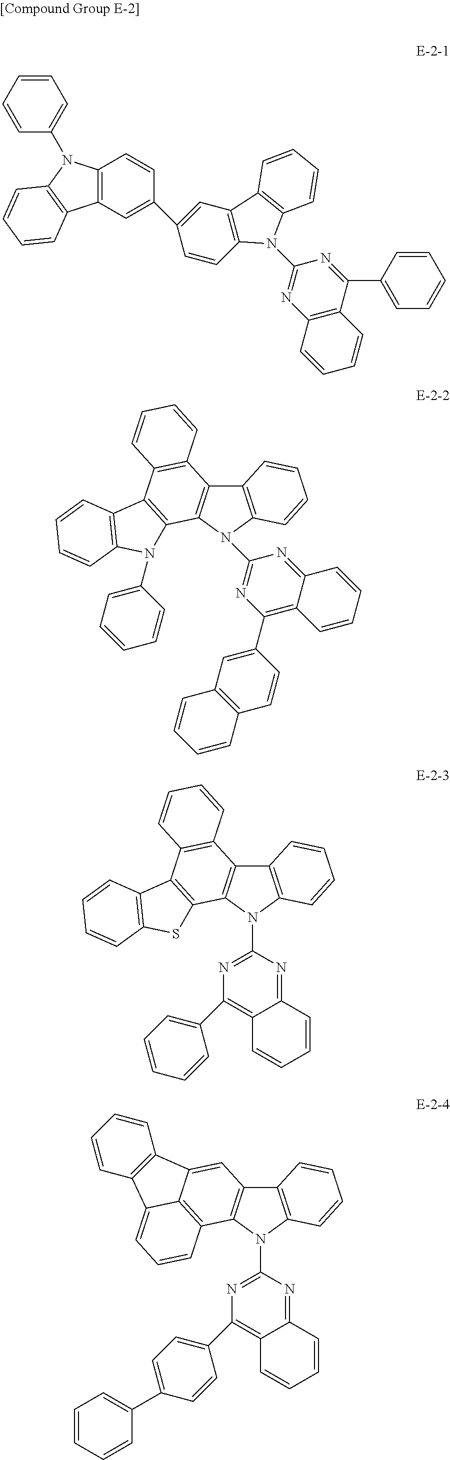

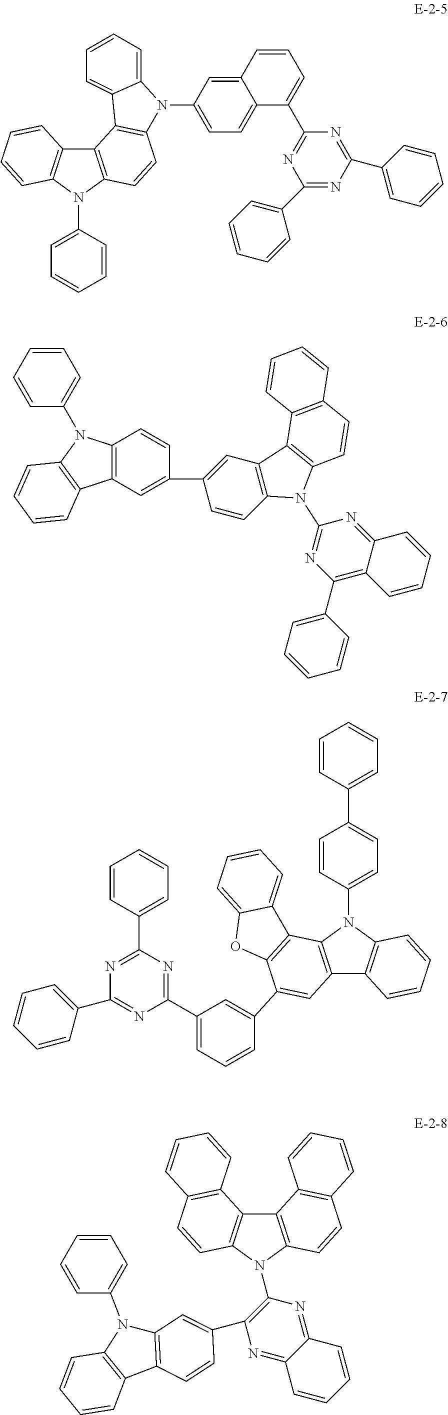 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

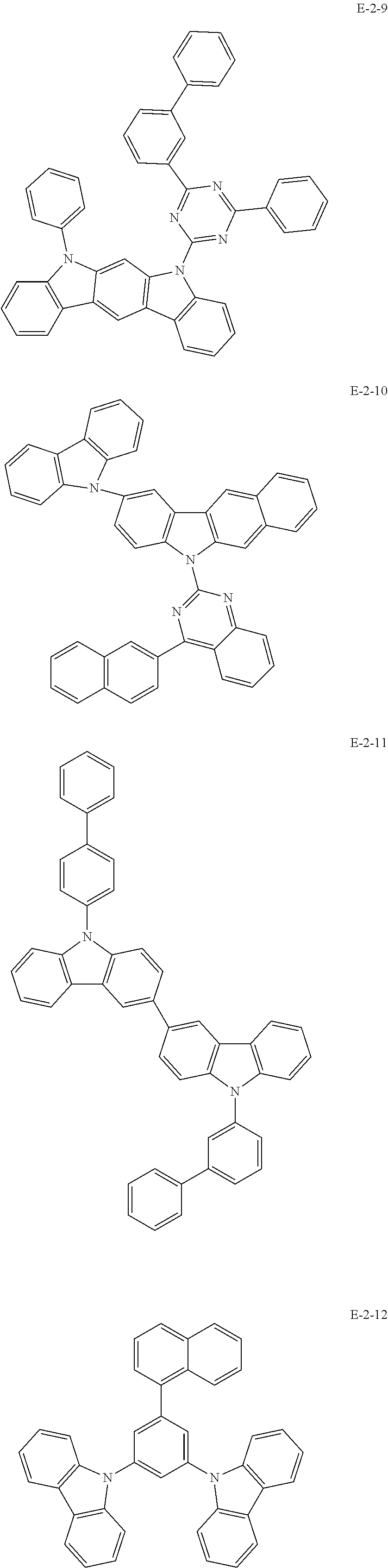 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

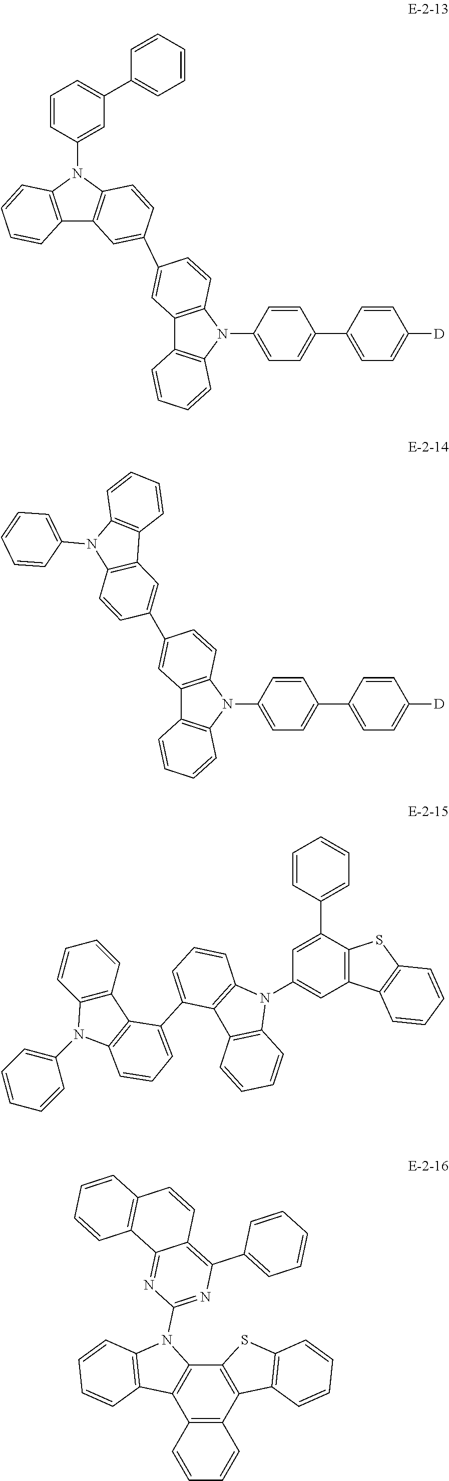 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; [2H]c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

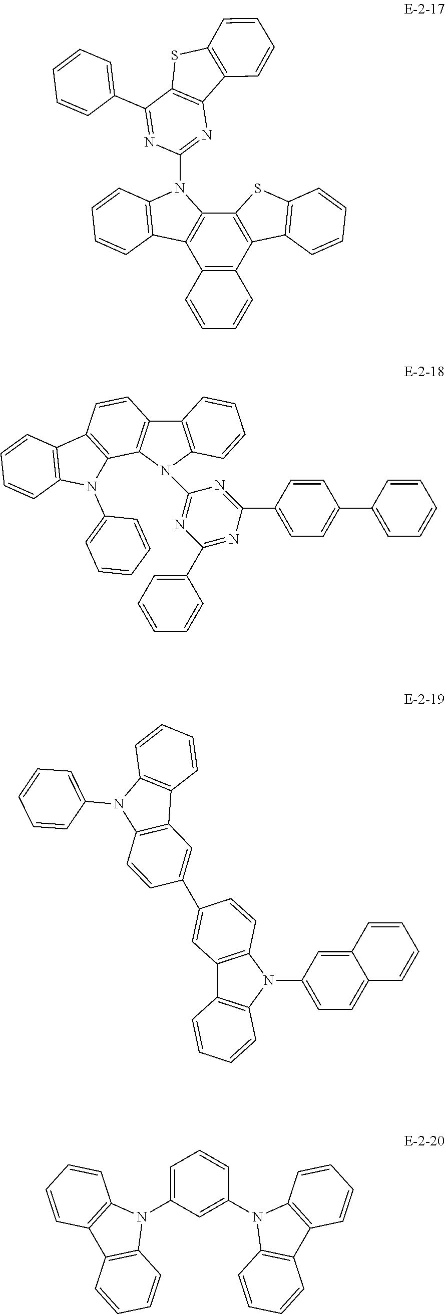 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

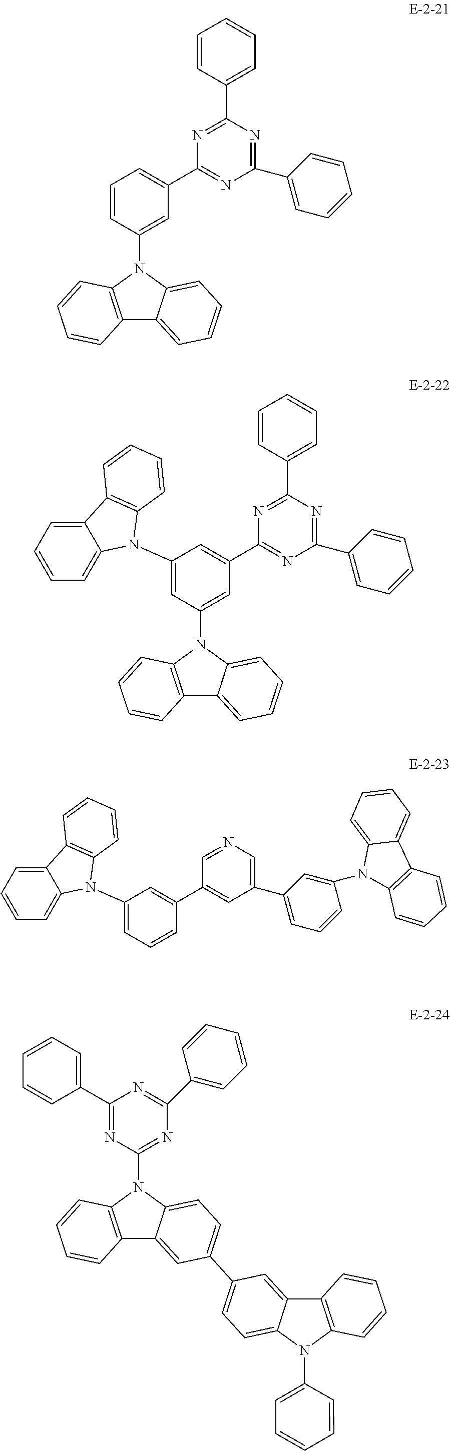 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layers EML1 and EML2 may further include a material of the related art as a host material. For example, the emission layers EML1 and EML2 may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

The emission layers EML1 and EML2 may include the compound represented by Formula M-a. The compound represented by Formula M-a may be used as a phosphorescent dopant material.

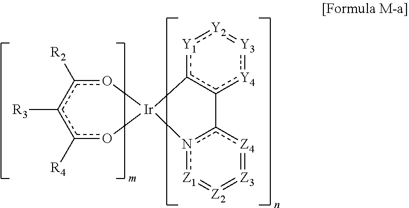

In Formula M-a, Y₁ to Y₄ and Z₁ to Z₄ may each independently be C(R₁) or N; R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, in case that m is 0, n may be 3, and in case that m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

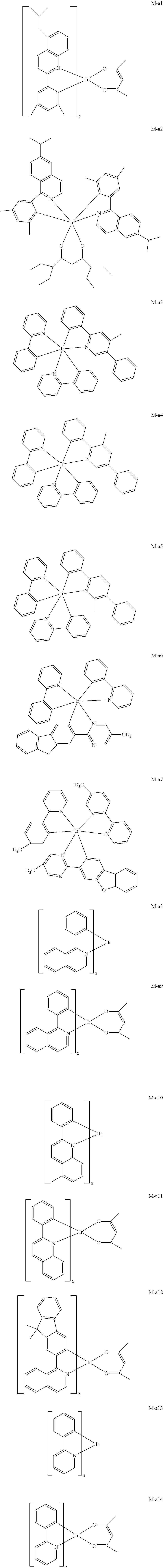

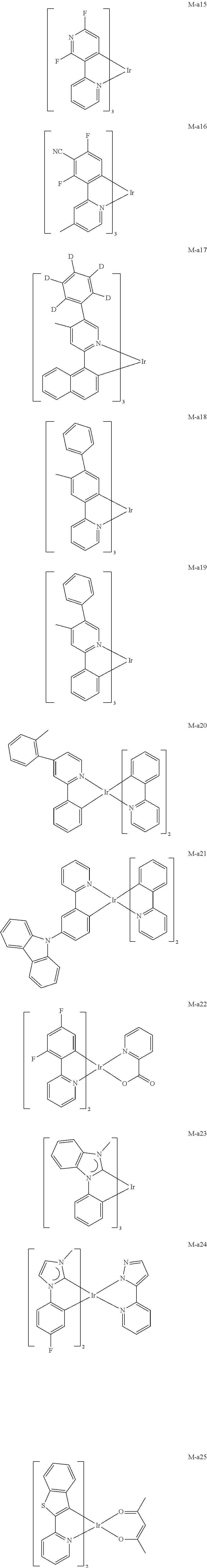

The emission layers EML1 and EML2 may further include a compound represented by any one of Formula F-a to Formula F-c. The compounds represented by Formula F-a to Formula F-c may be used as a fluorescent dopant material.

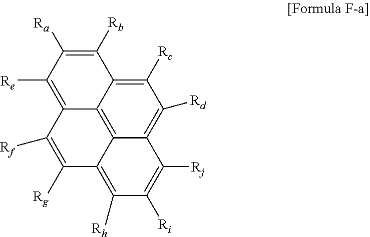

In Formula F-a, two of Rₐ to Rⱼ may each independently be substituted with a group represented by * —NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by * —NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may be a heteroaryl group containing O or S as a ring-forming atom.

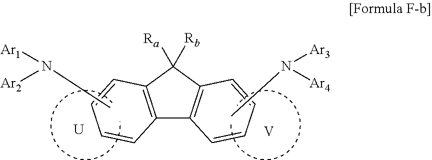

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. For example, in Formula F-b, in case that the number of U or V is 1, a fused ring may be present at a portion indicated by U or V, and in case that the number of U or V is 0, a fused ring may not be present at the portion indicated by U or V. For example, in case that the number of U is 0 and the number of V is 1, or in case that the number of U is 1 and the number of V is 0, a fused ring having a fluorene core of Formula F-b may be a cyclic compound having four rings. In case that the number of U and V is each 0, a fused ring having a fluorene core of Formula F-b may be a cyclic compound having three rings. In case that the number of U and V is each 1, a fused ring having a fluorene core in Formula F-b may be a cyclic compound having five rings.

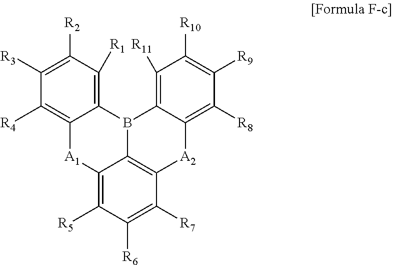

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula F-c, A₁ and A₂ may each independently be bonded to substituents of an adjacent ring to form a fused ring. For example, in case that A₁ and A₂ are each independently N(Rₘ), A₁ may be bonded to R₄ or R₅ to form a ring. For example, A₂ may be bonded to R₇ or R₈ to form a ring.

In an embodiment, the emission layers EML1 and EML2 may include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

The emission layers EML1 and EML2 may further include a phosphorescent dopant material of the related art. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

The electron transport regions ETR1 and ETR2 may each be a layer consisting of a single material, a layer including different materials, or a structure including multiple layers including different materials.

For example, the first electron transport region ETR1 and the second electron transport region ETR2 may have a single layer structure of electron injection layers EIL1 and EIL2 or electron transport layers ETL1 and ETL2, respectively, and may have a single layer structure formed of an electron injection material and an electron transport material. The first electron transport region ETR1 and the second electron transport region ETR2 may each have a single layer structure formed of multiple different materials, or may have a structure in which electron transport layers ETL1 and ETL2/electron injection layers EIL1 and EIL2, hole blocking layers (not shown)/electron transport layers ETL1 and ETL2/electron injection layer EIL1 and EIL2, electron transport layers ETL1 and ETL2/buffer layers (not shown)/electron injection layers EIL1 and EIL2 are respectively stacked in order from the emission layers EML1 and EML2, but embodiments are not limited thereto. The first electron transport region ETR1 and the second electron transport region ETR2 may each independently have a thickness in a range of about 1,000 Å to about 1,500 Å.

The first electron transport region ETR1 and the second electron transport region ETR2 may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the first electron transport region ETR1 and the second electron transport region ETR2 may include a compound represented by Formula ET-1:

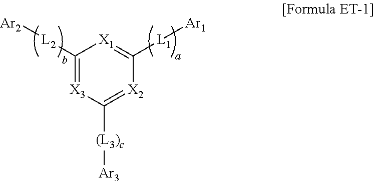

In Formula ET-1, at least one of X₁ to X₃ may each be N; and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In case that a to c are each independently 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or a mixture thereof.

In an embodiment, the electron transport region ETR may include at least one compound selected from Compound ETl to Compound ET36:

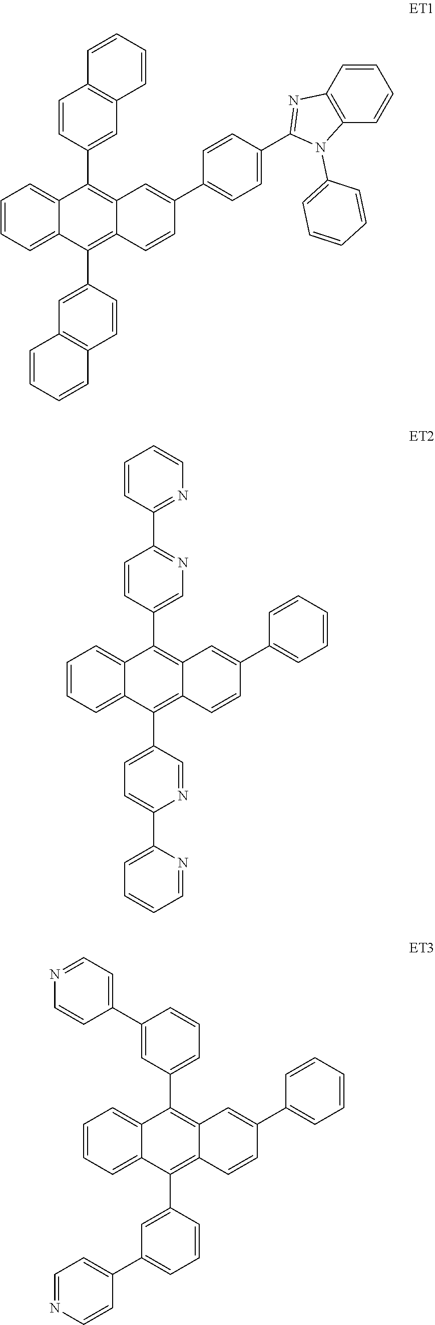 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

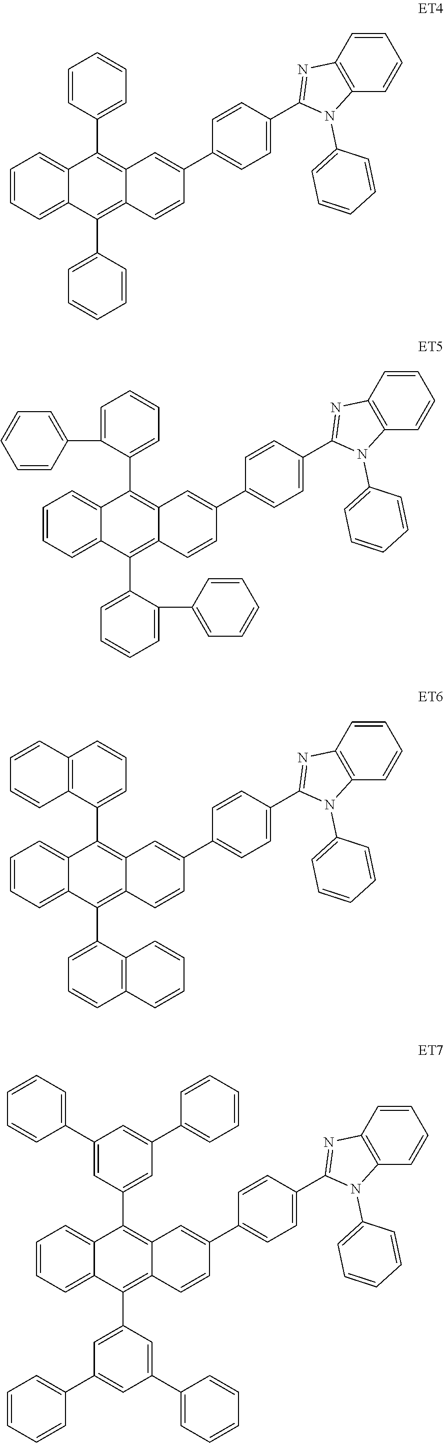 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

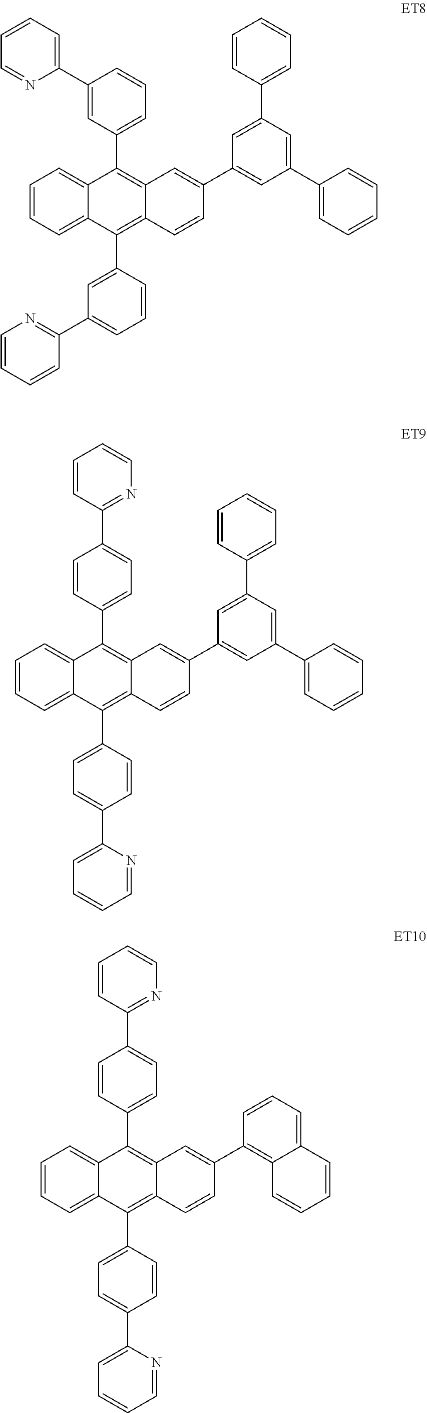

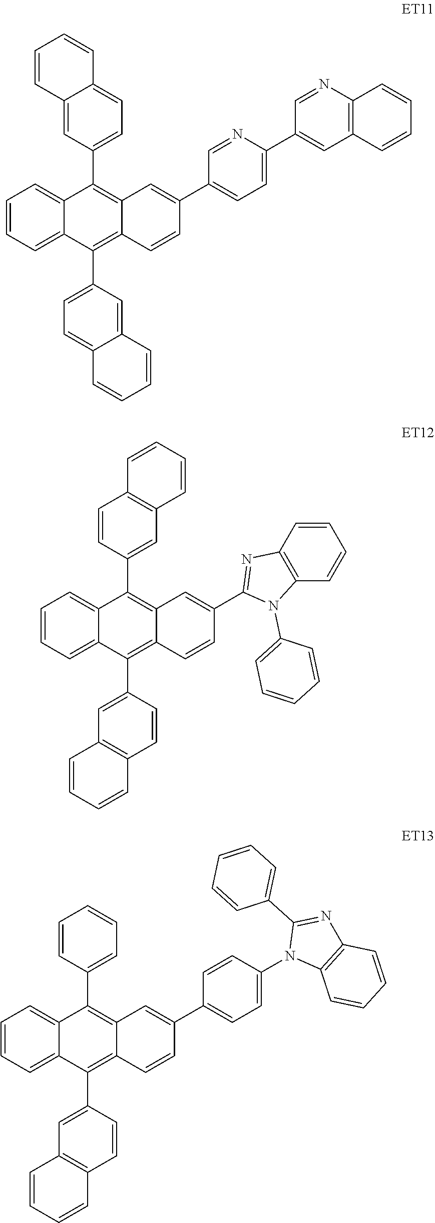 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

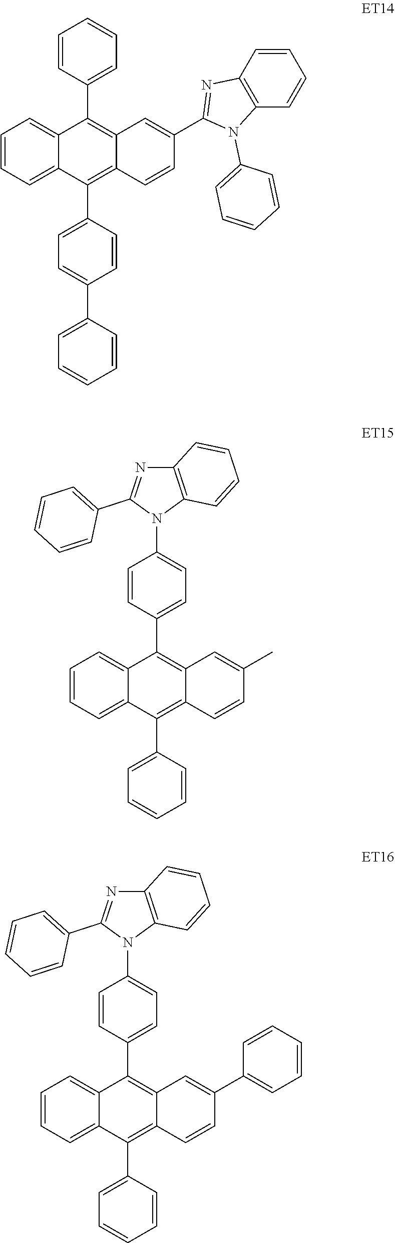 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

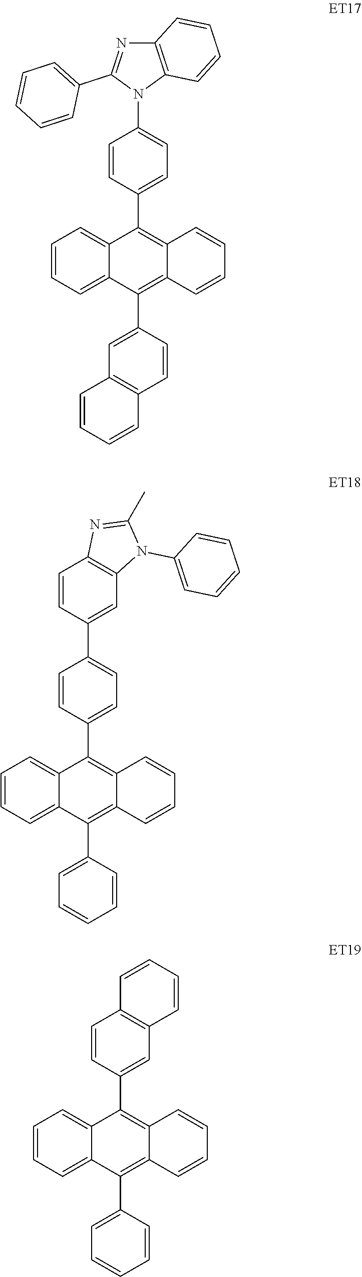

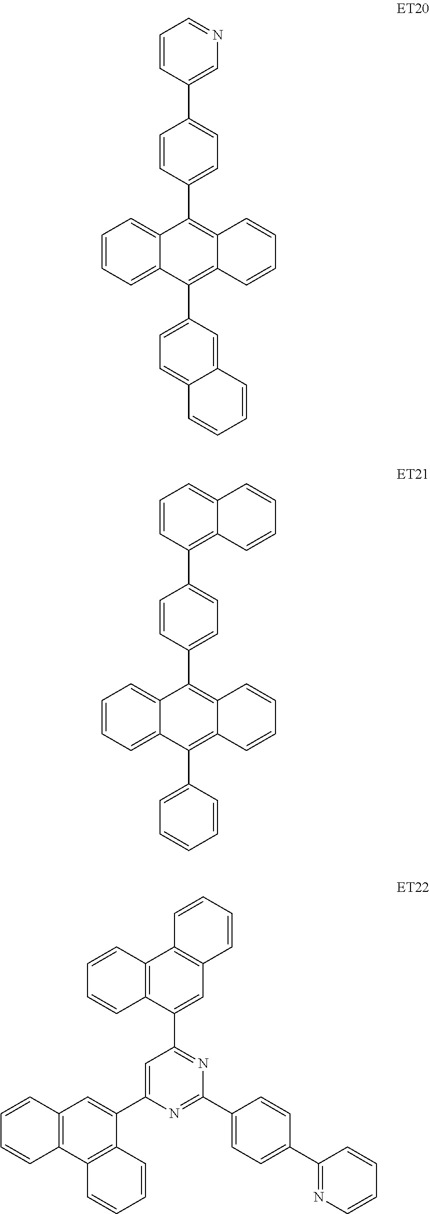

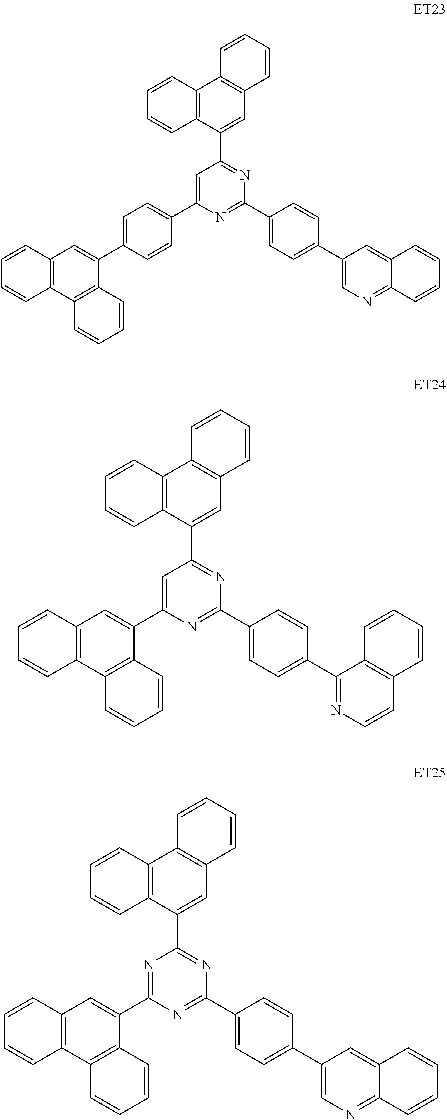 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

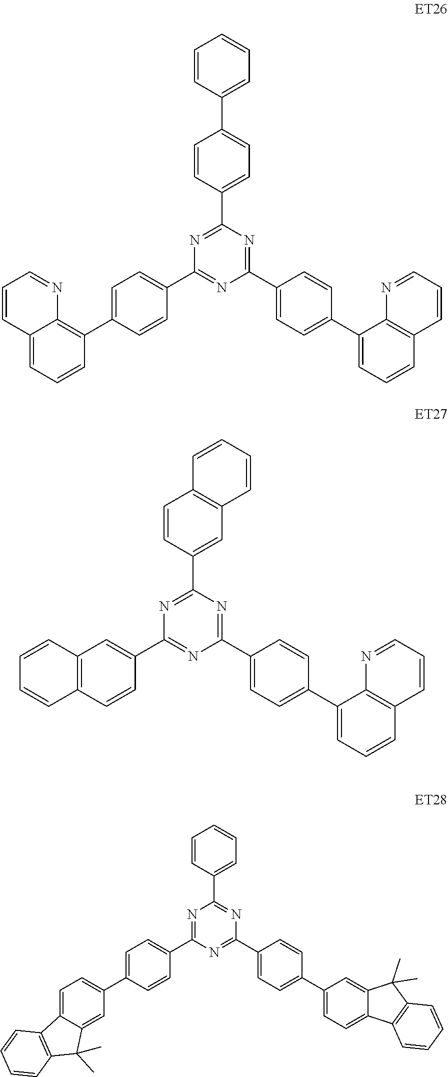 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

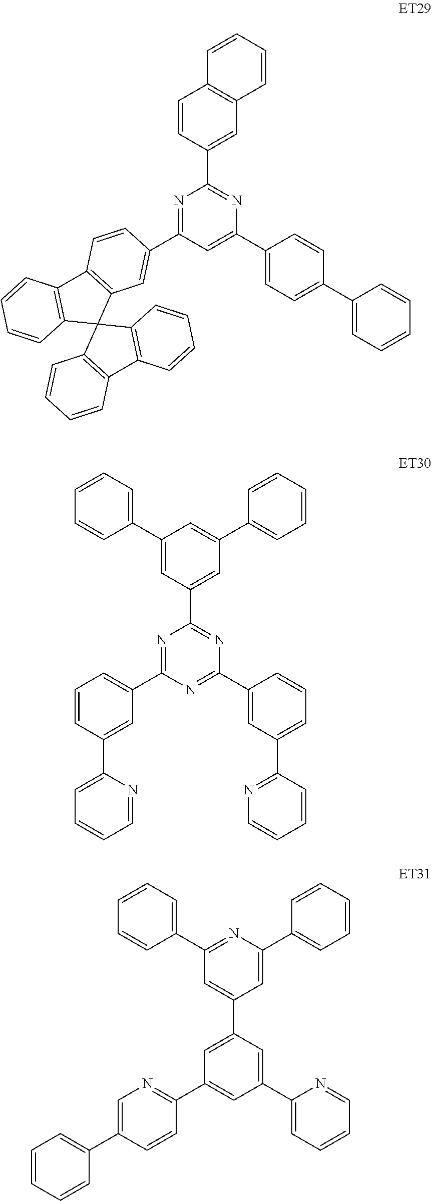 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

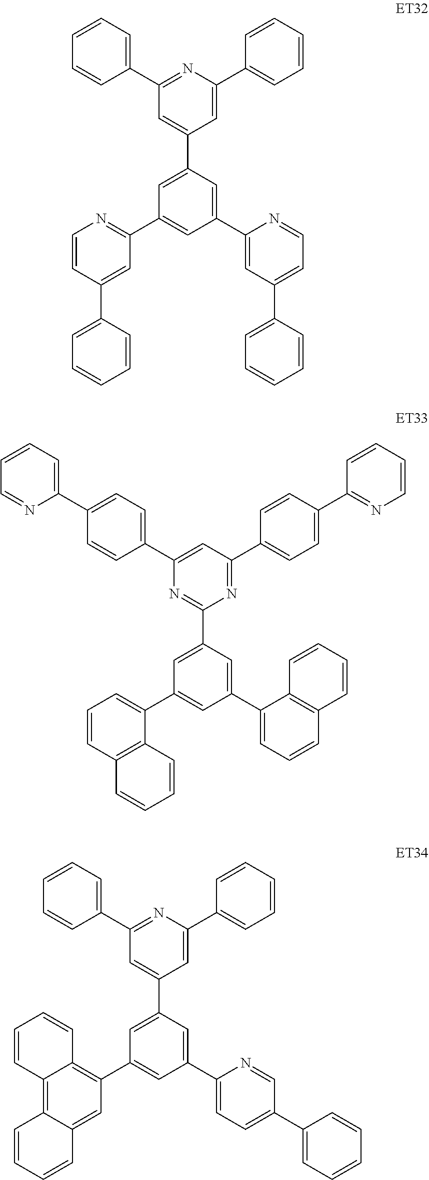 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

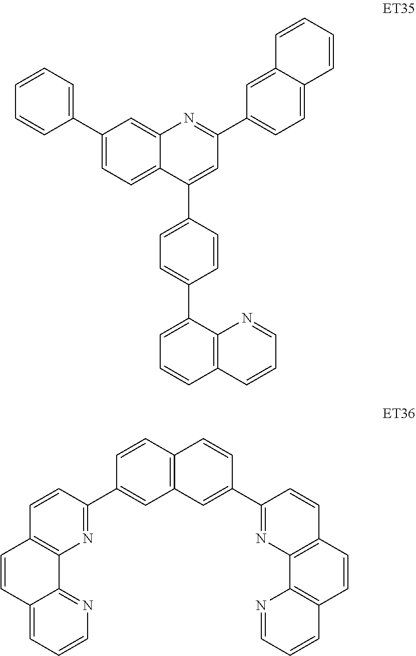 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the first and second electron transport regions ETR1 and ETR2 may each independently include a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbJ:Yb, LiF:Yb, etc., as a co-deposited material. The first and second electron transport regions ETR1 and ETR2 may each independently be formed of a metal oxide such as Li₂O and BaO, or 8-hydroxyl-lithium quinolate (Liq), etc., but embodiments are not limited thereto. The first and second electron transport regions ETR1 and ETR2 may each independently be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The first and second electron transport regions ETR1 and ETR2 may each independently further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The first and second electron transport regions ETR1 and ETR2 may include the above-described compounds of the electron transport region in at least one of an electron injection layers EIL1 and EIL2, an electron transport layers ETL1 and ETL2, and a hole blocking layers (not shown), respectively.

In case that the first and second electron transport regions ETR1 and ETR2 include electron transport layers ETL1 and ETL2, respectively, the electron transport layers ETL1 and ETL2 may each independently have a thickness in a range of about 100 Å to about 1,000 Å.

For example, the electron transport layers ETL1 and ETL2 may each independently have a thickness in a range of about 150 Å to about 500 Å. In case that the thicknesses of the electron transport layers ETL1 and ETL2 satisfy any of the above-described ranges, satisfactory electron transport properties may be obtained without a substantial increase in driving voltage. In case that the first and second hole transport regions ETR1 and ETR2 respectively include hole injection layers EIL1 and EIL2, the hole injection layers EIL1 and EIL2 may each independently have a thickness in a range of about 1 Å to about 100 Å. For example, the hole injection layers EIL1 and EIL2 may each independently have a thickness in a range of about 3 Å to about 90 Å. In case that the thicknesses of the electron injection layers EIL1 and EIL2 satisfy any of the above-described ranges, satisfactory electron injection properties may be obtained without a substantial increase in driving voltage.

The charge generation layer CGL1 may generate charges (electrons and holes) by forming a complex through an oxidation-reduction reaction in case that a voltage is applied thereto. The charge generation layer CGL1 may provide the generated electrons to each of the adjacent light emitting units OL1 and OL2. The charge generation layer CGL1 may increase the efficiency of current generated in each of the adjacent light emitting units OL1 and OL2 and may adjust the balance of charges between the adjacent light emitting units OL1 and OL2.

The charge generation layer CGL1 may include the p-type charge generation layer p-CGL1 and/or the n-type charge generation layer n-CGL1. The charge generation layer CGL1 may have a stacked structure in which the n-type charge generation layer n-CGL1 and the p-type charge generation layer p-CGL1 are bonded to each other.

The n-type charge generation layer n-CGL1 may be a charge generation layer that provides electrons to the adjacent light emitting units OL1 and OL2. The n-type charge generation layer n-CGL1 may include an n-dopant. The n-type charge generation layer n-CGL1 may be a layer in which the n-dopant is doped in a base material. The p-type charge generation layer p-CGL1 may be a charge generation layer that provides holes to the adjacent light emitting units OL1 and OL2. The p-type charge generation layer p-CGL1 may include a p-dopant. The p-type charge generation layer p-CGL1 may be a layer in which the p-dopant is doped in the base material. Although not shown in the drawings, a buffer layer (not shown) may be further disposed between the n-type charge generation layer n-CGL1 and the p-type charge generation layer p-CGL1.

The charge generation layers CGL1 may include an n-type aryl amine-based material or a p-type metal oxide. For example, the charge generation layers CGL1 may include a charge generation compound including an aryl amine-based organic compound, a carbazole-based compound, a metal, an oxide of a metal, a carbide of a metal, a fluoride of a metal, or a mixture thereof.

For example, the aryl amine-based organic compound may be N,N′-di(naphthalene-1-yl)-N,N′-diphenyl-benzidine (α-NPD), 4,4′,4″-tris[N(2-naphthyl)-N-phenylamino]-triphenylamine (2-TNATA), 4,4′,4″-tris(N,N-diphenylamino)triphenylamine (TDATA), 4,4′,4″-[tris(3-methylphenyl)phenylamino] triphenylamine (m-TDATA), spiro-TAD, or spiro-NPB, and the carbazole-based compound may be 4,4′-bis(carbazol-9-yl)biphenyl (CBP). For example, the metal may be cesium (Cs), molybdenum (Mo), vanadium (V), titanium (Ti), tungsten (W), barium (Ba), or lithium (Li). For example, the oxide, carbide, and fluoride of the metal may be Re₂O₇, MoO₃, V₂O₅, WO₃, TiO₂, Cs₂CO₃, BaF, LiF, or CsF.

The second electrode EL2 is provided on the second light emitting unit OL2. For example, the second electrode EL2 may be provided on the second electron transport region ETR2. In case that the light emitting element ED includes n light emitting units OL1 to OLn, the second electrode EL2 may be provided on the n-th electron transport region ETRn. The second electrode EL2 may be a common electrode. The second electrode EL2 may be a cathode or an anode, but embodiments are not limited thereto. For example, in case that the first electrode EL1 is an anode, the second electrode EL2 may be a cathode, and in case that the first electrode EL1 is a cathode, the second electrode EL2 may be an anode. The second electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. In case that the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

In case that the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, a compound thereof, or a mixture thereof (e.g., AgMg, AgYb, or MgYb). In another embodiment, the second electrode EL2 may have a multi-layered structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown, the second electrode EL2 may be electrically connected to an auxiliary electrode. If the second electrode EL2 is electrically connected to the auxiliary electrode, resistance of the second electrode EL2 may decrease.

In an embodiment, the light emitting element ED may further include a capping layer which may be disposed on the second electrode EL2. The capping layer may be a multilayer or a single layer.

In an embodiment, the capping layer may include an organic layer or an inorganic layer. For example, in case that the capping layer includes an inorganic material, the inorganic material may include an alkaline metal compound (e.g., LiF), an alkaline earth metal compound (e.g., MgF₂), SiON, SiNₓ, SiOy, etc.

For example, in case that the capping layer includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., or may include an epoxy resin or acrylate such as methacrylate. However, embodiments are not limited thereto. The capping layer may include at least one compound selected from Compounds P1 to P5:

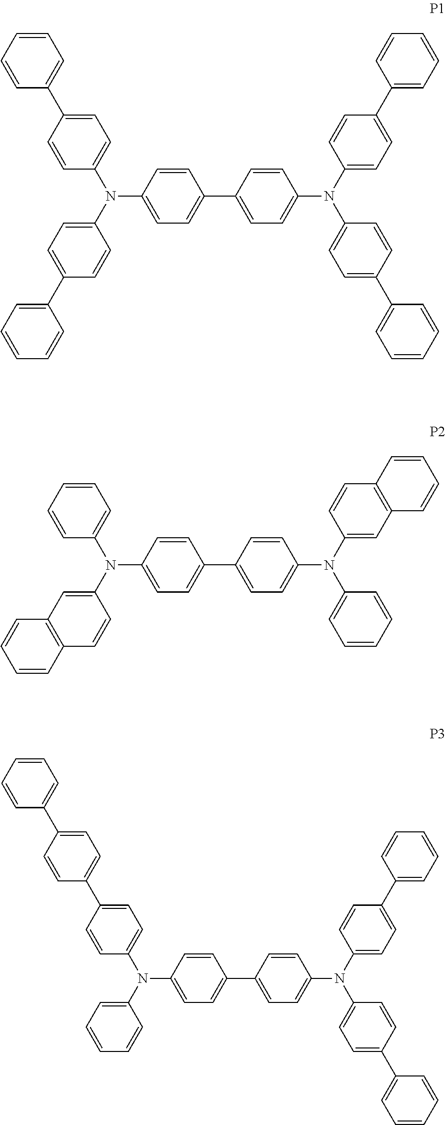 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

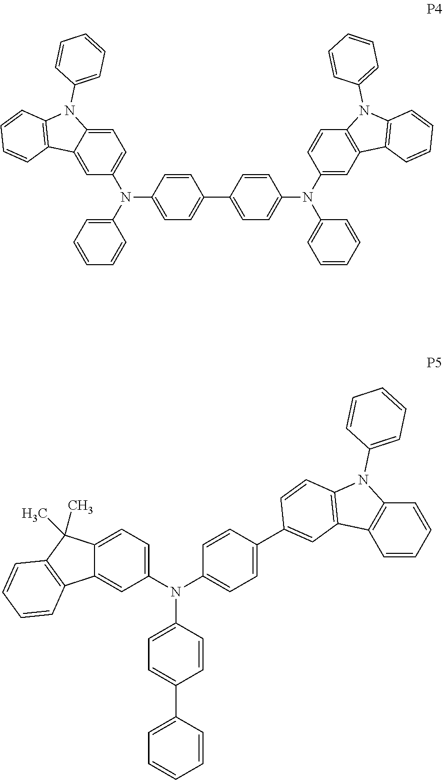 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer may have a refractive index equal to or greater than about 1.6. For example, the capping layer may have a refractive index equal to or greater than about 1.6 with respect to light in a wavelength range from about 550 nm to about 660 nm.

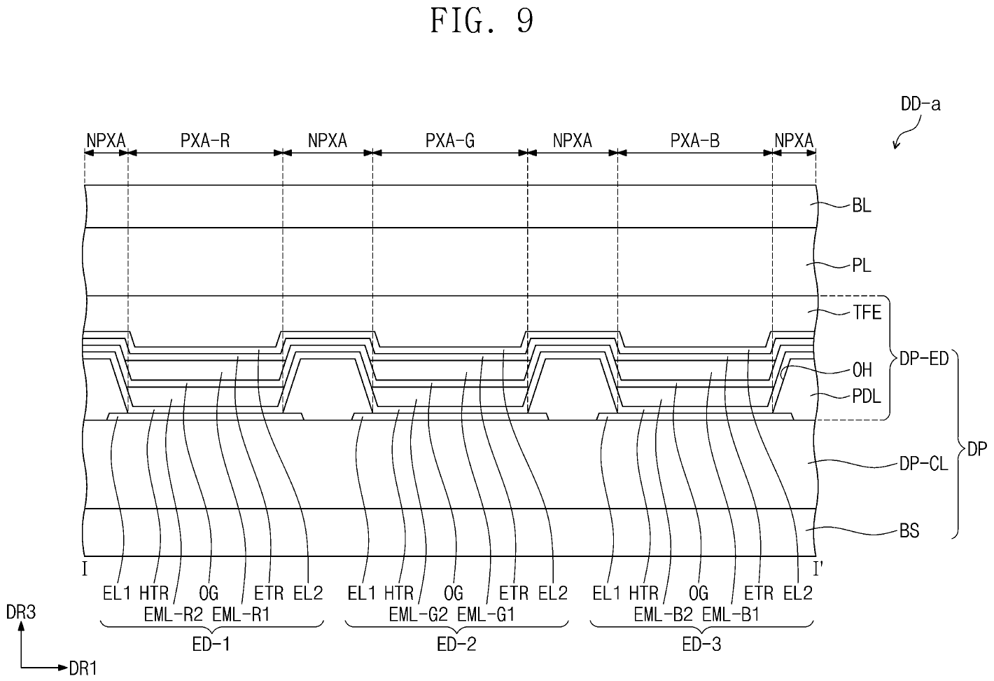

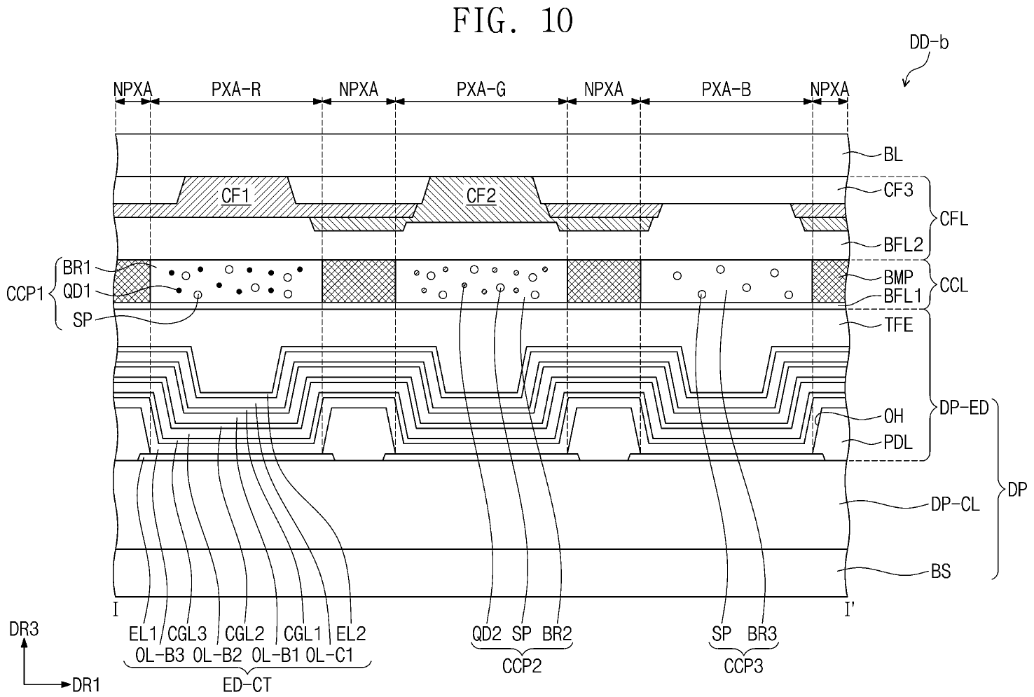

FIGS. 9 and 10 are each a schematic cross-sectional view of a display device according to an embodiment. In the descriptions of the display apparatuses according to embodiments as shown in FIGS. 9 and 10, the features which have been described above with respect to FIGS. 1 to 8 will not be explained again and the differing features will be described.

Referring to FIG. 9, the display device DD-a according to an embodiment may include light emitting elements ED-1, ED-2, and ED-3 in which two emission layers are stacked. The first to third light emitting elements ED-1, ED-2, and ED-3 are shown in FIG. 9 each include two emission layers stacked in a thickness direction between the hole transport region HTR and the electron transport region ETR. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

In an embodiment, at least one of the first blue emission layer EML-B1 or the second blue emission layer EML-B2 may include the hole transporting host, the electron transporting host, the phosphorescent sensitizer, and the first fluorescent dopant as described above. For example, the first blue emission layer EML-B1 and the second blue emission layer EML-B2 may each independently include the hole transporting host, the electron transporting host, the phosphorescent sensitizer, and the first fluorescent dopant as described above. As another example, one of the first blue emission layer EML-B1 and the second blue emission layer EML-B2 may include the hole transporting host, the electron transporting host, the phosphorescent sensitizer, and the first fluorescent dopant as described above, and the other may include the hole transporting host, the electron transporting host, and the second fluorescent dopant as described above.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

The first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

An optical auxiliary layer PL may be disposed on the display element layer DP-ED. The optical auxiliary layer PL may include a polarizing layer. The optical auxiliary layer PL may be disposed on the display panel DP and control light that is reflected at the display panel DP from an external light. Although not shown in FIG. 9, in an embodiment, the optical auxiliary layer PL in the display device may be omitted.

In contrast to FIG. 9, FIG. 10 shows a display device DD-b that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may each be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 disposed between adjacent light emitting structures OL-B1, OL-B2, OL-B3, and OL-C1 may include a p-type charge generation layer and/or an n-type charge generation layer.

In an embodiment, at least one of the light emitting structures OL-B1, OL-B2, and OL-B3 included in the display device DD-b may include a hole transporting host, an electron transporting host, a phosphorescent sensitizer, and a first fluorescent dopant as described above. The light emitting structures OL-B1, OL-B2, and OL-B3 may each independently include an emission layer. At least one emission layer in the light emitting structures OL-B1, OL-B2, and OL-B3 may include a hole transporting host, an electron transporting host, a phosphorescent sensitizer, and a first fluorescent dopant as described above, and the remainder of the emission layers may include a hole transporting host, an electron transporting host, and a second fluorescent dopant as described above.

In an embodiment, the electronic device may include a display device including multiple light emitting elements, and a control part which controls the display device. The electronic device according to an embodiment may be a device that is activated according to an electrical signal. The electronic device may include display devices of various embodiments. For example, the electronic device may include not only large-sized electronic devices such as a television set, a monitor, or an outdoor billboard; or small- and medium-sized electronic devices such as a personal computer, a laptop computer, a personal digital terminal, a display device for a vehicle, a game console, a portable electronic device, or a camera. However, these are merely presented as examples, and thus may be employed in other electronic apparatuses.

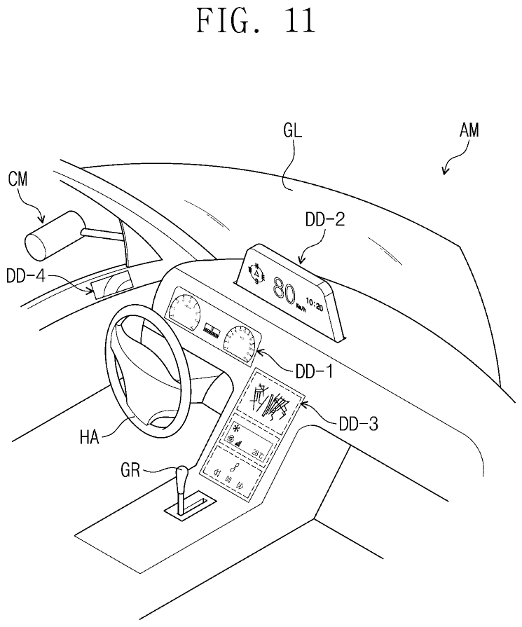

FIG. 11 is a schematic perspective view of an interior of a vehicle in which display devices are disposed, according to embodiments. FIG. 11 illustrates a vehicle AM as an example of an electronic device that includes the display devices.

Referring to FIG. 11, the electronic device according to an embodiment may include the display devices DD-1, DD-2, DD-3, and DD-4 for the vehicle AM. FIG. 10 illustrates the first to fourth display devices DD-1, DD-2, DD-3, and DD-4 as display devices for a vehicle AM disposed inside the vehicle AM. FIG. 11 illustrates an automobile as an example of the vehicle AM. However, embodiments are not limited thereto, and the first to fourth display devices DD-1, DD-2, DD-3, and DD-4 may be disposed in various transportation means such as bicycles, motorcycles, trains, ships, and airplanes. At least one of the first to fourth display devices DD-1, DD-2, DD-3, and DD-4 may have a structure according to one of display devices DD, DD-a, and DD-b, as described with reference to FIG. 1, FIG. 2, FIG. 4, FIG. 8, and FIG. 9.

In an embodiment, at least one of the first to fourth display devices DD-1, DD-2, DD-3, and DD-4 may include the light emitting element ED as described with reference to FIGS. 5 to 8. The first to fourth display devices DD-1, DD-2, DD-3, and DD-4 may each independently include multiple light emitting elements ED. Each light emitting element ED included in the first to fourth display devices DD-1, DD-2, DD-3, and DD-4 may include multiple emission layers, and at least one of the emission layers may include the hole transporting host, the electron transporting host, the phosphorescent sensitizer, and the first fluorescent dopant having a difference (E_{ST,F1}) between the singlet state energy level and the triplet state energy level equal to or greater than about 0.4 eV. Accordingly, the electronic device of an embodiment may exhibit improved image quality.

Referring to FIG. 11, the vehicle AM may include a steering wheel HA and a gearshift GR for driving the vehicle AM. The vehicle AM may include a windshield GL disposed so as to face the driver.

The first display device DD-1 may be disposed in a first region that overlaps the steering wheel HA. For example, the first display device DD-1 may be a digital cluster which displays first information of the vehicle AM. The first information may include a first scale which indicates a driving speed of the vehicle AM, a second scale which indicates an engine speed (for example, revolutions per minute (RPM)), a fuel gauge, etc. The first scale and the second scale may each be displayed as a digital image.

The second display device DD-2 may be disposed in a second region facing the driver's seat and overlapping the windshield GL. The driver's seat may be a seat where the steering wheel HA is disposed. For example, the second display device DD-2 may be a head up display (HUD) that displays second information of the vehicle AM. The second display device DD-2 may be optically transparent. The second information may include digital numbers that indicate a driving speed and may further include information such as the current time. Although not shown in FIG. 11, in an embodiment, the second information of the second display device DD-2 may be projected onto the windshield GL to be displayed.

The third display device DD-3 may be disposed in a third region adjacent to the gearshift GR. For example, the third display device DD-3 may be a center information display (CID) for a vehicle that displays third information, and the third display apparatus DD-3 may be disposed between the driver's seat and the passenger seat. The passenger seat may be a seat that is spaced apart from the driver's seat with the gearshift GR disposed therebetween. The third information may include information about traffic (e.g., navigation information), playing music or radio or a video (or an image), temperatures inside the vehicle AM, etc.

The fourth display device DD-4 may be spaced apart from the steering wheel HA and the gearshift GR, and may be disposed in a fourth region adjacent to a side of the vehicle AM. For example, the fourth display device DD-4 may be a digital side-view mirror that displays fourth information. The fourth display device DD-4 may display an image outside the vehicle AM that is taken by a camera module CM disposed outside the vehicle AM. The fourth information may include an image outside of the vehicle AM.

The first to fourth information as described above are only presented as examples, and the first to fourth display devices DD-1, DD-2, DD-3, and DD-4 may further display information about the interior and exterior of the vehicle AM. The first to fourth information may include information that is different from each other. However, embodiments are not limited thereto, and a part of the first to fourth information may include the same information as one another.

Hereinafter, the light emitting element according to an embodiment will be described with reference to the Examples and the Comparative Examples. The Examples described below are only provided as illustrations to assist in the understanding the disclosure, and the scope thereof is not limited thereto.

### EXAMPLES

### 1. Manufacture of Light Emitting Element

As an anode, an ITO-formed glass substrate of about 15 Ω/cm² (about 1,200 Å) was cut to a size of 50 mm×50 mm×0.7 mm, cleansed by ultrasonic waves using isopropyl alcohol and pure water for about 5 minutes each, and irradiated with ultraviolet rays for about 30 minutes and exposed to ozone and cleansed. The glass substrate was installed on a vacuum deposition apparatus.

On the anode, 2-TNATA was deposited in a vacuum to form a 600 Å-thick first hole injection layer, and on the first hole injection layer, NPB was deposited in a vacuum to form a 300 Å-thick first hole transport layer.

On the upper portion of the first hole injection layer, a first emission layer was formed. On the first emission layer, ET08 was deposited in a vacuum to form a 50 Å-thick first hole blocking layer. On the upper portion of the first hole blocking layer, Alq₃ was deposited to form a 300 Å-thick first electron transport layer. On the upper portion of the first electron transport layer, LiF, which is an alkaline metal halide, was deposited to form a 10 Å-thick first electron injection layer. An 80 Å-thick n-type charge generation layer was formed on the first electron injection layer, and a 100 Å-thick p-type charge generation layer was formed on the n-type charge generation layer.

On the p-type charge generation layer, a second hole injection layer, a second hole transport layer, a second emission layer, a second hole blocking layer, a second electron transport layer, and a second electron injection layer were sequentially formed. The second hole injection layer, the second hole transport layer, the second hole blocking layer, the second electron transport layer, and the second electron injection layer were formed in the same manner as the first hole injection layer, the first hole transport layer, the first hole blocking layer, the first electron transport layer, and the first electron injection layer, respectively.

At least one of the first emission layer and the second emission layer was formed to have a thickness of about 300 Å by co-depositing a mixed host, a phosphorescent sensitizer, and a fluorescent dopant at a weight ratio of about 84:15:1. The mixed host is a mixture of an HT-14 compound (deuterium substitution rate of 100%) and an ET08 compound at a weight ratio of about 5:5. Among the first emission layer and the second emission layer, the emission layer not including the phosphorescent sensitizer was formed to have a thickness of about 300 Å by co-depositing the host mixture and the fluorescent dopant at a weight ratio of about 99:1.

On the upper portion of the second electron injection layer, Al was deposited in a vacuum to form a 3000 Å-thick cathode of LiF/Al, thereby manufacturing a light emitting element.

The compounds used as materials for an emission layer in the light emitting elements of Examples and Comparative Exam les are shown in Table 1.

TABLE 1

| | | Hole | Electron | | |
|---|---|---|---|---|---|
| | | transporting | transporting | Phosphorescent | Fluorescent |
| Division | | host | host | sensitizer | dopant |
| Example 1 | First emission layer | HT-14 | ET08 | Compound 13 | FD-1 |
| Example 1 | Second emission layer | HT-14 | ET08 | — | DA1 |
| Example 2 | First emission layer | HT-14 | ET08 | — | DA1 |
| Example 2 | Second emission layer | HT-14 | ET08 | Compound 13 | FD-1 |
| Example 3 | First emission layer | HT-14 | ET08 | Compound 13 | FD-1 |
| Example 3 | Second emission layer | HT-14 | ET08 | Compound 13 | FD-1 |
| Comparative | First emission layer | HT-14 | ET08 | Compound 13 | DA1 |
| Example 1 | | | | | |
| Comparative | Second emission layer | HT-14 | ET08 | Compound 13 | DA1 |
| Example 1 | | | | | |
| Comparative | First emission layer | HT-14 | ET08 | — | FD-1 |
| Example 2 | | | | | |
| Comparative | Second emission layer | HT-14 | ET08 | — | FD-1 |
| Example 2 | | | | | |

### [Materials for Emission Layer Used in Manufacturing Light Emitting Element]

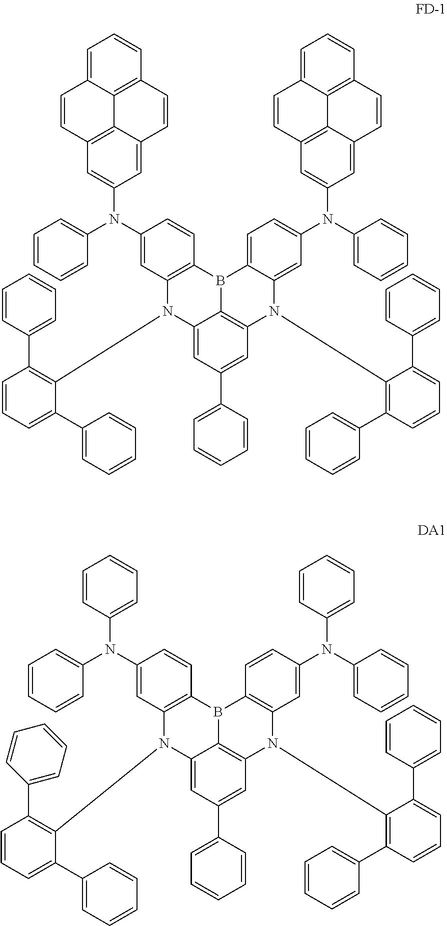 [SMILES: c1ccc(-c2cc3c4c(c2)N(c2c(-c5ccccc5)cccc2-c2ccccc2)c2cc(N(c5ccccc5)c5cc6ccc7cccc8ccc(c5)c6c78)ccc2B4c2ccc(N(c4ccccc4)c4cc5ccc6cccc7ccc(c4)c5c67)cc2N3c2c(-c3ccccc3)cccc2-c2ccccc2)cc1 ; c1ccc(-c2cc3c4c(c2)N(c2c(-c5ccccc5)cccc2-c2ccccc2)c2cc(N(c5ccccc5)c5ccccc5)ccc2B4c2ccc(N(c4ccccc4)c4ccccc4)cc2N3c2c(-c3ccccc3)cccc2-c2ccccc2)cc1]

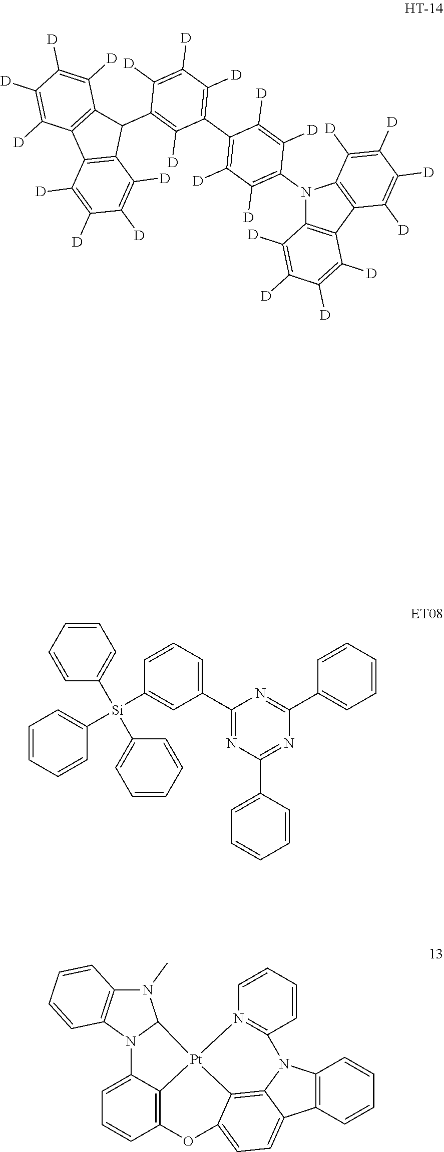

Table 2 shows the FWHM, the singlet state energy level, the triplet state energy level, and the difference between the singlet state energy level and the triplet state energy level of the fluorescent dopant used in manufacturing the light emitting elements of Examples and Comparative Examples. In Table 2, Si represents the singlet state energy level of the fluorescent dopant, and T1 represents the triplet state energy level of the fluorescent dopant. ΔE_{ST} shows the difference between the singlet state energy level and the triplet state energy level of the fluorescent dopant.

TABLE 2

| Division | FWHM (nm) | S1 (eV) | T1 (eV) | ΔE_{ST} (eV) |
|---|---|---|---|---|
| FD-1 | 18 | 2.81 | 2.20 | 0.61 |
| DA1 | 85 | 3.10 | 2.99 | 0.11 |

### 2. Evaluation of Light Emitting Element

Table 3 shows the evaluation results of the relative luminous efficiency and the relative element service life of the light emitting elements according to Examples 1 to 3 and Comparative Examples 1 and 2, respectively. In order to evaluate the characteristics of the light emitting element, the luminous efficiency (cd/A) was measured by using Keithley MU 236. For the element service life, the time taken to reach 95% brightness relative to an initial brightness was measured as a service life (LT₉₅) by using PR650. In Table 2, the luminous efficiency and the element service life are shown as relative values on the basis of the luminous efficiency and the element service life in Example 1 as 100%.

TABLE 3

| | Relative luminous | Relative element service |
|---|---|---|
| | efficiency (%) | life (%) |
| Example 1 | 100 | 100 |
| Example 2 | 120 | 190 |
| Example 3 | 150 | 320 |
| Comparative Example 1 | 190 | 70 |
| Comparative Example 2 | 50 | 65 |

Referring to Table 3, it was confirmed that each of the light emitting elements of Examples include the hole transporting host, the electron transporting host, the phosphorescent sensitizer, and the first fluorescent dopant according to an embodiment in at least one emission layer, thereby having an excellent element service life compared to the light emitting elements of Comparative Examples.

For example, the light emitting elements of Examples 1 and 2 respectively included the hole transporting host, the electron transporting host, and the phosphorescent sensitizer in the first emission layer or the second emission layer, and included the first fluorescent dopant according to an embodiment having a ΔE_{ST} of about 0.4 eV, thereby exhibiting improved luminous efficiency and element service life. The light emitting element of Example 3 includes the hole transporting host, the electron transporting host, the phosphorescent sensitizer, and the first fluorescent dopant according to an embodiment in each of the first emission layer and the second emission layer, thereby exhibiting excellent luminous efficiency and element service life characteristics.

On the other hand, the light emitting element of Comparative Example 1 does not include the first fluorescent dopant in both the first emission layer and the second emission layer, thereby exhibiting significantly reduced element service life compared to Examples. The light emitting element of Comparative Example 2 includes the first fluorescent dopant according to an embodiment in the first and second emission layers but does not include the phosphorescent sensitizer, thereby exhibiting significantly reduced luminous efficiency and element service life characteristics compared to Examples.

The light emitting element according to an embodiment may exhibit improved element characteristics with high efficiency and long service life.

The display device according to an embodiment includes the above-described light emitting elements and thus may have improved extraction efficiency of the light emitted from the light emitting elements.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
a plurality of emission layers disposed between the first electrode and the second electrode, wherein
at least one of the plurality of emission layers comprises a hole transporting host, an electron transporting host, a phosphorescent sensitizer, and a first fluorescent dopant,
the first fluorescent dopant comprises a pentacyclic fused ring core that includes one boron atom and two heteroatoms as ring-forming atoms, and at least one amine substituent of the fused ring core,
the at least one amine substituent is substituted with at least one substituted or unsubstituted pyrenyl group, and
a difference between a triplet state energy level of the first fluorescent dopant and a singlet state energy level of the first fluorescent dopant is equal to or greater than about 0.4 eV.

2. The light emitting element of claim 1, wherein the first fluorescent dopant is represented by Formula 1: 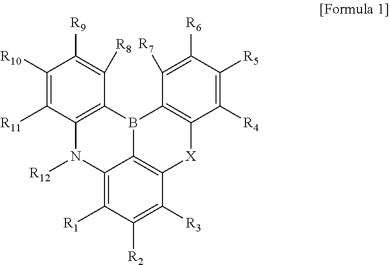
wherein in Formula 1,
X is N(R₁₃), S, or O,
R₁ to R₁₃ are each independently a hydrogen atom, a deuterium atom, a substituted or unsubstituted amine group, or a substituted or unsubstituted aryl group having 3 to 30 ring-forming carbon atoms, and
at least one of R₁ to R₁₁ is each independently a moiety represented by Formula 2: 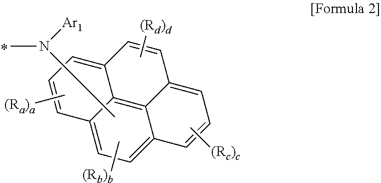
wherein in Formula 2,
Ar₁ is a substituted or unsubstituted aryl group having 3 to 30 ring-forming carbon atoms,
Rₐ to R_{d} are each independently a hydrogen atom or a deuterium atom,
a and c are each independently an integer from 0 to 3, and
b and d are each independently an integer from 0 to 2.

3. The light emitting element of claim 2, wherein in Formula 1,
X is N(R₁₃), and
R₁₂ and R₁₃ are each independently a substituted or unsubstituted biphenyl group or a substituted or unsubstituted terphenyl group.

4. The light emitting element of claim 3, wherein the first fluorescent dopant comprises at least one compound selected from Compound Group 1:

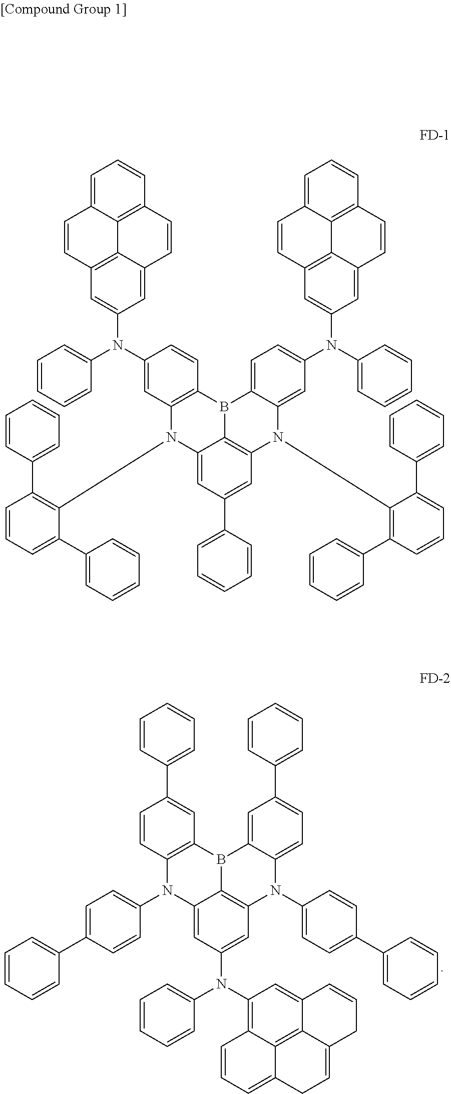 [SMILES: c1ccc(-c2cc3c4c(c2)N(c2c(-c5ccccc5)cccc2-c2ccccc2)c2cc(N(c5ccccc5)c5cc6ccc7cccc8ccc(c5)c6c78)ccc2B4c2ccc(N(c4ccccc4)c4cc5ccc6cccc7ccc(c4)c5c67)cc2N3c2c(-c3ccccc3)cccc2-c2ccccc2)cc1 ; C1=Cc2cc(N(c3ccccc3)c3cc4c5c(c3)N(c3ccc(-c6ccccc6)cc3)c3ccc(-c6ccccc6)cc3B5c3cc(-c5ccccc5)ccc3N4c3ccc(-c4ccccc4)cc3)c3cccc4c3c2C(=CC4)C1]

5. The light emitting element of claim 1, wherein the hole transporting host and the electron transporting host form an exciplex.

6. The light emitting element of claim 5, wherein
a triplet state energy level of the exciplex is higher than a triplet state energy level of the phosphorescent sensitizer, and
the triplet state energy level of the phosphorescent sensitizer is higher than a triplet state energy level of the first fluorescent dopant.

7. The light emitting element of claim 1, wherein light emitted from the first fluorescent dopant has a full width at half maximum (FWHM) equal to or less than about 25 nm.

8. The light emitting element of claim 1, wherein
the plurality of emission layers comprise:
a first emission layer disposed on the first electrode; and
a second emission layer disposed on the first emission layer,
one of the first emission layer and the second emission layer comprises the hole transporting host, the electron transporting host, the phosphorescent sensitizer, and the first fluorescent dopant, and
the other of first emission layer and the second emission layer comprises the hole transporting host, the electron transporting host, and a second fluorescent dopant that is different from the first fluorescent dopant.

9. The light emitting element of claim 8, wherein the second fluorescent dopant has a difference between a singlet state energy level and a triplet state energy level equal to or less than about 0.3 eV.

10. The light emitting element of claim 1, wherein
the plurality of emission layers comprise:
a first emission layer disposed on the first electrode; and
a second emission layer disposed on the first emission layer, and
each of the first emission layer and the second emission layer comprises the hole transporting host, the electron transporting host, the phosphorescent sensitizer, and the first fluorescent dopant.

11. The light emitting element of claim 1, wherein the hole transporting host comprises at least one compound selected from Compound Group 2: 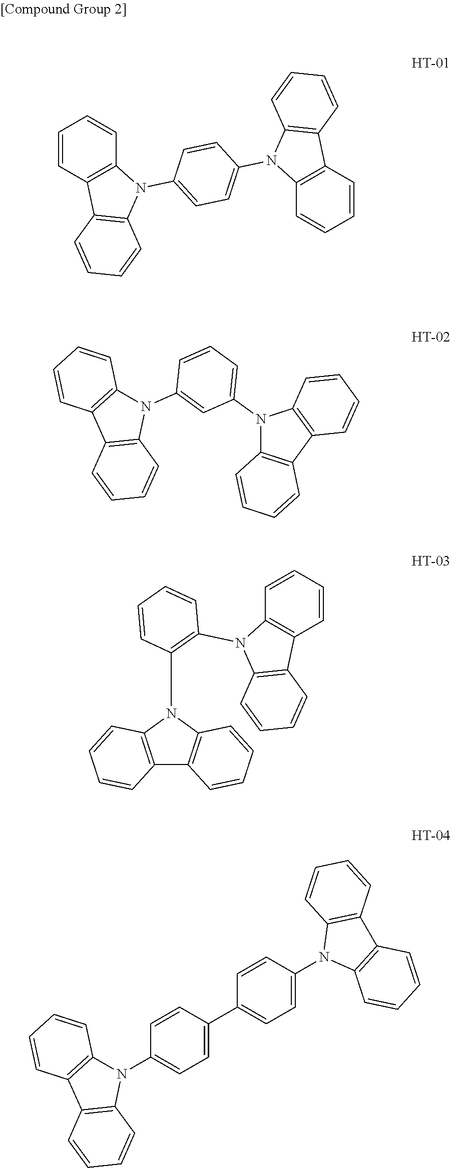 [SMILES: c1ccc2c(c1)c1ccccc1n2-c1ccc(-n2c3ccccc3c3ccccc32)cc1 ; c1cc(-n2c3ccccc3c3ccccc32)cc(-n2c3ccccc3c3ccccc32)c1 ; c1ccc(-n2c3ccccc3c3ccccc32)c(-n2c3ccccc3c3ccccc32)c1 ; c1ccc2c(c1)c1ccccc1n2-c1ccc(-c2ccc(-n3c4ccccc4c4ccccc43)cc2)cc1] 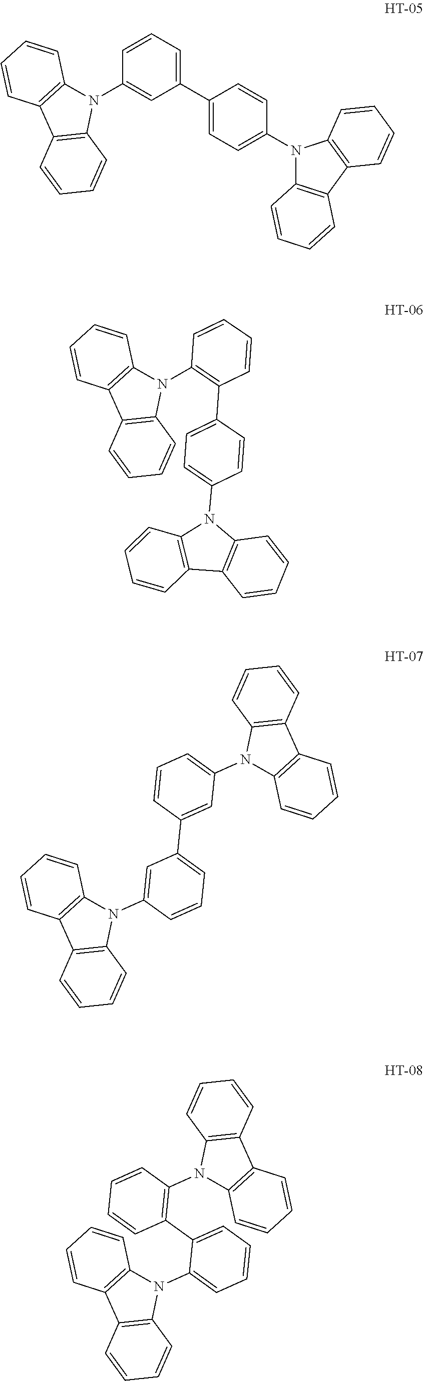 [SMILES: c1cc(-c2ccc(-n3c4ccccc4c4ccccc43)cc2)cc(-n2c3ccccc3c3ccccc32)c1 ; c1ccc(-n2c3ccccc3c3ccccc32)c(-c2ccc(-n3c4ccccc4c4ccccc43)cc2)c1 ; c1cc(-c2cccc(-n3c4ccccc4c4ccccc43)c2)cc(-n2c3ccccc3c3ccccc32)c1 ; c1ccc(-n2c3ccccc3c3ccccc32)c(-c2ccccc2-n2c3ccccc3c3ccccc32)c1] 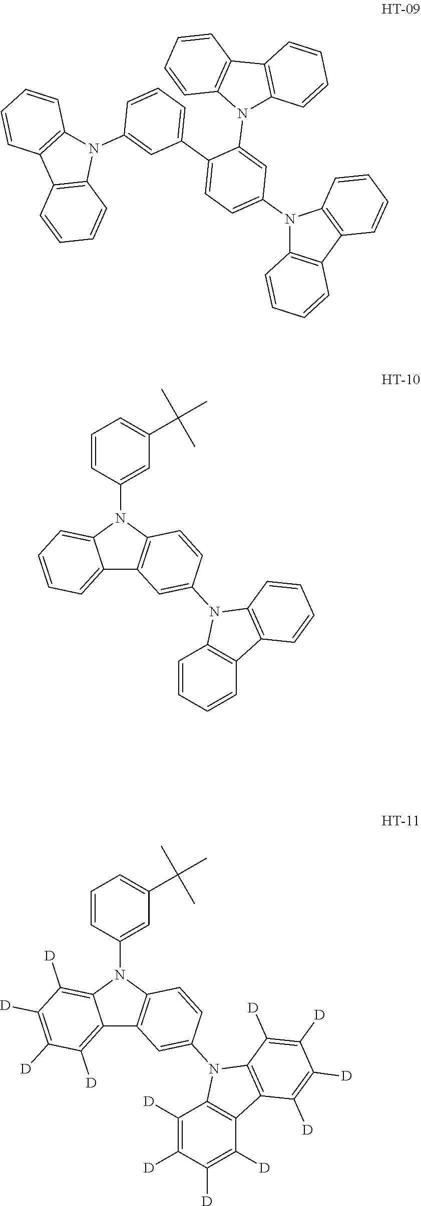 [SMILES: c1cc(-c2ccc(-n3c4ccccc4c4ccccc43)cc2-n2c3ccccc3c3ccccc32)cc(-n2c3ccccc3c3ccccc32)c1 ; CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1] 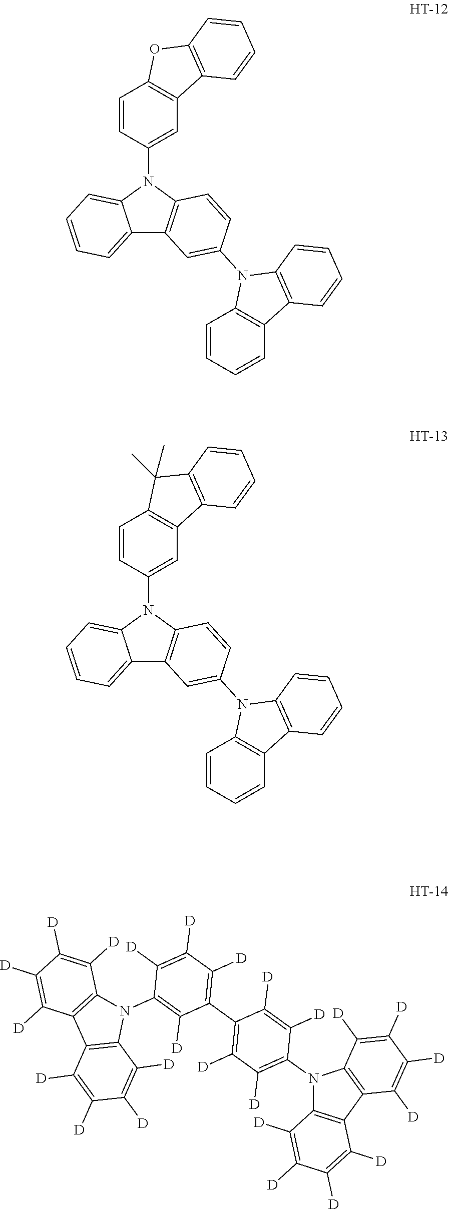 [SMILES: c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21 ; [2H]c1c([2H])c(-c2c([2H])c([2H])c(-n3c4c([2H])c([2H])c([2H])c([2H])c4c4c([2H])c([2H])c([2H])c([2H])c43)c([2H])c2[2H])c([2H])c(-n2c3c([2H])c([2H])c([2H])c([2H])c3c3c([2H])c([2H])c([2H])c([2H])c32)c1[2H]] 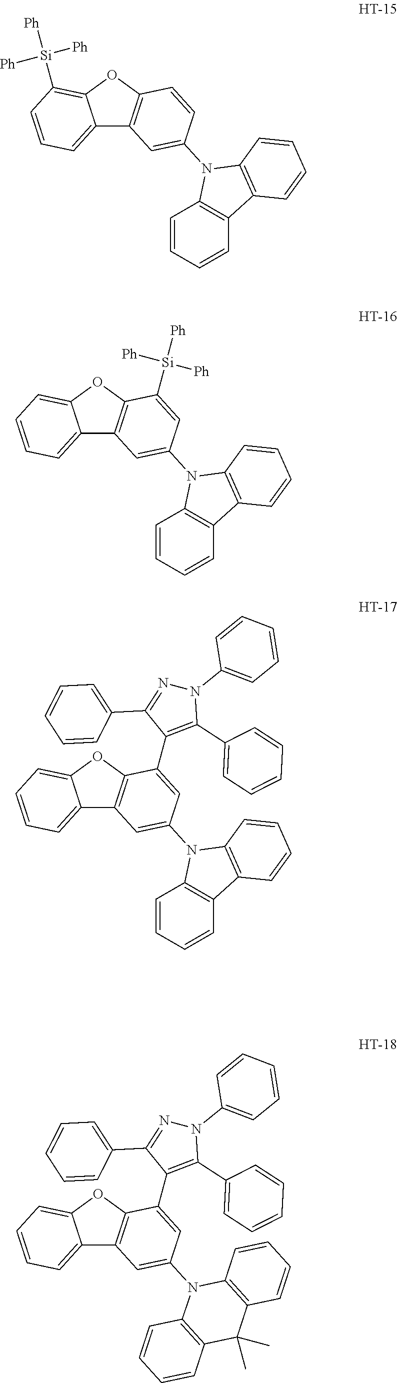 [SMILES: c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21] 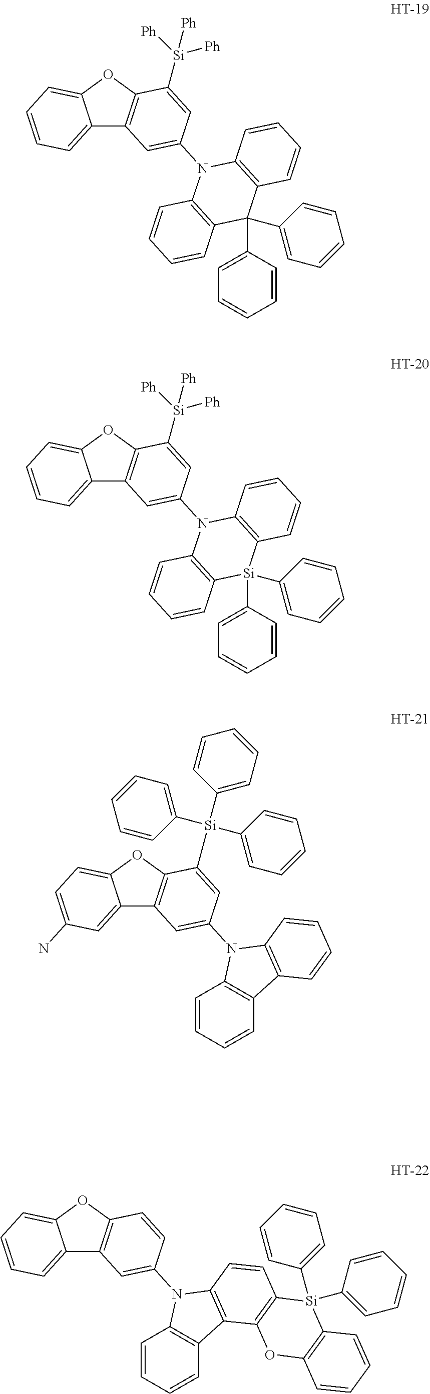 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; Nc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1] 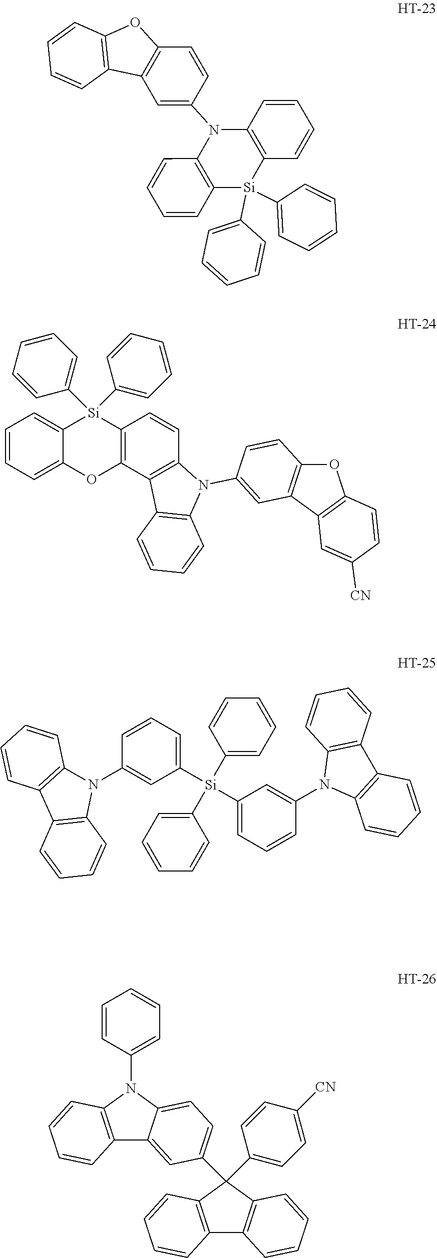 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1] 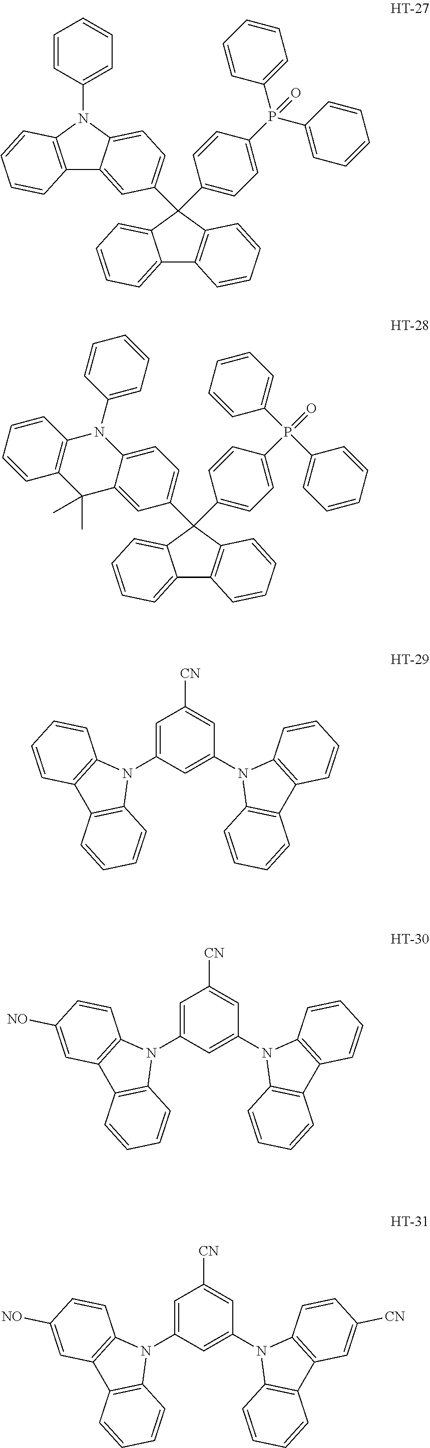 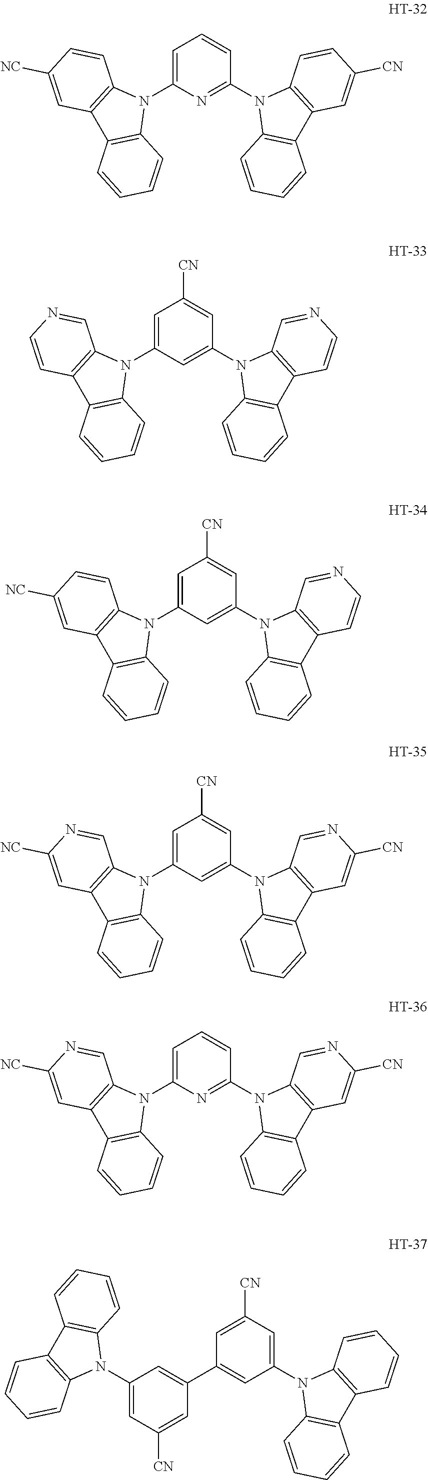 [SMILES: N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1] 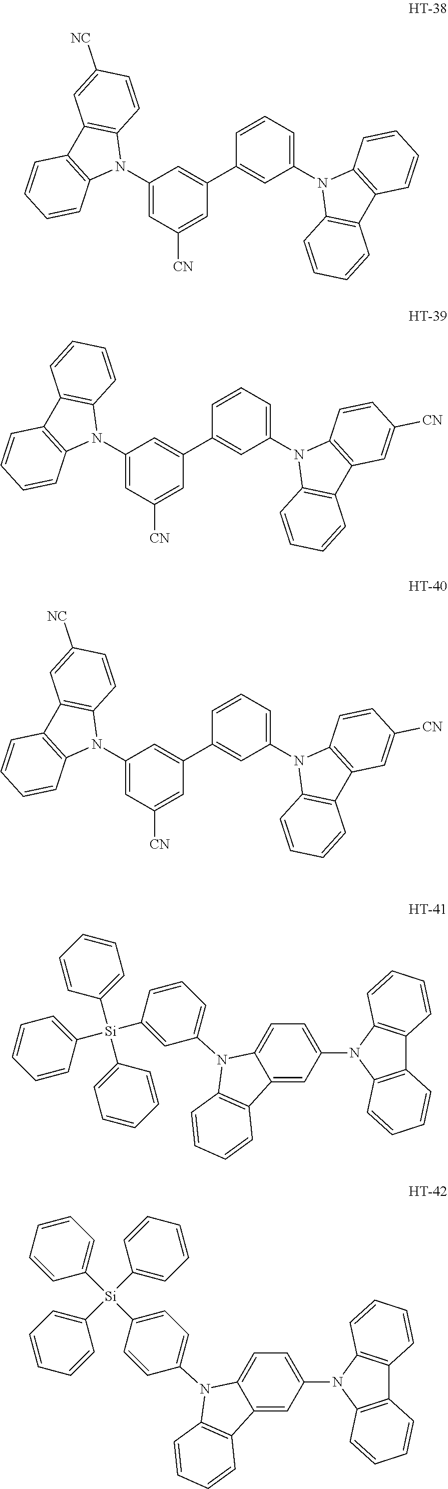 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1] 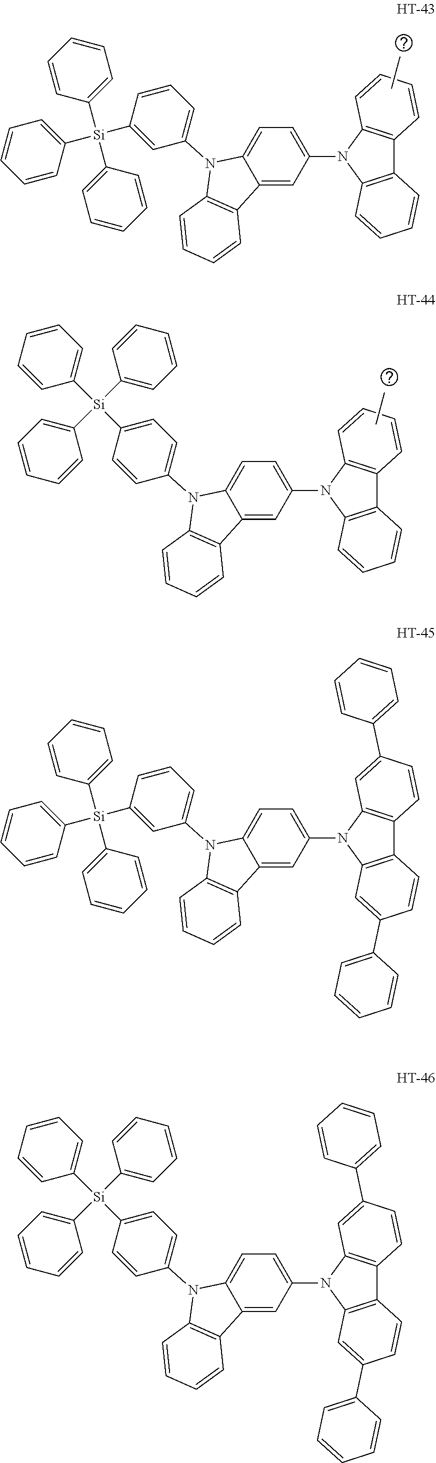 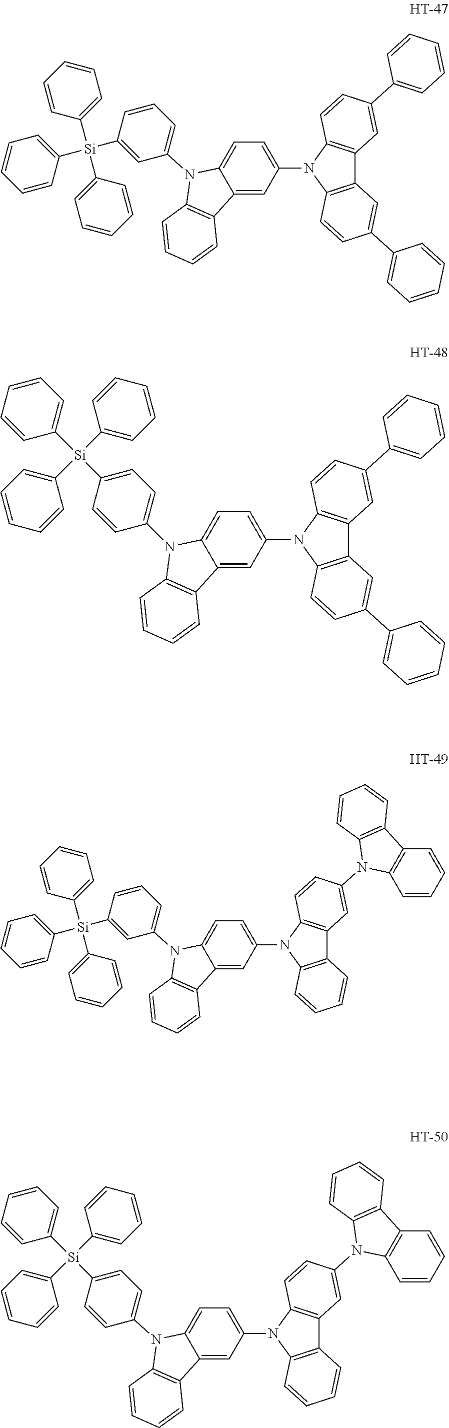 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1] 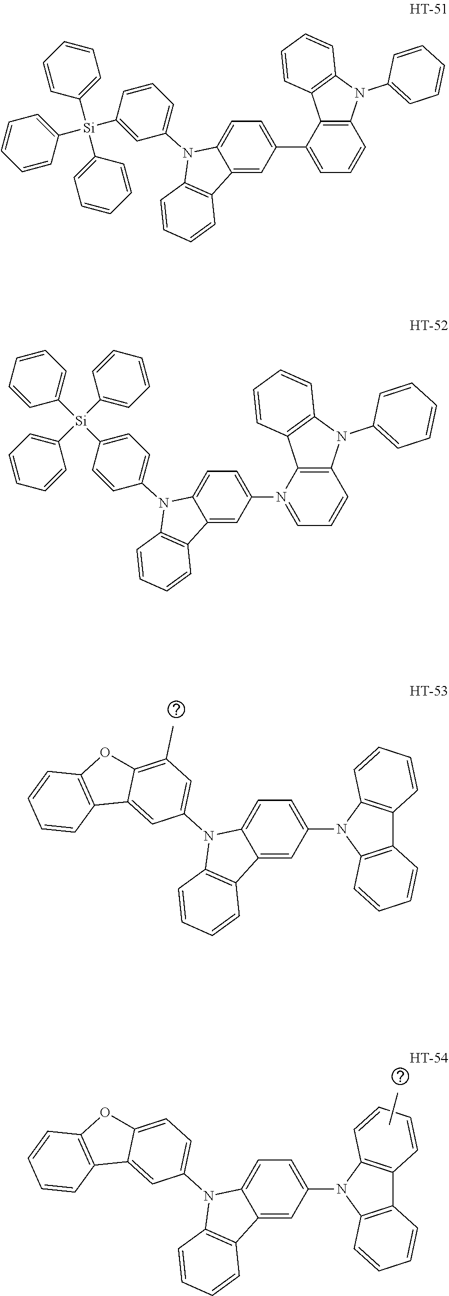 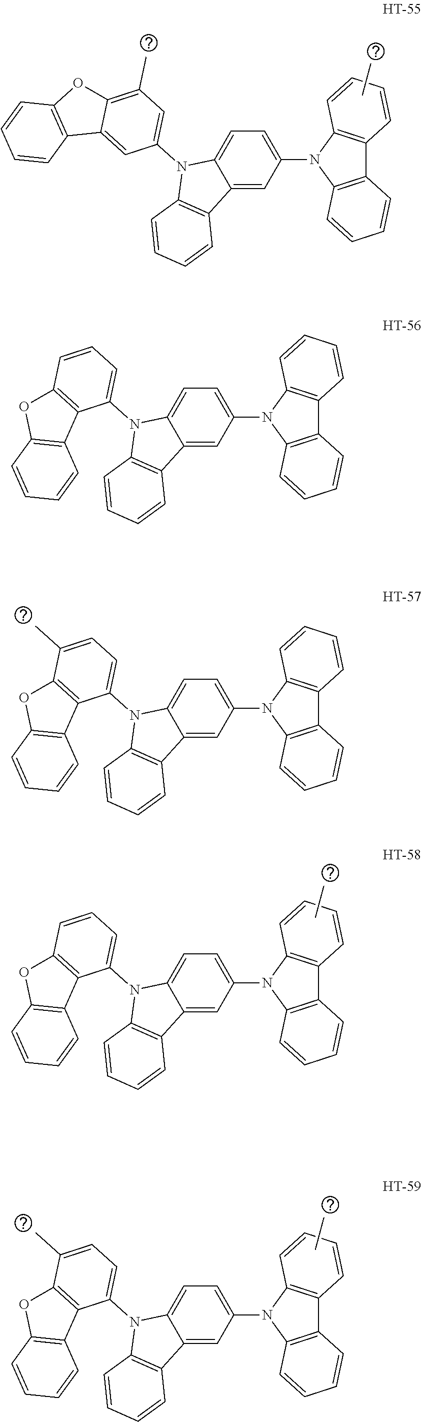 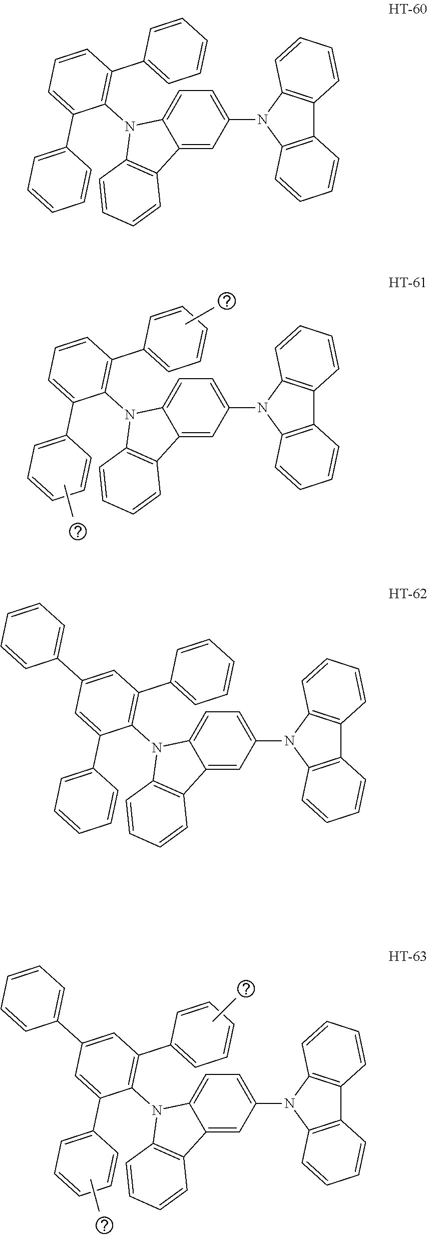 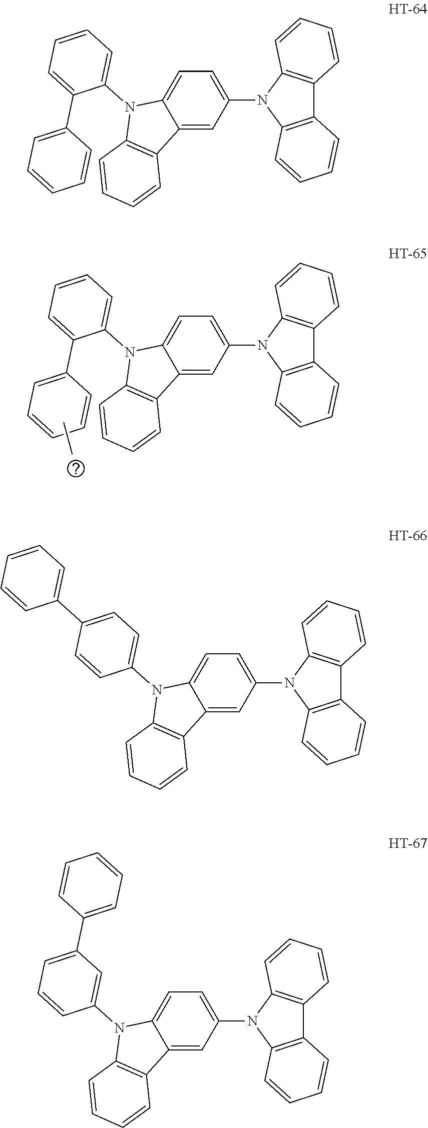
wherein in Compound Group 2,
D represents a deuterium atom.

12. The light emitting element of claim 1, wherein the electron transporting host comprises at least one compound selected from Compound Group 3: 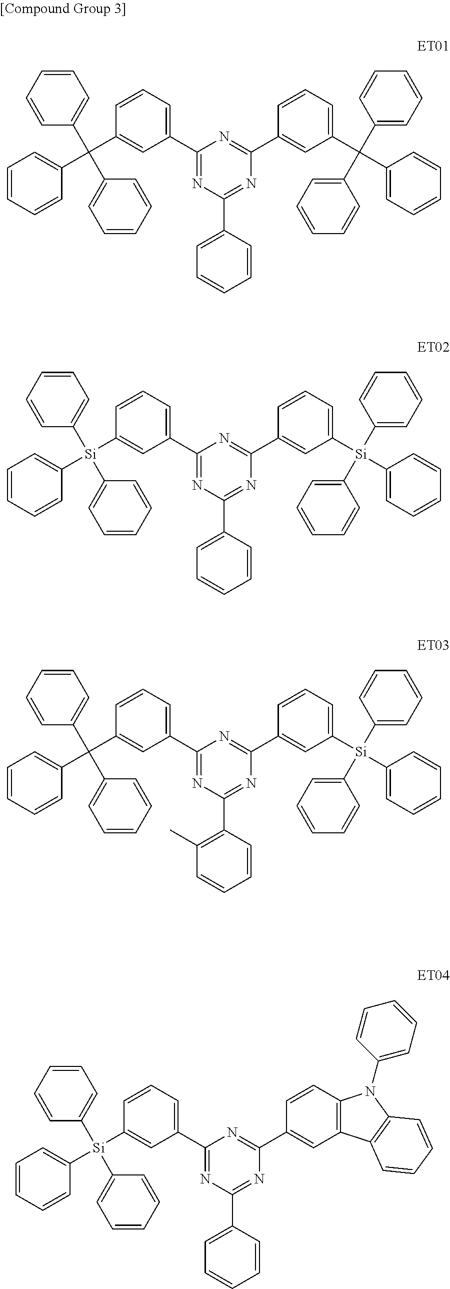 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc([Si](c3ccccc3)(c3ccccc3)c3ccccc3)c2)n1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1] 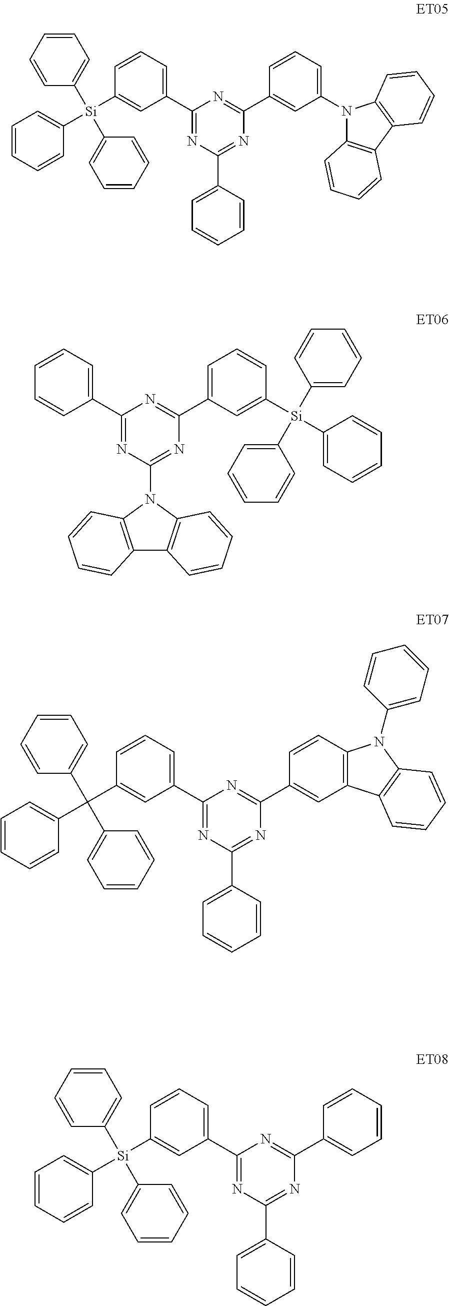 [SMILES: c1ccc(-c2nc(-c3cccc(-n4c5ccccc5c5ccccc54)c3)nc(-c3cccc([Si](c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-n3c4ccccc4c4ccccc43)n2)cc1 ; c1ccc(-c2nc(-c3cccc(C(c4ccccc4)(c4ccccc4)c4ccccc4)c3)nc(-c3ccc4c(c3)c3ccccc3n4-c3ccccc3)n2)cc1 ; c1ccc(-c2nc(-c3ccccc3)nc(-c3cccc([Si](c4ccccc4)(c4ccccc4)c4ccccc4)c3)n2)cc1] 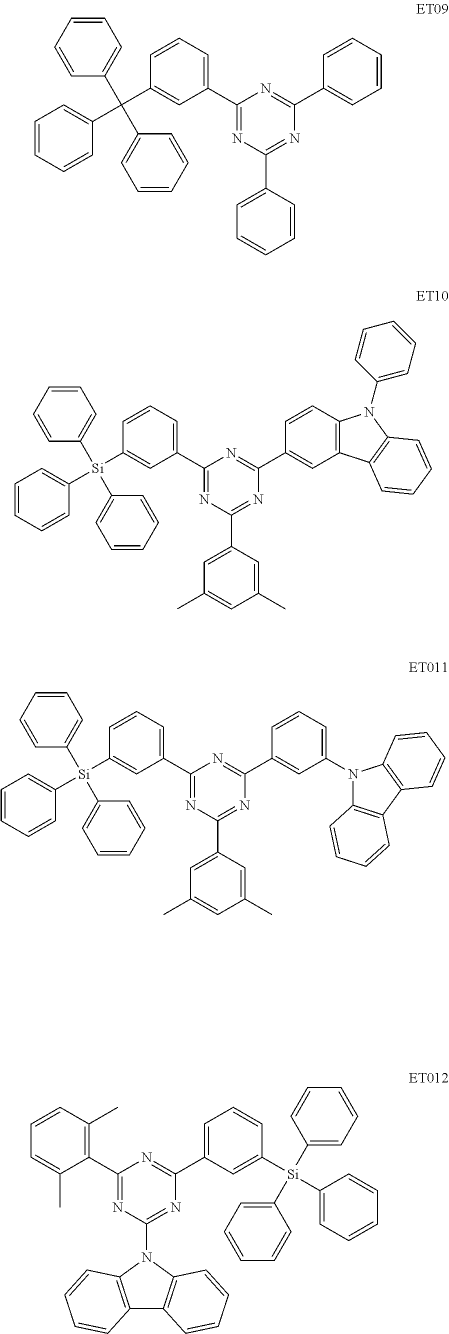 [SMILES: c1ccc(-c2nc(-c3ccccc3)nc(-c3cccc(C(c4ccccc4)(c4ccccc4)c4ccccc4)c3)n2)cc1 ; Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc([Si](c4ccccc4)(c4ccccc4)c4ccccc4)c3)n2)c1 ; Cc1cccc(C)c1-c1nc(-c2cccc([Si](c3ccccc3)(c3ccccc3)c3ccccc3)c2)nc(-n2c3ccccc3c3ccccc32)n1] 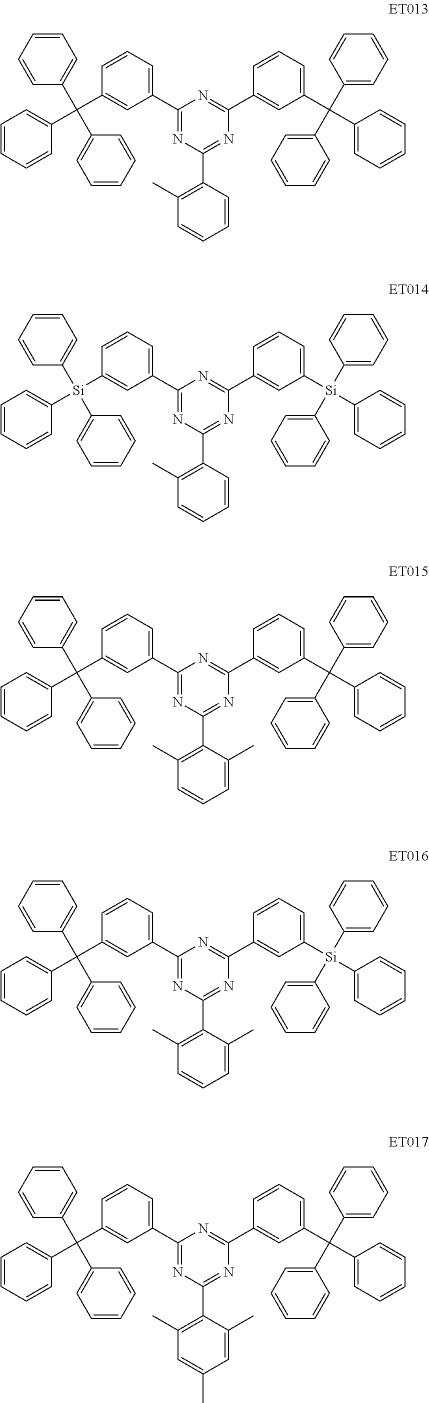 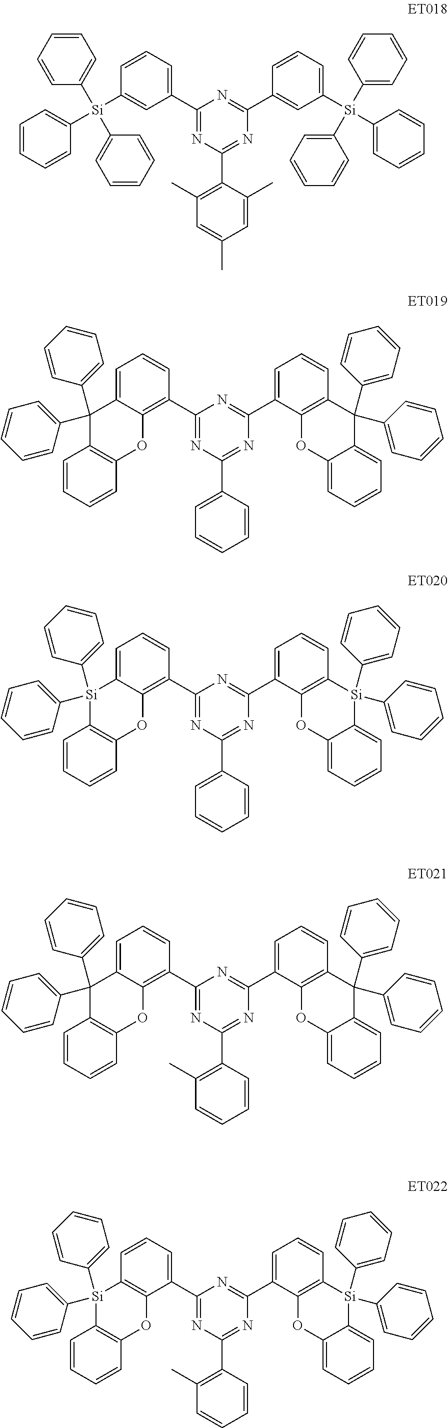 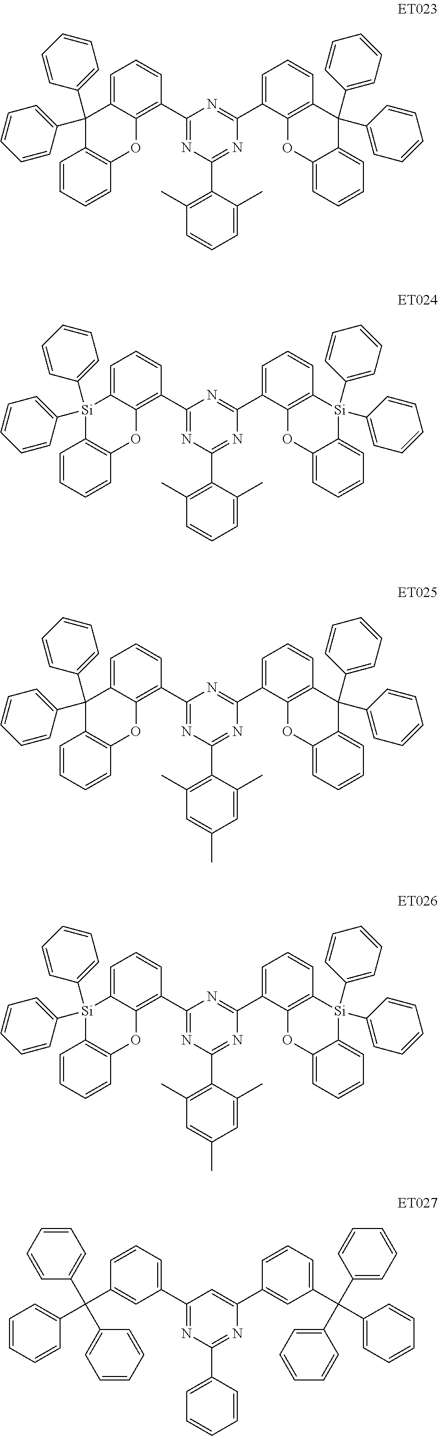 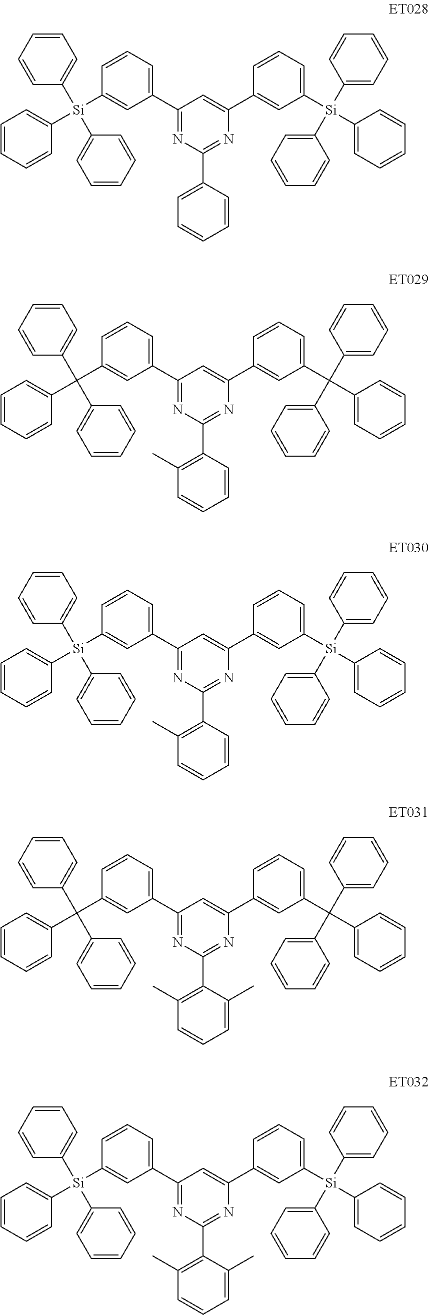 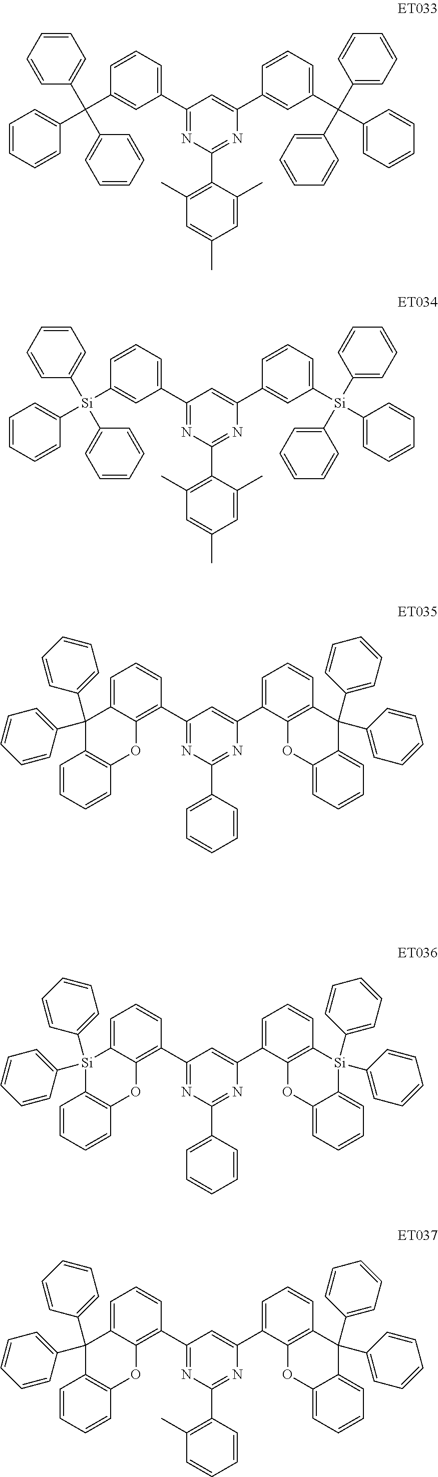 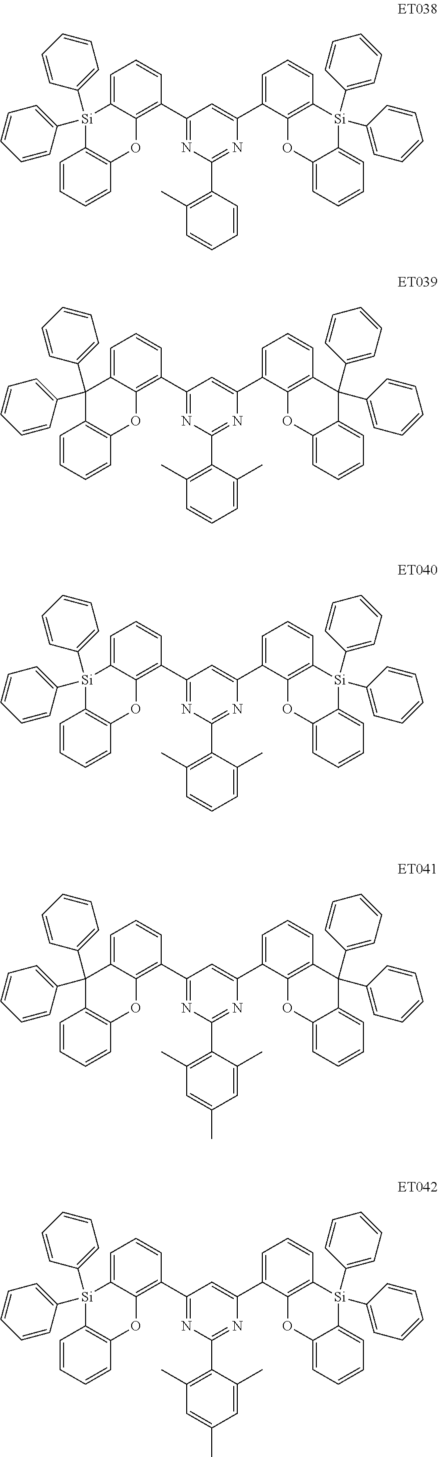 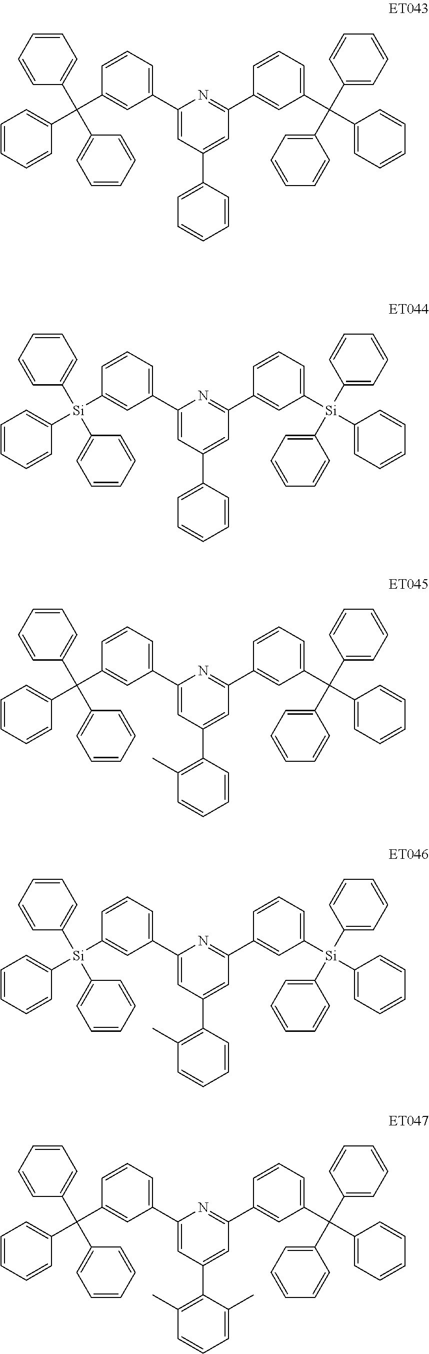 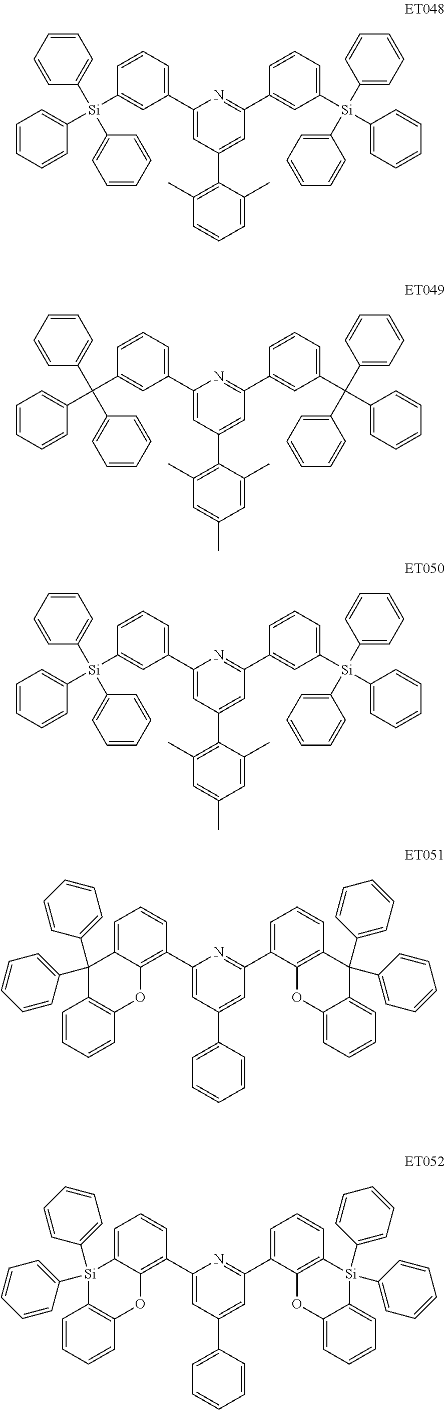 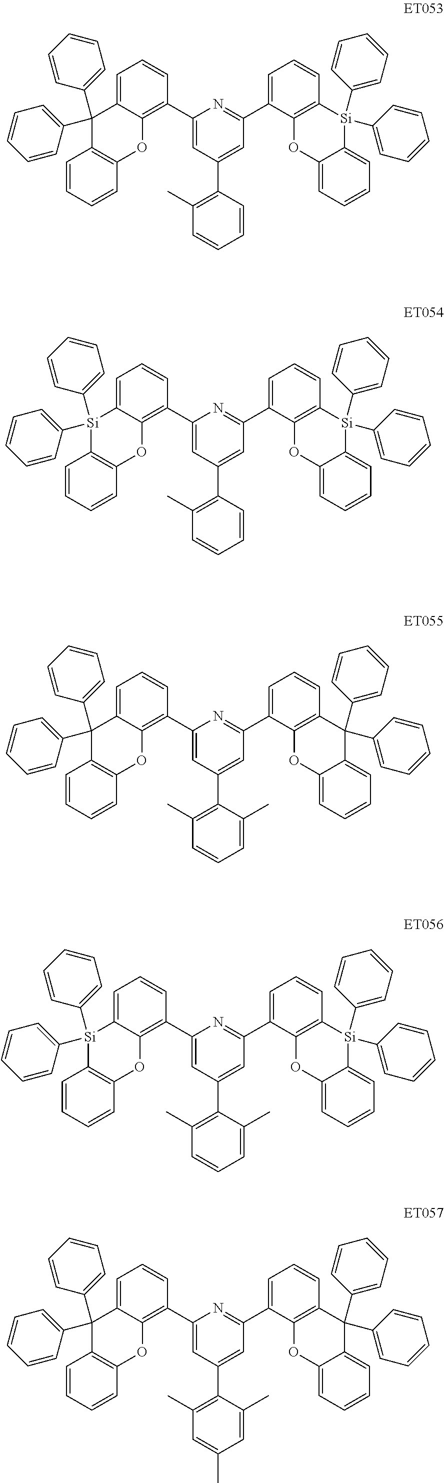 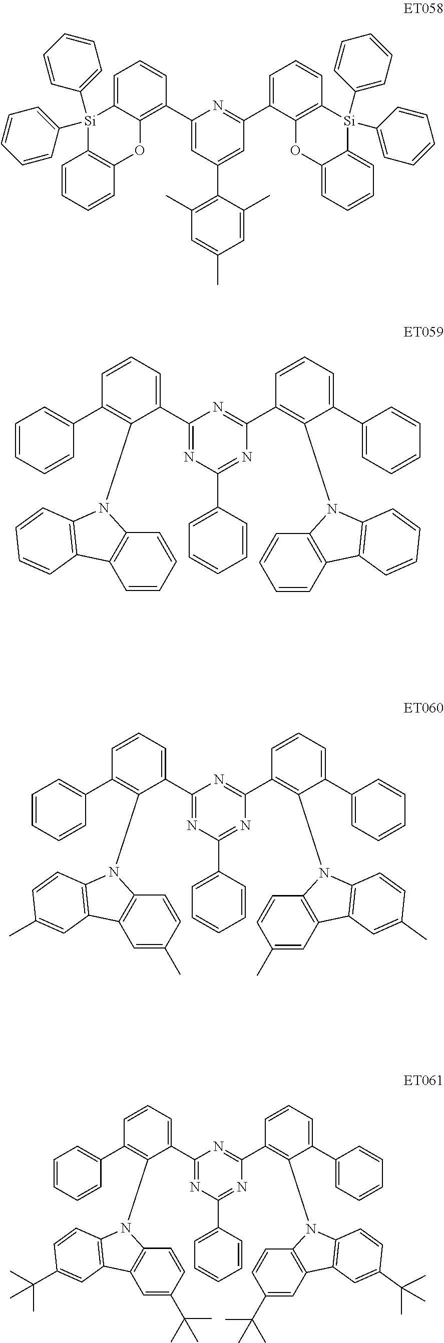 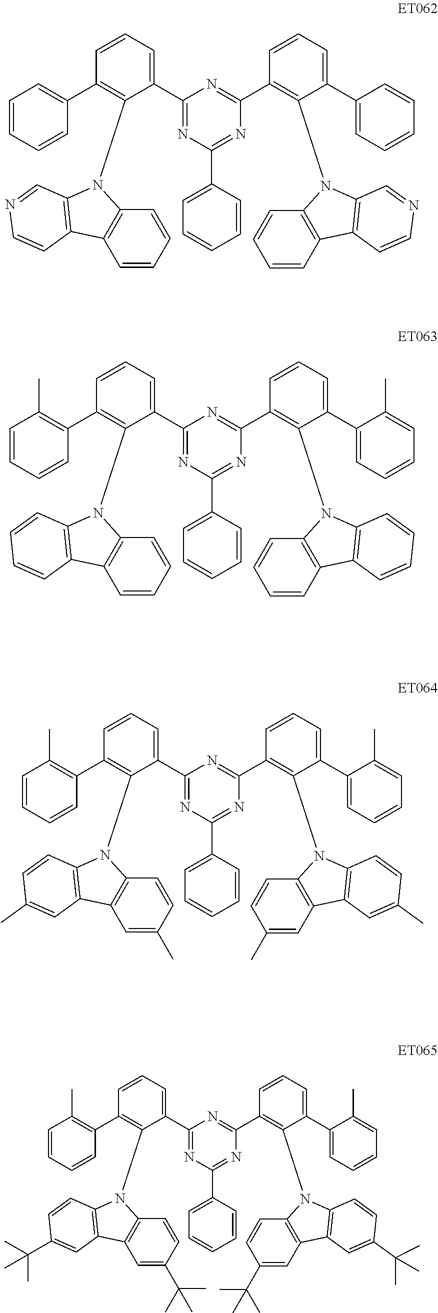 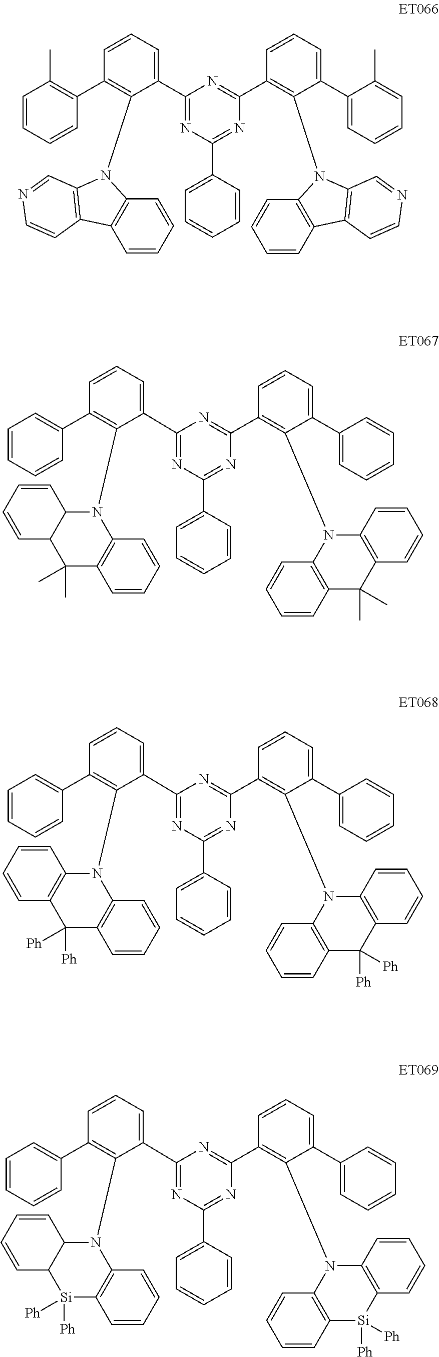 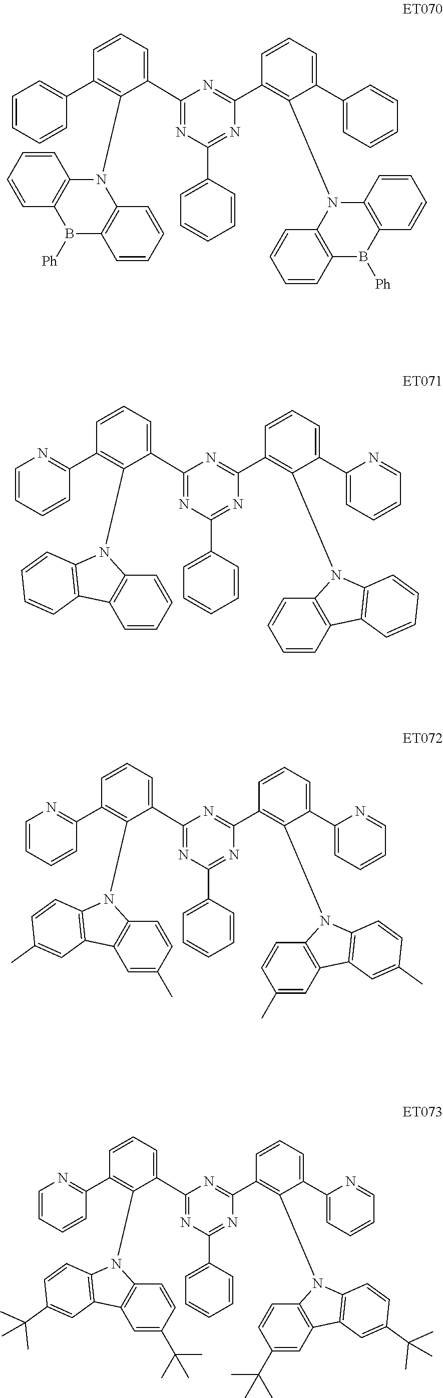 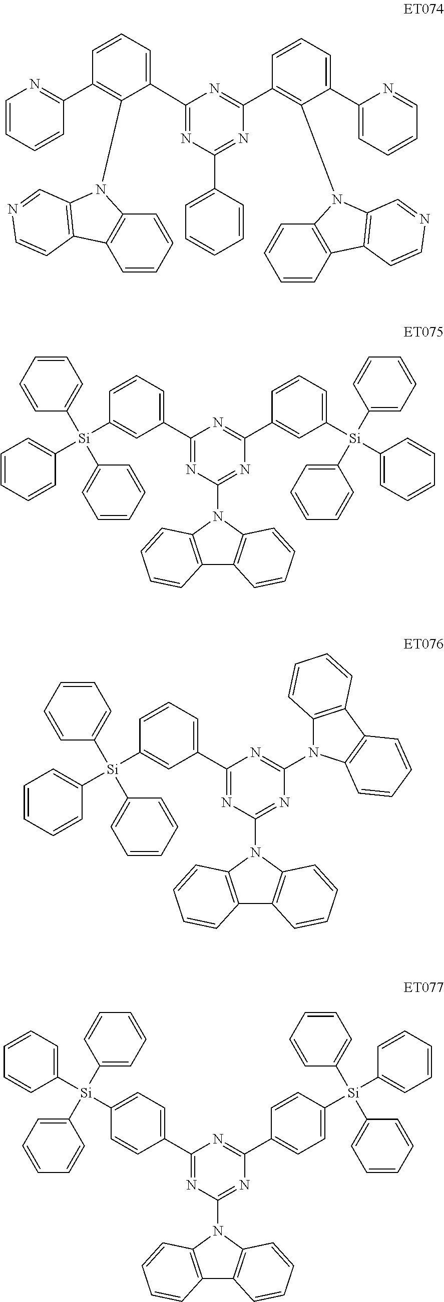 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1] 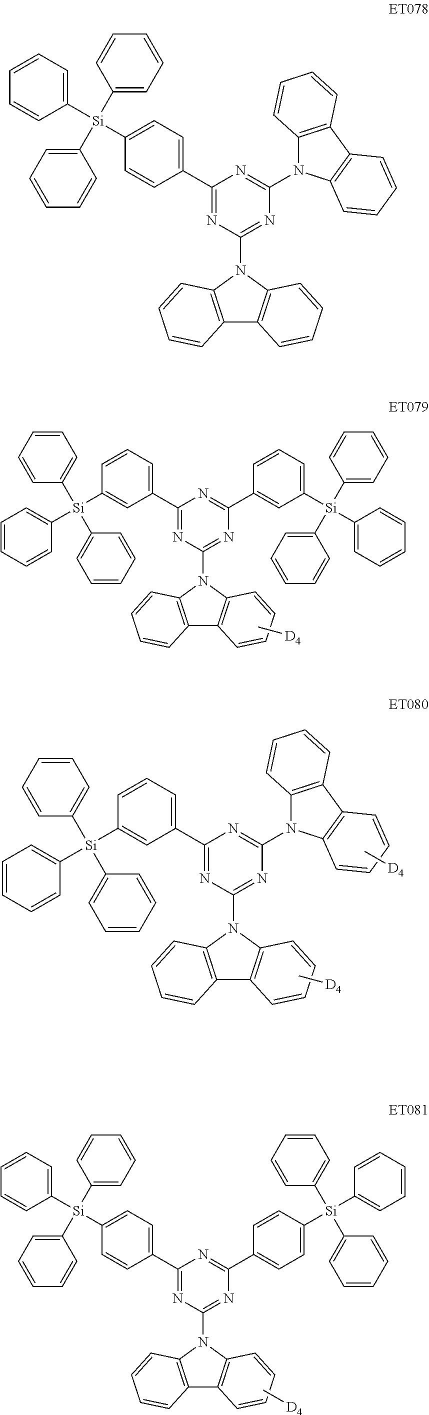 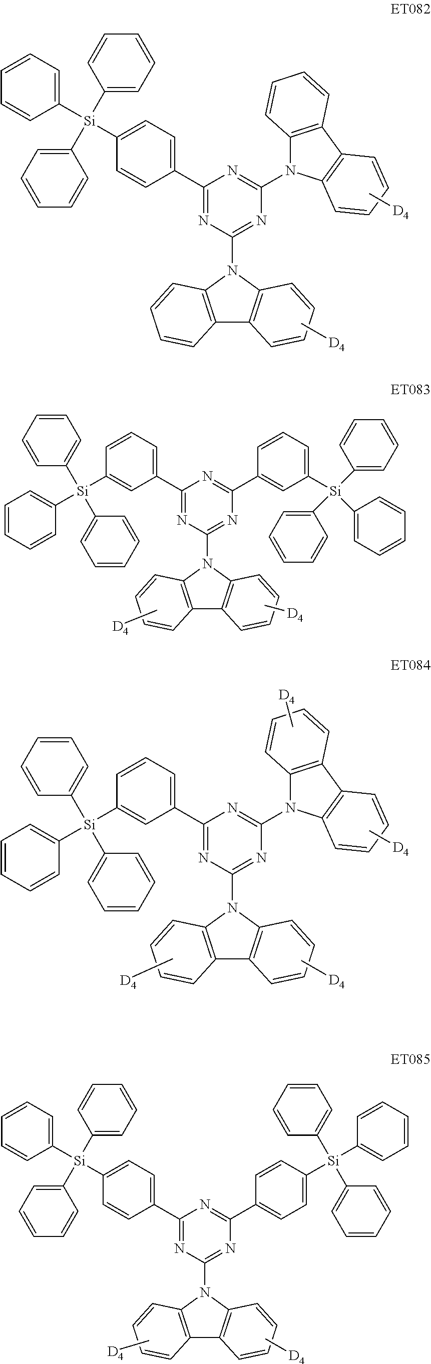 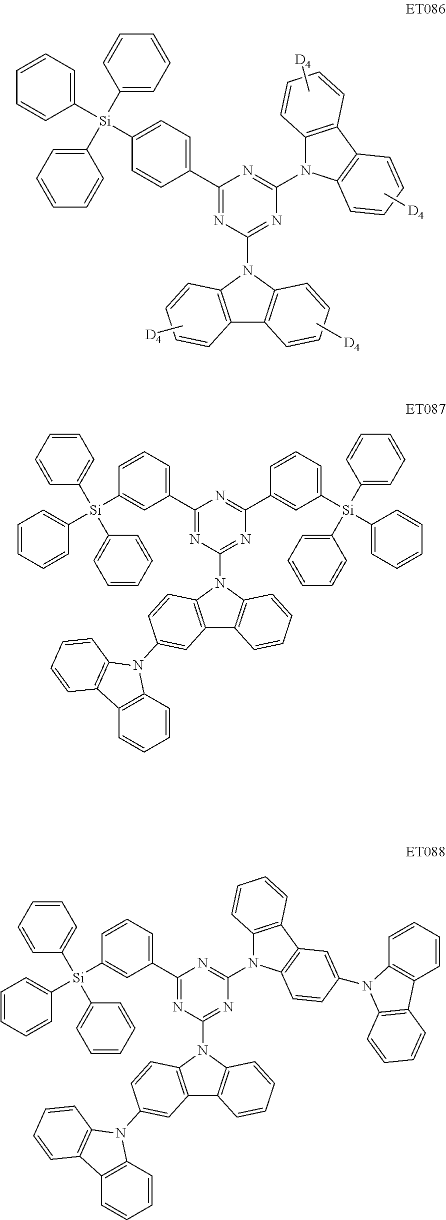 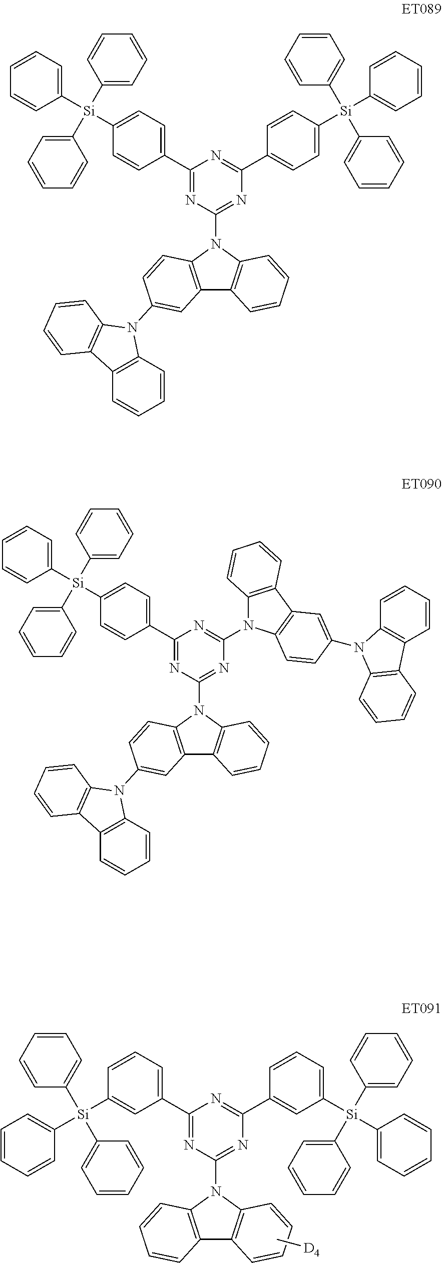 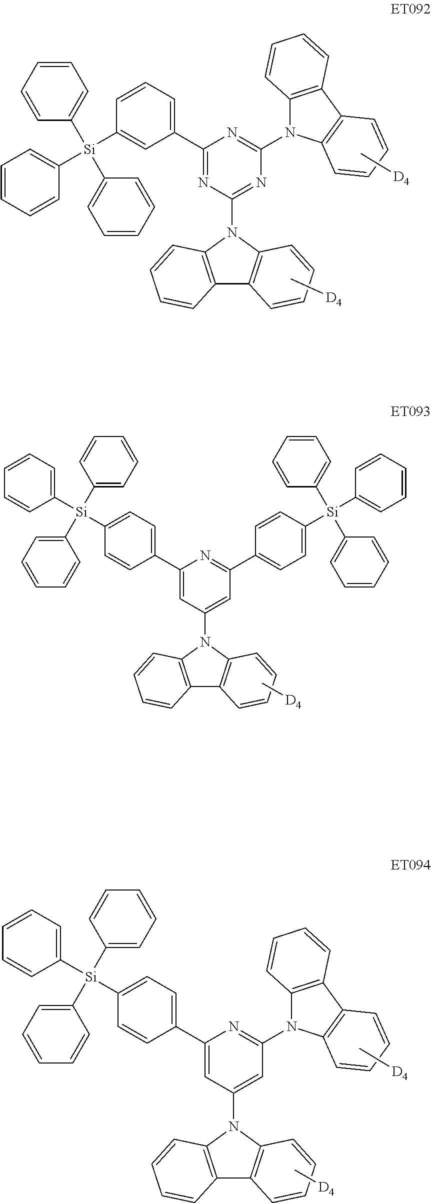 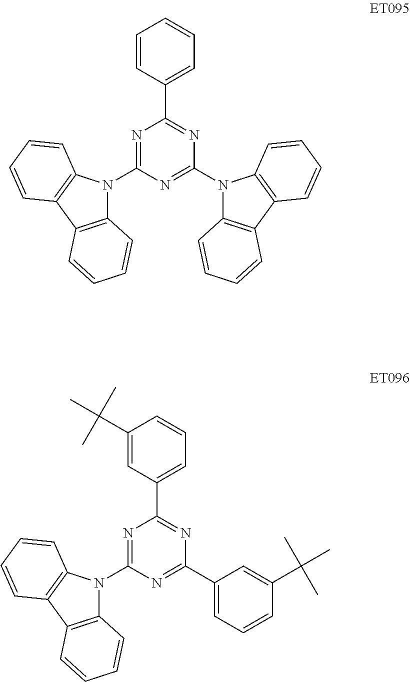 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]
wherein in Compound Group 3,
D represents a deuterium atom.

13. The light emitting element of claim 1, wherein the first fluorescent dopant has a molar extinction coefficient equal to or greater than about 2×10⁵ M⁻¹cm⁻¹.

14. The light emitting element of claim 1, wherein the phosphorescent sensitizer comprises a compound represented by Formula PS: 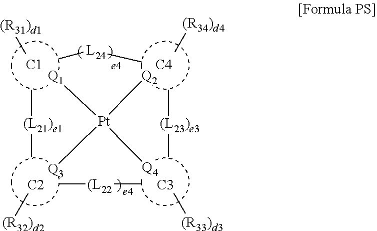
wherein in Formula PS,
Q₁ to Q₄ are each independently C or N, and
rings C1 to C4 are each independently a substituted or unsubstituted hydrocarbon ring group having 5 to 30 ring-forming carbon atoms or a substituted or unsubstituted heterocyclic group having 2 to 30 ring-forming carbon atoms,
L₂₁ to L₂₄ are each independently a direct linkage, 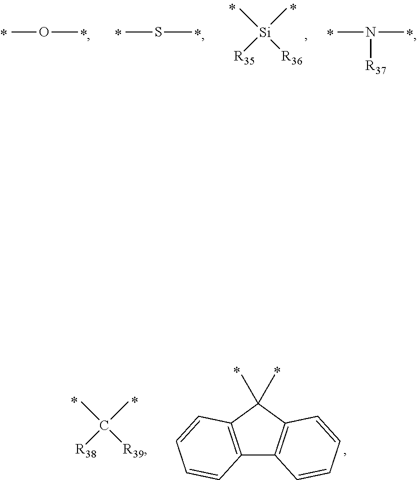
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
e1 to e4 are each independently 0 or 1,
d1 to d4 are each independently an integer from 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

15. A display device comprising:
a substrate in which a first pixel region, a second pixel region, and a third pixel region are defined; and
a display element layer disposed on the substrate, wherein
the first pixel region emits light in a first wavelength region,
the second pixel region emits light in a second wavelength region having a wavelength that is shorter than the light in the first wavelength region,
the third pixel region emits light in a third wavelength region having a wavelength that is shorter than the light in the first wavelength region and shorter than the light in the second wavelength region,
the display element layer comprises a first light emitting element, a second light emitting element, and a third light emitting element, which respectively correspond to the first pixel region, the second pixel region, and the third pixel region,
each of the first, second, and third light emitting elements comprise:
a first electrode;
a second electrode facing the first electrode;
a first light emitting unit disposed between the first electrode and the second electrode and comprising a first emission layer;
a second light emitting unit disposed on the first light emitting unit and comprising a second emission layer; and
a charge generation layer disposed between the first light emitting unit and the second light emitting unit,
at least one of the first emission layer and the second emission layer of the third light emitting element comprises a hole transporting host, an electron transporting host, a phosphorescent sensitizer, and a first fluorescent dopant,
the first fluorescent dopant comprises a pentacyclic fused ring core that includes one boron atom and two heteroatoms as ring-forming atoms, and at least one amine substituent of the fused ring core,
the at least one amine substituent is substituted with at least one substituted or unsubstituted pyrenyl group, and
a difference between a triplet state energy level the first fluorescent dopant and a singlet state energy level of the first fluorescent dopant is equal to or greater than about 0.4 eV.

16. The display device of claim 15, wherein
the charge generation layer comprises:
an n-type charge generation layer overlapping the first to third pixel regions and provided as a common layer on the first light emitting unit; and
a p-type charge generation layer disposed on the n-type charge generation layer, and
the p-type charge generation layer is provided as a patterned layer overlapping each of the first to third pixel regions.

17. The display device of claim 15, wherein
the first light emitting unit comprises a first hole transport region disposed on the first electrode, a first emission layer disposed on the first hole transport region, and a first electron transport region disposed on the first emission layer, and
the second light emitting unit comprises a second hole transport region disposed on the charge generation layer, a second emission layer disposed on the second hole transport region, and a second electron transport region disposed on the second emission layer.

18. The display device of claim 15, further comprising:
a light control layer comprising a first light control part overlapping the first pixel region, a second light control part overlapping the second pixel region, and a third light control part overlapping the third pixel region, wherein
the light control layer is disposed on the first to third light emitting elements.

19. The display device of claim 15, wherein
the hole transporting host and the electron transporting host form an exciplex,
a triplet state energy level of the exciplex is higher than a triplet state energy level of the phosphorescent sensitizer, and
the triplet state energy level of the phosphorescent sensitizer is higher than a triplet state energy level of the first fluorescent dopant.

20. The display device of claim 15, wherein light emitted from the first fluorescent dopant has a full width at half maximum (FWHM) equal to or less than about 25 nm.
